(19) United States
(12) Patent Application Publication
(10) Pub. No.: US 2012/0003437 A1
(43) Pub. Date: Jan. 5, 2012

(54) PHOTOSENSITIVE COMPOSITION, PATTERN FORMING MATERIAL AND PHOTOSENSITIVE FILM USING THE SAME, PATTERN FORMING METHOD, PATTERN FILM, ANTIREFLECTION FILM, INSULATING FILM, OPTICAL DEVICE, AND ELECTRONIC DEVICE

(75) Inventors: Kenji WADA, Shizuoka (JP); Masaki OHTA, Shizuoka (JP); Kunihiko KODAMA, Shizuoka (JP)

(73) Assignee: FUJIFILM CORPORATION, Tokyo (JP)

(21) Appl. No.: 13/172,967

(22) Filed: Jun. 30, 2011

(30) Foreign Application Priority Data
Jul. 1, 2010 (JP) 2010-151499

(51) Int. Cl. G03F 7/075; B32B 3/00; G03F 7/20; G03F 7/30

(52) U.S. Cl. 428/195.1; 430/270.1; 430/325

(57) ABSTRACT

A photosensitive composition contains (A) a polymer obtained from a silsesquioxane constituted of one or two or more kinds of a cage-shaped silsesquioxane compound represented by the specific formula.

### BACKGROUND OF THE INVENTION

1. Field of the Invention

The present invention relates to a photosensitive composition which reacts upon irradiation with an actinic ray or a radiation, whereby its properties are changed, and to a pattern forming method and a film using the photosensitive composition. In more detail, the invention relates to a photosensitive composition capable of forming a coating film which is useful for interlayer insulating film materials in semiconductor devices or the like or as antireflection films or the like in optical devices and which has an appropriate uniform thickness and capable of manufacturing a pattern film which is excellent in resolution, dielectric constant characteristics, refractive index characteristics and the like; a pattern forming material and a photosensitive film using the same; a pattern forming method; a pattern film; an antireflection film; an insulating film; an optical device; and an electronic device.

2. Description of the Related Art

At the time of laser annealing or in a photoresist process for fabricating various display panels such as liquid crystal display panels, cold cathode ray tube panels and plasma displays, solid-state imaging devices such as charge coupled devices (CCD) and complementary metal oxide film semiconductor (CMOS) image sensors, optical devices such as solar cell panels, thin film transistors and single crystal thin film silicon solar cells, for the purposes of preventing glare of external light from occurring, enhancing a light condensing rate and more enhancing an image quality, an antireflection film is used.

Examples of this antireflection film include a multi-layered configuration in which a high refractive index layer and a low refractive index layer, each of which is made of a metal oxide, etc., are laminated on a substrate; and a single-layered configuration in which only a low refractive index layer made of an organic fluorine compound or an inorganic compound, etc. is provided, on the basis of an optical theory of antireflection. In either layer configuration, a low refractive index material made of a cured film having excellent scratch resistance, coatability and durability is desired. In particular, in the case of use as an antireflection film of an optical device, for example, image sensors, since the antireflection film is exposed under a high-temperature condition of 200° C. or higher over a long period of time, high heat resistance and stability with time of refractive index under a high-temperature condition are required.

There have been proposed various low refractive index materials up to date. For example, in JP-A-2004-21036 (the term “JP-A” as used herein means an “unexamined published Japanese patent application”), a low refractive index material is fabricated using a hydrolysis condensate of an alkoxysilane.

However, in the case of using a hydrolysis condensate of an alkoxysilane as described in JP-A-2004-21036, a reaction proceeds between silanol groups, etc. remaining in the hydrolysis condensate on the occasion of baking at the time of film formation, and film contraction proceeds, thereby possibly generating a crack, etc. Thus, film formation processability is poor. Also, adsorption of water, etc. is easy to occur due to the residual silanol group, and as a result, there is involved such a problem that the refractive index changes with a lapse of time. Furthermore, the refractive index of the resulting film is not always on a satisfactory level from the standpoint of practical use, and realization of a lower refractive index is required.

Meanwhile, as an interlayer insulating film in conventional semiconductor devices and the like, silica (SiO₂) films formed in a vacuum process such as a chemical vapor deposition (CVD) process are frequently used. In recent years, for the purpose of forming a more uniform interlayer insulating film, an insulating film of a coating type which is composed mainly of a hydrolyzate of a tetraalkoxysilane called an SOG (spin on glass) film has also become to be used. Also, following an increase of integration of semiconductor devices and the like, there is developed an interlayer insulating film with a low dielectric constant which is composed mainly of a polyorganosiloxane called an organic SOG.

But, even in a CVD-SiO₂ film exhibiting a lowest dielectric constant among inorganic material films, its relative dielectric constant is about 4. Also, a relative dielectric constant of an SiOF film which is recently studied as a low-dielectric constant CVD film is from about 3.3 to 3.5. However, this film is high in hygroscopicity, so that there is involved such a problem that its dielectric constant increases in due course when it is used.

Under such circumstances, there is proposed a method in which a high-boiling solvent or a heat decomposable compound is added to an organopolysiloxane as an insulating film material having excellent insulating properties, heat resistance and durability to form pores, thereby decreasing a dielectric constant (see Chem. Rev., 56, 2010, 110, 56 to 110). However, in such a porous film, even when the dielectric constant characteristics are lowered by making the film porous, there were involved such problems as a lowering of mechanical strength and occurrence of an increase of the dielectric constant due to moisture absorption. Also, since pores connected to each other are formed, there was encountered such a problem that copper used for wirings is diffused into the insulating film.

Meanwhile, there is also known an attempt to obtain a film with low refractive index and low density by coating a solution having a low-molecular weight cage-type compound to an organic polymer (see JP-A-2000-334881). But, in a method of adding a cage-type compound monomer, various characteristics such as dielectric constant and Young's modulus of the resulting film are not always satisfactory from the viewpoint of practical use, and furthermore, there was involved such a problem as deterioration of coating surface properties.

In addition to such dielectric characteristics and reflectance characteristics, it is further desired to solve many problems such as complication of a manufacturing process. In order to overcome the complication of a manufacturing process, JP-A-2009-215423 and US-A-2009/291389 disclose, as a patterning method not using a photoresist, a method of using a silica based material provided with photosensitivity and exposing and developing the material itself to form a pattern. However, there are still involved a lot of insufficient points, so that improvements are desired.

Specifically, JP-A-2009-215423 discloses a negative working resist made of a double-decker type POSS polymer. However, not only its resolution in pattern formation is insufficient, but its low refractive index properties in refractive index of the resulting pattern are insufficient.

Also, US-A-2009/291389 discloses a resist made of a sol-gel polymer. However, not only its resolution in pattern formation is insufficient, but its low dielectric constant properties of the resulting pattern are insufficient.

Furthermore, in the working examples of JP-A-2007-298841, there is known a technology in which a film is formed using a solution containing a polysilsesquioxane polymer derived from a cage-type silicon compound having a specified structure and a photosensitive metal complex, and this film is exposed and developed to form a pattern. However, the irradiated exposure amount is very large, the film is low in sensitivity, and the resulting pattern is insufficient in low refractive index properties in refractive index and low dielectric constant properties in dielectric constant. Furthermore, in view of the fact that the metal catalyst is used, an applicable device is largely limited.

### SUMMARY OF THE INVENTION

In view of the foregoing background, the invention has been made, and a problem of the invention is to solve the foregoing various problems of the related art and to attain the following objects.

That is, an object of the invention is to provide a photosensitive composition capable of forming a pattern film which is satisfactory in coating surface properties, low in refractive index and small in a change of refractive index even under a high-temperature condition (the foregoing is a performance suitable for, for example, an antireflection film in an optical device) and also a pattern film which is low in dielectric constant and high in Young's modulus (the foregoing is a performance suitable for, for example, an interlayer insulating film in a semiconductor device or the like) at a high resolution; a pattern forming material and a photosensitive film using the same; a pattern forming method; and a pattern film.

Furthermore, another object of the invention is to provide an antireflection film and an insulating film, each of which is produced using the subject photosensitive composition, and an optical device and an electronic device each using the same.

The invention has the following constitutions, from which are attained the foregoing objects of the invention.

[1] A photosensitive composition comprising:

(A) a polymer obtained from a silsesquioxane constituted of one or two or more kinds of a cage-shaped silsesquioxane compound represented by the following formula (1):

(RSiO_{1.5})ₐ (1)

wherein

each R independently represents an organic group, and at least two of R's represent a polymerizable group; a represents an integer of from 8 to 16; and each R may be the same as or different from every other R, and

(B) a photopolymerization initiator,

provided that a polymerizable group derived from the cage-shaped silsesquioxane compound remains in the polymer.

[2] The photosensitive composition according to [1] above, wherein the cage-shaped silsesquioxane compound is one or two or more members selected from the group consisting of cage-shaped silsesquioxane compounds represented by the following general formulae (Q-1) to (Q-7):

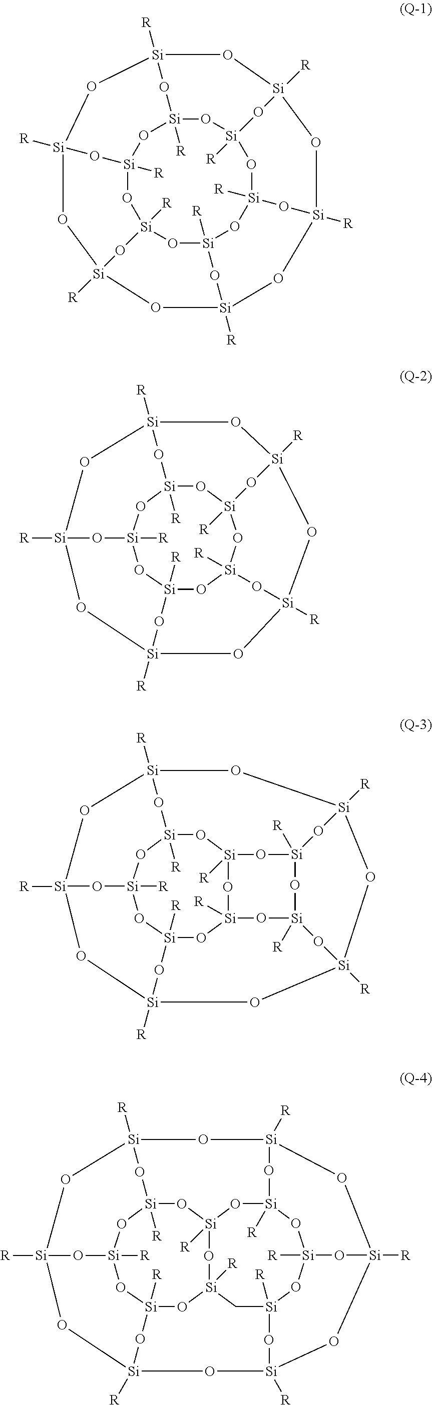

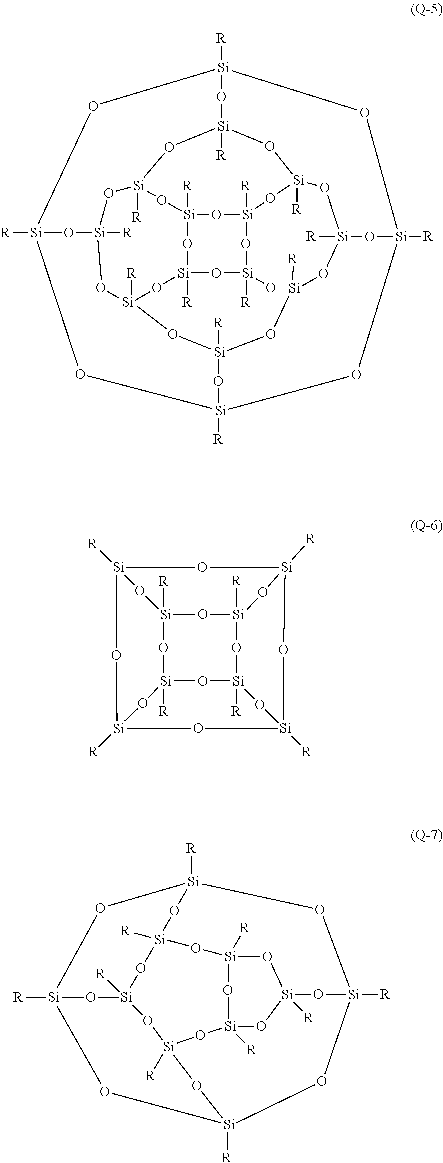

wherein

each R independently represents an organic group, and in each of the general formulae (Q-1) to (Q-7), at least two of R's represent a polymerizable group.

[3] The photosensitive composition according to [1] or [2] above, wherein a content of the polymerizable group in the polymer is from 10 to 90 mol % in the whole of organic groups bonded to the silicon atoms.
[4] The photosensitive composition according to any one of [1] to [3] above, wherein a weight average molecular weight of the polymer is from 10,000 to 500,000.
[5] The photosensitive composition according to any one of [1] to [4] above, which is a negative working composition.
[6] The photosensitive composition according to any one of [1] to [5] above, wherein the photopolymerization initiator is an oxime compound.
[7] A pattern forming material, which is the photosensitive composition according to any one of [1] to [6] above.
[8] A photosensitive film, which is formed from the photosensitive composition according to any one of [1] to [6] above.
[9] A pattern forming method comprising:

a step of forming the photosensitive film according to [8] above;

a step of exposing the photosensitive film; and

a development step of developing the exposed photosensitive film to obtain a pattern film.

[10] The pattern forming method according to [9] above, wherein the development step is a step of performing development with a developer containing an organic solvent.
[11] The pattern forming method according to [10] above, wherein the developer containing an organic solvent is a developer containing at least one solvent selected from the group consisting of a ketone based solvent, an ester based solvent, an alcohol based solvent, an amide based solvent and an ether based solvent.
[12] A pattern film obtained by the pattern forming method according to any one of [9] to [11] above.
[13] The pattern film according to [12] above, having a refractive index of 1.35 or less.
[14] The pattern film according to [12] or [13] above, having a relative dielectric constant at 25° C. of 2.50 or less.
[15] The pattern film according to any one of [12] to [14] above, having a film density of from 0.7 to 1.25 g/cm³.
[16] An antireflection film, which is the pattern film according to any one of [12] to [15] above.
[17] An insulating film, which is the pattern film according to any one of [12] to [15] above.
[18] An optical device having the antireflection film according to [16] above.
[19] An electronic device having the insulating film according to [17] above.

According to the invention, it is possible to provide a photosensitive composition capable of forming a pattern film which is satisfactory in coating surface properties, low in refractive index and small in a change of refractive index even under a high-temperature condition (the foregoing is a performance suitable especially for an antireflection film in an optical device) and also a pattern film which is low in dielectric constant and high in Young's modulus (the foregoing is a performance suitable especially for an interlayer insulating film in a semiconductor device or the like) at a high resolution; a pattern forming material and a photosensitive film using the same; a pattern forming method; and a pattern film.

Furthermore, according to the invention, it is possible to provide an antireflection film and an insulating film, each of which is produced using the foregoing photosensitive composition, and an optical device and an electronic device each using the same.

### DETAILED DESCRIPTION OF THE INVENTION

The invention is hereunder described in detail.

Incidentally, in the expressions regarding groups (atomic groups) in this specification, it should be construed that an expression without designating “substituted” or “unsubstituted” includes both one not having a substituent and one having a substituent. For example, it should be construed that an “alkyl group” includes not only an alkyl group not having a substituent (unsubstituted alkyl group) but an alkyl group having a substituent (substituted alkyl group).

Also, the “actinic ray” or “radiation” as referred to in this specification means, for example, a far ultraviolet light represented by a bright line spectrum of a mercury vapor lamp or an excimer laser, an extreme ultraviolet light (EUV light), an X-ray, an electron beam or the like. Also, the “light” as referred to in the invention means an actinic ray or a radiation. The “exposure” as referred to in this specification includes not only exposure with a far ultraviolet light represented by a mercury vapor lamp or an excimer laser, an X-ray, EUV light or the like but drawing with a particle beam such as an electron beam and an ion beam, unless otherwise indicated.

The photosensitive composition of the invention contains (A) a polymer obtained from a silsesquioxane constituted of one or two or more kinds of a cage-shaped silsesquioxane compound represented by an average composition formula as described later; and (B) a photopolymerization initiator.

Here, a polymerizable group derived from the cage-shaped silsesquioxane compound remains in this polymer.

By using the photosensitive composition of the invention, it may be considered that a structure of the cage-shaped silsesquioxane compound contained in the photosensitive composition of the invention greatly contributes to the fact that a pattern film which is satisfactory in coating surface properties, small in a change of refractive index even under a high-temperature condition, low in dielectric constant and high in Young's modulus can be formed.

Also, when after forming a film from the photosensitive composition of the invention containing a polymer obtained from a cage-shaped silsesquioxane compound and a photopolymerization initiator, this film is exposed, a reaction due to a residual polymerizable group in the polymer proceeds, whereby an exposed area is cured. Subsequently, by performing a development step using an alkaline developer, an unexposed area is removed, whereby a pattern can be formed. With respect to this development step, the film formed from the photosensitive composition of the invention is excellent in developability. Though its action is not completely elucidated yet, it may be conjectured that a peculiar high-order structure of the polymer obtained from the cage-shaped silsesquioxane compound contained in the photosensitive composition of the invention largely improves solubility of the resulting film in the developer, thereby contributing to revealment of high developability.

The photosensitive composition according to the invention is typically a negative working composition (composition capable of forming a negative pattern).

The invention also relates to a pattern forming material that is the foregoing photosensitive composition.

First of all, the silsesquioxane that is a raw material of the polymer contained in the composition is described. Thereafter, a polymer produced from the silsesquioxane and a production method of the same are described in detail.

### [1] Silsesquioxane:

### <Cage-Shaped Silsesquioxane Compound>

The silsesquioxane as referred to herein is a compound having a structure in which each silicon atom is bonded to three oxygen atoms, and each oxygen atom is bonded to two silicon atoms (RSiO_{1.5}; an oxygen atom number is 1.5 relative to a silicon atom number). More specifically, the RSiO_{1.5} unit shares an oxygen atom in another RSiO_{1.5} unit to connect to other unit. Incidentally, the caged-shaped structure refers to a structure in which a volume is determined by plural rings formed by covalently bonded atoms, and a point positioning within the volume cannot leave from the volume without passing through the ring.

Since the silsesquioxane of the invention is constituted of one or two or more kinds of a cage-shaped silsesquioxane compound represented by the following formula (1), not only a film using the subject polymer has a lower refractive index, but it exhibits excellent low refractive index properties, heat resistance and resistance to moisture and the like. Incidentally, in the case of using a plural kind (two or more kinds) of a cage-shaped silsesquioxane compound, two kinds of the same cage-shaped compound may be used, or every one kind of a compound having a different cage shape may be used, respectively.

(RSiO_{1.5})ₐ (1)

In the formula (1), each R independently represents an organic group, and at least two of R's represent a polymerizable group. Each R may be the same as or different from every other R.

However, a polymerizable group derived from the cage-shaped silsesquioxane compound remains in the polymer.

In the formula (1), a represents an integer of from 8 to 16. a is more preferably an integer of 8, 10, 12, 14 or 16. In view of the fact that the resulting film exhibits more excellent low refractive index properties and heat resistance, a is preferably 8, 10 or 12; and from the viewpoint of polymerization controllability, a is more preferably 8.

As a preferred embodiment of the cage-shaped silsesquioxane compound, there are exemplified compounds represented by the following general formulae (Q-1) to (Q-7). Above all, a compound represented by the general formula (Q-6) is the most preferable from the viewpoints of availability, polymerization controllability and solubility.

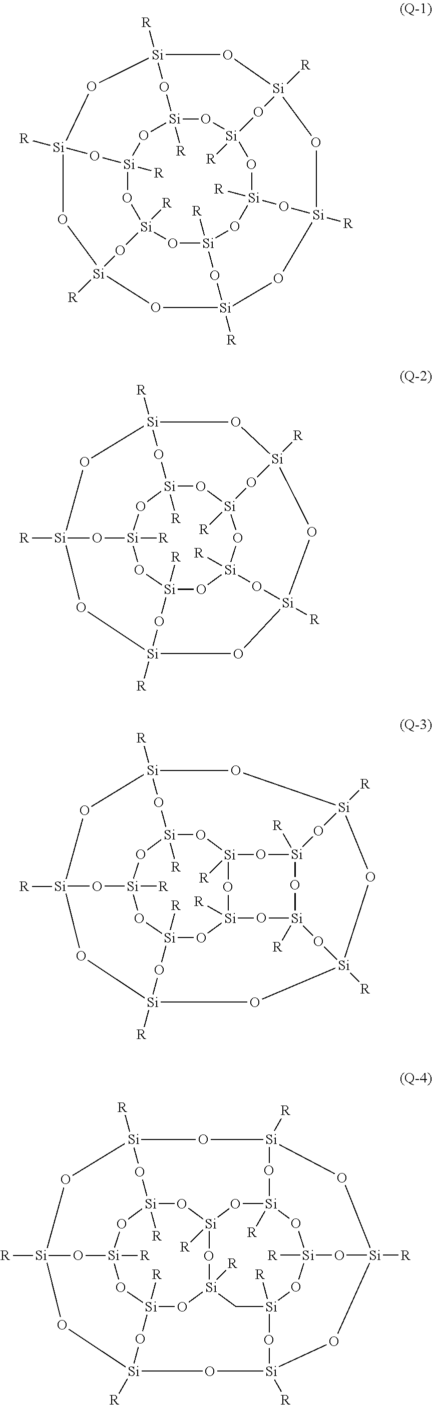

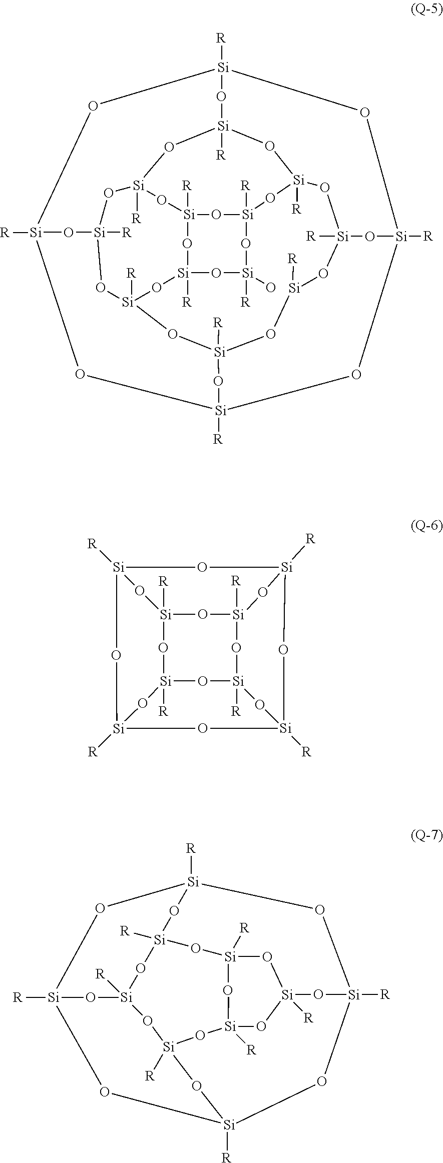

In the general formulae (Q-1) to (Q-7), each R independently represents an organic group, and in each of the general formulae (Q-1) to (Q-7), at least two of R's represent a polymerizable group.

Examples of the organic group represented by R include a polymerizable group and a non-polymerizable group.

The polymerizable group is not particularly limited, and examples thereof include a radical polymerizable group and a cationic polymerizable group. More specifically, cationic polymerizable groups such as an epoxy group, an oxetanyl group, an oxazolyl group and a vinyloxy group; and radical polymerizable groups such as an alkenyl group, an alkynyl group, an acrylic acid ester, a methacrylic acid ester, an acrylamide, methacrylamide, a vinyl ether and a vinyl ester are preferable. Above of all, in view of the facts that synthesis is easy and that a polymerization reaction satisfactorily proceeds, an alkenyl group or an alkynyl group is more preferable.

Incidentally, examples of the alkenyl group include groups having a double bond at an arbitrary position of an alkyl group, a cycloalkyl group, an aryl group, an aralkyl group, an alkoxy group or a silicon atom-containing group. Above all, an alkenyl group having from 2 to 12 carbon atoms is preferable, and an alkenyl group having from 2 to 6 carbon atoms is more preferable. Examples thereof include a vinyl group and an allyl group. From the viewpoints of easiness of polymerization controllability and mechanical strength, a vinyl group is preferable.

Examples of the alkynyl group include groups having a triple bond at an arbitrary position of an alkyl group, a cycloalkyl group, an aryl group, an aralkyl group, an alkoxy group or a silicon atom-containing group. Above all, an alkynyl group having from 2 to 12 carbon atoms is preferable, and an alkynyl group having from 2 to 6 carbon atoms is more preferable. From the viewpoint of easiness of polymerization controllability, an ethynyl group is preferable.

The non-polymerizable group as referred to herein means a group not having the foregoing polymerizability. Specific examples thereof include an alkyl group, a cycloalkyl group, an aryl group, an aralkyl group, an alkoxy group, a silicon atom-containing group and a group obtained by combining these groups. Above all, in view of the facts that the photosensitive film exhibits excellent developability and that the resulting pattern film exhibits excellent low refractive index properties and heat resistance, an alkyl group or a cycloalkyl group is preferable.

The alkyl group may have a substituent and is preferably a linear or branched alkyl group having from 1 to 20 carbon atoms. The alkyl group may have an oxygen atom, a sulfur atom, a nitrogen atom or a halogen atom in a chain thereof. Specific examples of the alkyl group include linear alkyl groups such as a methyl group, an ethyl group, an n-propyl group, an n-butyl group, an n-pentyl group, an n-hexyl group, an n-octyl group, an n-dodecyl group, an n-tetradecyl group and an n-octadecyl group; and branched alkyl groups such as an isopropyl group, an isobutyl group, a t-butyl group, a neopentyl group and a 2-ethylhexyl group.

Incidentally, as one of preferred embodiments of the alkyl group, in view of the fact that the resulting film exhibits more excellent low refractive index properties, an alkyl group having a fluorine atom (fluorinated alkyl group) is preferable. Examples of the fluorinated alkyl group include those in which a part or all of hydrogen atoms of the alkyl group are substituted with a fluorine atom. Specific examples thereof include a trifluoromethyl group, a pentafluoroethyl group, a heptafluoropropyl group and a nanofluorobutyl group.

The cycloalkyl group may have a substituent and is preferably a cycloalkyl group having from 3 to 20 carbon atoms. The cycloalkyl group may be polycyclic and may have an oxygen atom in a ring thereof. Specific examples thereof include a cyclopropyl group, a cyclopentyl group, a cyclohexyl group, a norbonyl group and an adamantyl group.

The aryl group may have a substituent and is preferably an aryl group having from 6 to 14 carbon atoms. Examples thereof include a phenyl group and a naphthyl group.

The aralkyl group may have a substituent and is preferably an aralkyl group having from 7 to 20 carbon atoms. Examples thereof include a benzyl group, a phenethyl group, a naphthylmethyl group and a naphthylethyl group.

The alkoxy group may have a substituent and is preferably an alkoxy group having from 1 to 20 carbon atoms. Examples thereof include a methoxy group, an ethoxy group, a propoxy group, an n-butoxy group, a pentyloxy group, a hexyloxy group and a heptyloxy group.

Though the silicon atom-containing group is not particularly limited so far as silicon is contained therein, a group represented by the following general formula (2) is preferable.

*-L¹-Si—(R²⁰)₃ (2)

In the general formula (2), * represents a bonding position to the silicon atom. L¹ represents an alkylene group, —O—, —S—, —Si(R²¹)(R²²)—, —N(R²³— or a divalent connecting group obtained by combining these groups. L¹ is preferably an alkylene group, —O— or a divalent connecting group obtained by combining these groups.

The alkylene group is preferably an alkylene group having from 1 to 12 carbon atoms, and more preferably an alkylene group having from 1 to 6 carbon atoms. Each of R²¹, R²², R²³ and R²⁰ independently represents an alkyl group, a cycloalkyl group, an aryl group or an alkoxy group. The definitions of the alkyl group, the cycloalkyl group, the aryl group and the alkoxy group represented by R²¹, R²², R²³ and R²⁰ are the same as those described above, and preferred examples thereof include a methyl group, an ethyl group, a butyl group and a cyclohexyl group.

The silicon atom-containing group is preferably a silyloxy group (for example, trimethylsilyloxy, triethylsilyloxy or t-butyldimethylsilyloxy).

It is preferable that the cage-shaped silsesquioxane compound represented by the formula (1) is represented by the following average composition formula (3).

(R¹SiO_{1.5})ₓ(R²SiO_{1.5})_{y} (3)

In the formula (3), R¹ represents a polymerizable group. R² represents a non-polymerizable group. Here, the polymerizable group and the non-polymerizable group are synonymous with those described above, respectively. x represents a number of from 2.0 to 14.0 (2.0≦x≦14.0), and y represents a number of from 0 to 14.0 (0≦y≦14.0), provided that a relation of ((x+y)=8 to 16) is satisfied. Incidentally, each R¹ and each R² may be the same as or different from every other R¹ and R², respectively.

In the formula (3), x represents a number of from 2.0 to 14.0, and in view of the fact that the resulting film exhibits more excellent low refractive index properties, heat resistance, light resistance and curing properties, x is preferably 2.5 or more, and more preferably 3.0 or more.

In the formula (3), y represents a number of from 0 to 14.0, and in view of the fact that the resulting film exhibits more excellent low refractive index properties, heat resistance and coatability, y is preferably from 0 to 12.0, more preferably from 0 to 10.0, still more preferably from 0 to 7.5, and yet still more preferably from 0 to 5.0.

In the formula (3), a relation of ((x+y)=8 to 16) is satisfied, and in view of the fact that the resulting film exhibits more excellent low refractive index properties, heat resistance, hygroscopicity and storage stability, (x+y) is preferably from 8 to 14, more preferably from 8 to 12, and still more preferably from 8 to 10.

Furthermore, in the formula (3), a proportion of x(x/(x+y)) is preferably satisfied with a relation of 0.1≦(x/(x+y))≦1.0. In view of the fact that the resulting film exhibits more excellent low refractive index properties, heat resistance and mechanical strength, a relation of 0.2≦(x/(x+y))≦1.0 is more preferable, and a relation of 0.3≦(x/(x+y))≦1.0 is still more preferable.

### <Preferred Embodiment of Silsesquioxane>

As one of preferred embodiments of the silsesquioxane, in view of the fact that the resulting film exhibits more excellent refractive index properties and heat resistance, there is exemplified a silsesquioxane constituted of the cage-shaped silsesquioxane compound represented by the foregoing general formula (Q-6), in which in the formula (3), x represents a number falling within the range of 2.0≦x≦8.0 (preferably 3.0≦x≦8.0), and y represents a number falling within the range of 0≦y≦6.0, (preferably 0≦y≦5.0), with (x+y) being 8.

This silsesquioxane is constituted of one or two or more kinds of the cage-shaped silsesquioxane represented by the foregoing general formula (Q-6) (T8 type). For example, this silsesquioxane may be a mixture of a cage-shaped silsesquioxane compound having eight polymerizable groups and a cage-shaped silsesquioxane compound having four polymerizable groups and four non-polymerizable groups.

As other preferred embodiment of the silsesquioxane, there is exemplified a silsesquioxane constituted of the cage-shaped silsesquioxane compound represented by the foregoing general formula (Q-2) and/or the cage-shaped silsesquioxane compound represented by the foregoing general formula (Q-7), in which in the formula (3), x represents a number falling within the range of 2.0≦x≦10.0 (preferably 3.0≦x≦10.0), and y represents a number falling within the range of 0≦y≦8.0 (preferably 0≦y≦7.0), with (x+y) being 10.

This silsesquioxane is constituted of one or two or more kinds of the cage-shaped silsesquioxane represented by the foregoing general formula (Q-2) or (Q-7) (T10 type).

As other preferred embodiment of the silsesquioxane, there is exemplified a silsesquioxane constituted of the cage-shaped silsesquioxane compound represented by the foregoing general formula (Q-1) and/or the cage-shaped silsesquioxane compound represented by the foregoing general formula (Q-3), in which in the formula (3), x represents a number falling within the range of 2.0≦x≦12.0 (preferably 3.0≦x≦12.0), and y represents a number falling within the range of 0≦y≦10.0 (preferably 0≦y≦9.0), with (x+y) being 12.

This silsesquioxane is constituted of one or two or more kinds of the cage-shaped silsesquioxane represented by the foregoing general formula (Q-1) or (Q-3) (T12 type).

As other preferred embodiment of the silsesquioxane, there is exemplified a silsesquioxane constituted of the cage-shaped silsesquioxane compound represented by the foregoing general formula (Q-4), in which in the formula (3), x represents a number falling within the range of 2.0≦x≦14.0, and y represents a number falling within the range of 0≦y≦12.0, with (x+y) being 14.

This silsesquioxane is constituted of one or two or more kinds of the cage-shaped silsesquioxane represented by the foregoing general formula (Q-4) (T14 type).

As one of other preferred embodiments of the silsesquioxane, there is exemplified a silsesquioxane including a cage-shaped silsesquioxane compound having at least three polymerizable groups and at least three non-polymerizable groups (this compound will be hereinafter also referred to as “compound (A)”). That is, this compound (A) is a compound in which in the formula (3), at least three R's represent a polymerizable group, and furthermore, at least three R's represent a non-polymerizable group. When this compound (A) is contained, a pattern film having a lower refractive index and having excellent heat resistance can be obtained.

In this embodiment, the cage-shaped silsesquioxane compound (A) may have three or more polymerizable groups and three or more non-polymerizable groups.

Though a structure of the compound (A) is not particularly limited, it is preferable that the compound (A) is a compound represented by any of the foregoing general formulae (Q-1) to (Q-7).

For example, among compounds represented by the generated formula (Q-6), a compound having from 3 to 5 polymerizable groups and from 3 to 5 non-polymerizable groups, with a total number of the both being 8, is corresponding to the compound (A).

Also, among compounds represented by the general formula (Q-2) or (Q-7), a compound having from 3 to 7 polymerizable groups and from 3 to 7 non-polymerizable groups, with a total number of the both being 10, is corresponding to the compound (A).

Also, among compounds represented by the general formula (Q-4), a compound having from 3 to 11 polymerizable groups and from 3 to 11 non-polymerizable groups, with a total number of the both being 14, is corresponding to the compound (A).

Though a content of the compound (A) in the whole of the silsesquioxanes is not particularly limited, in view of the fact that various characteristics of the resulting film are more excellent, the content of the compound (A) is preferably 10 mol % or more, more preferably from 20 to 100 mol %, and still more preferably from 60 to 100 mol %, relative to a total amount of the silsesquioxanes. In particular, it is preferable that the silsesquioxane is constituted of only the compound (A) and does not substantially contain other cage-shaped silsesquioxane compound.

Though the foregoing silsesquioxane is in general constituted of a cage-shaped silsesquioxane compound, it may contain other polysiloxane compound (for example, a ladder type silsesquioxane compound, etc.) within the range where the effects of the invention are not impaired.

Specific examples of the silsesquioxane are shown below, but it should not be construed that the invention is limited thereto. Incidentally, a substituent ratio in Table 1 is corresponding to x/y in the formula (3).

TABLE 1

| | Cage | | | Substituent |
|---|---|---|---|---|
| Compound | structure | Substituent R¹ | Substituent R² | ratio |
| I-1 | Q-1 | Vinyl | Methyl | 6.0/6.0 |
| I-2 | Q-1 | Vinyl | Methyl | 3.0/9.0 |
| I-3 | Q-1 | Vinyl | Phenyl | 6.0/6.0 |
| I-4 | Q-2 | Vinyl | Methyl | 5.0/5.0 |
| I-5 | Q-3 | Vinyl | Dodecyl | 6.0/6.0 |
| I-6 | Q-4 | 4-Vinylphenyl | Ethyl | 4.0/10.0 |
| I-7 | Q-5 | Ethynyl | Methyl | 4.5/11.5 |
| I-8 | Q-6 | Vinyl | Methyl/Phenyl | 2.5/3.5/2.0 |
| I-9 | Q-6 | Vinyl | Methyl | 2.5/5.5 |
| I-10 | Q-6 | Vinyl | Methyl | 3.0/5.0 |
| I-11 | Q-6 | Vinyl | Methyl | 3.5/4.5 |
| I-12 | Q-6 | Vinyl | Methyl | 3.9/4.1 |
| I-13 | Q-6 | Vinyl | Methyl | 4.0/4.0 |
| I-14 | Q-6 | Vinyl | Methyl | 4.4/3.6 |
| I-15 | Q-6 | Vinyl | Methyl | 5.0/3.0 |
| I-16 | Q-6 | Vinyl | Methyl | 5.5/2.5 |
| I-17 | Q-6 | Ethynyl | Methyl | 3.1/4.9 |
| I-18 | Q-6 | Vinyl | Phenyl | 4.0/4.0 |
| I-19 | Q-6 | 4-Vinylphenyl | Methyl | 3.5/4.5 |
| I-20 | Q-6 | 4-Vinylphenyl/Vinyl | Methyl | 1.0/2.0/5.0 |
| I-21 | Q-6 | Vinyl | Pentafluorophenyl | 4.0/4.0 |
| I-22 | Q-6 | Vinyl | CF₃CH₂CH₂— | 3.0/5.0 |
| I-23 | Q-6 | CH₂═C(CH₃)CO₂(CH₂)₃—/Vinyl | Methyl | 1.0/3.0/4.0 |
| I-24 | Q-6 | (CH₂═CH)Me₂SiO— | Me₂SiO— | 4.0/4.0 |
| I-25 | Q-6 | Vinyl | Propyl | 4.0/4.0 |
| I-26 | Q-6 | Vinyl | Ethyl | 4.1/3.9 |
| I-27 | Q-6 | Vinyl | Ethyl | 4.3/3.7 |
| I-28 | Q-6 | Allyl | Cyclohexyl | 2.5/5.5 |
| I-29 | Q-6 | Allyl/Vinyl | Methyl | 1.2/1.9/4.9 |
| I-30 | Q-6 | CH₂═C(CH₃)CO₂(CH₂)₃— | Methyl | 2.0/6.0 |
| I-31 | Q-7 | Ethynyl | Phenyl | 3.0/7.0 |
| I-32 | Q-6 | Vinyl | — | 8.0/0.0 |
| I-33 | Q-1 | Vinyl | — | 12.0/0.0 |

As to the cage-shaped silsesquioxane compound which is used in the invention, those which are available from Aldrich and Hybrid Plastics, Inc. may be used. Also, the cage-shaped silsesquioxane compound may be synthesized by a known process described in, for example, Polymers, 20, 67 to 85, 2008; Journal of Inorganic and Organometallic Polymers, 11(3), 123 to 154, 2001; Journal of Organometallic Chemistry, 542, 141 to 183, 1997; Journal of Macromolecular Science A. Chemistry, 44(7), 659 to 664, 2007; Chem. Rev., 95, 1409 to 1430, 1995; Journal of Inorganic and Organometallic Polymers, 11(3), 155 to 164, 2001; Dalton Transactions, 36 to 39, 2008; Macromolecules, 37(23), 8517 to 8522, 2004; and Chem. Mater, 8, 1250 to 1259, 1996.

[2] Polymer of silsesquioxane:

Physical properties of a polymer obtained using the foregoing silsesquioxane as a raw material and a production method thereof are hereunder described in detail.

Though a weight average molecular weight (Mw) of the polymer is not particularly limited, it is preferably from 1.0×10⁴ to 50×10⁴, more preferably from 3.5×10⁴ to 40×10⁴, and most preferably from 5.0×10⁴ to 35×10⁴.

Though a number average molecular weight (Mn) of the polymer is not particularly limited, it is preferably from 1.5×10⁴ to 35×10⁴, more preferably from 1.5×10⁴ to 20×10⁴, and most preferably from 2.5×10⁴ to 15×10⁴.

Though a (Z+1) average molecular weight (M_{Z+1}) of the polymer is not particularly limited, it is preferably from 1.5×10⁴ to 65×10⁴, more preferably from 2.5×10⁴ to 50×10⁴, and most preferably from 3.5×10⁴ to 35×10⁴.

By setting the weight average molecular weight and the number average molecular weight to the foregoing ranges, respectively, it is possible to form a film having a low refractive index, in which solubility in an organic solvent and filter filtration properties are enhanced, the generation of a particle at the storage can be suppressed, and surface properties of a coating film are improved.

From the viewpoints of solubility in an organic solvent, filter filtration properties and surface properties of a coating film, it is preferable that the polymer does not substantially contain a component having a molecular weight of 3,000,000 or more; it is more preferable that the polymer does not substantially a component having a molecular weight of 2,000,000 or more; and it is the most preferable that a component having a molecular weight of 1,000,000 or more.

An unreacted polymerizable group derived from the cage-shaped silsesquioxane compound remains in the polymer.

Among the polymerizable groups derived from the cage-shaped silsesquioxane compound, it is preferable that from 10 to 90 mol % of the polymerizable group remains in an unreacted state; it is more preferable that from 20 to 90 mol % of the polymerizable group remains in an unreacted state; and it is the most preferable that from 30 to 90 mol % of the polymerizable group remains in an unreacted state. When the amount of the polymerizable group remaining in an unreacted state in the polymer falls within the foregoing range, not only developability of a film formed from the photosensitive composition of the invention is sufficiently obtainable, but heat resistance, curing properties and mechanical strength of the resulting pattern film are more enhanced.

These can be determined from a ¹H-NMR spectrum or the like.

The foregoing polymer is a polymer composed mainly of a silsesquioxane constituted of one or two or more kinds of the cage-shaped silsesquioxane compound represented by the foregoing formula (1). Though a content of the polymerizable group in this polymer is not particularly limited, it is preferably from 5 to 90 mol %, more preferably from 10 to 90 mol %, and still more preferably from 10 to 80 mol % in the whole of organic groups bonded to the silicon atoms (namely, all of groups corresponding to R in the foregoing formula (1)). When the content of the polymerizable group in the polymer falls within the foregoing range, not only developability of a film formed from the photosensitive composition of the invention is sufficiently obtainable, but heat resistance and mechanical strength of the resulting pattern film are more enhanced. These can be determined from a ¹H-NMR spectrum or the like.

Incidentally, a structure derived from the cage-shaped silsesquioxane compound is contained in a proportion of preferably from 10 to 100% by mass, and more preferably from 20 to 100% by mass in the polymer. When the content of the structure derived from the cage-shaped silsesquioxane compound falls within the foregoing range, heat resistance, low refractive index properties and transparency of the resulting film are more enhanced.

Also, it is preferable that the polymer does not substantially have an aromatic group. According to this, it is possible to reveal excellent low refractive index properties more surely. Specifically, a content of the aromatic group is preferably 5 mol % or less, more preferably 3 mol % or less, and theoretically 0 mol % (namely, the polymer does not have an aromatic group), relative to the whole of organic groups bonded to the silicon atoms (namely, all of groups corresponding to R in the foregoing formula (1)).

The polymer may be used alone or in combination of two or more kinds thereof.

### <Production Method of Polymer>

A method for producing the polymer is not particularly limited so far as the polymerizable group derived from the cage-shaped silsesquioxane compound remains in the resulting polymer. Examples thereof include a polymerization reaction of a polymerizable group and a hydrosilylation reaction.

As the polymerization reaction of a polymerizable group, any polymerization reaction may be adopted. Examples thereof include radical polymerization, cationic polymerization, anionic polymerization, ring-opening polymerization, polycondensation, polyaddition, addition condensation and transition metal catalyst polymerization.

The hydrosilylation reaction can be, for example, performed by a method in which the foregoing cage-shaped silsesquioxane compound and in addition to this, a compound containing two or more SiH groups in a molecule thereof (for example, bis(dimethylsilyl)ethane, 1,1,3,3-tetramethyldisiloxane, etc.) are dissolved in an organic solvent (for example, toluene, xylene, etc.), to which is then added a catalyst (for example, platinum(0)-1,3-divinyl-1,1,3,3-tetramethyldisiloxane complex, etc.), and the mixture is heated at from 20 to 200° C.

As the method for producing the foregoing polymer, a polymerization reaction via a polymerizable group is preferable, and radical polymerization is the most preferable. Examples of the synthesis process include a batch polymerization process in which the foregoing silsesquioxane and an initiator are dissolved in a solvent, and the solution is heated to achieve polymerization; a dropwise addition polymerization process (continuous addition) in which the silsesquioxane is dissolved in a solvent and heated, and a solution of an initiator is added dropwise over from 1 to 10 hours; and a divided addition process (divided addition) in which an initiator is added in several divided portions. In view of the fact that film strength and molecular weight reproducibility are more improved, divided addition or continuous addition is preferable.

A reaction temperature of the polymerization reaction is in general from 0° C. to 200° C., preferably from 40° C. to 170° C., and more preferably from 80° C. to 160° C.

Also, in order to suppress inactivation of the polymerization initiator by an acid, it is preferable to perform the reaction in an inert gas atmosphere (for example, nitrogen, argon, etc.). An oxygen concentration at the reaction is preferably 100 ppm or less, more preferably 50 ppm or less and especially preferably 20 ppm or less.

A concentration of the silsesquioxane in the reaction solution at the polymerization is preferably 30% by mass or less, more preferably 20% by mass or less, still more preferably 15% by mass or less, and most preferably 10% by mass or less, relative to a total mass of the reaction solution. By setting the concentration of the silsesquioxane in the reaction solution at the polymerization to the foregoing range, the formation of impurities such as a gelled component can be suppressed.

As the solvent which is used in the foregoing polymerization reaction, any solvent may be used so far as not only it is able to dissolve the silsesquioxane therein in a necessary concentration, but it does not adversely affect characteristics of the film formed from the resulting polymer. In the following description, for example, an ester based solvent refers to a solvent having an ester group in a molecule thereof.

As the solvent, for example, solvents described in paragraph [0038] of JP-A-2008-218639 can be used.

Of these, ester based solvents, ether based solvents and aromatic hydrocarbon based solvents are preferable as the solvent. Specifically, ethyl acetate, propyl acetate, isopropyl acetate, butyl acetate, pentyl acetate, hexyl acetate, methyl propionate, propylene glycol monomethyl ether acetate, tetrahydrofuran, diphenyl ether, anisole, toluene, xylene, mesitylene or t-butylbenzene is preferable. Ethyl acetate, butyl acetate, diphenyl ether, anisole, mesitylene or t-butylbenzene is especially preferable. These solvents may be used alone or in admixture of two or more kinds thereof.

It is preferable that a boiling point of the solvent is 65° C. or higher because the reaction solution can be heated to a temperature necessary for decomposing the polymerization initiator at the reaction.

Of the foregoing solvents, in view of the facts that polymerization control of the resulting polymer is easy and that various characteristics of the resulting film are more excellent, it is especially preferable to use a solvent having a chain transfer constant (Cx) satisfying a relation of 0<Cx≦5.0×10⁴.

Also, in view of the facts that polymerization control of the resulting polymer is easy and that various characteristics of the resulting film are more excellent, an SP (solubility parameter) value of the solvent is preferably from 10 to 25 (MPa^{1/2}), and more preferably from 15 to 25 (MPa^{1/2}). Here, the SP value is a value obtained by a method described in, for example, Polymer Handbook Fourth Edition Volume 2 (A John Wiley & Sons, Inc., Publication), J. BRANDRUP, E. H. IMMERGUT and E. A. GRULKE (1999), pp. 675 to 714.

It is preferable that the polymerization reaction of the silsesquioxane is performed in the presence of a nonmetallic polymerization initiator. For example, the polymerization can be performed in the presence of a polymerization initiator capable of producing a free radical such as a carbon radical and an oxygen radical upon heating, thereby exhibiting activity.

In particular, an organic peroxide or an organic azo based compound is preferably used as the polymerization initiator. Compounds described in paragraphs [0033] to [0035] of JP-A-2008-239685 can be used as the organic peroxide or organic azo based compound.

In view of safety of a reagent itself and molecular weight reproducibility of the polymerization reaction, an organic azo based compound is preferable as the polymerization initiator. Above all, an azo ester compound such as V-601 in which a harmful cyano is not incorporated into a polymer is preferable.

A 10-hour half-life temperature of the polymerization initiator is preferably 100° C. or less. When the 10-hour half-life temperature is 100° C. or less, it is easy to allow the polymerization initiator not to remain at the termination of the reaction.

The polymerization initiator may be used alone or in admixture of two or more kinds thereof.

A use amount of the polymerization initiator is preferably from 0.0001 to 2 mol, more preferably from 0.003 to 1 mol, and especially preferably from 0.001 to 0.5 mol, per mol of the silsesquioxane.

By synthesizing the polymer under the foregoing condition, a polymer in which a polymerizable group derived from the cage-shaped silsesquioxane compound remains can be suitably obtained.

Also, in the resulting polymer, among the polymerizable groups derived from the cage-shaped silsesquioxane compound, it is possible to change the content of the polymerizable group remaining in an unreacted state by properly changing various conditions such as a reaction temperature of the polymerization reaction of the polymerizable group and a concentration of the silsesquioxane in the reaction solution at the polymerization.

Though the reaction solution after the polymerization reaction of the silsesquioxane may be used as a coating solution as it is, it is preferable to perform a purification treatment after the termination of the reaction. As a process of the purification, there can be applied usual processes such as a liquid-liquid extraction process in which residual monomers or oligomer components are removed by washing with water or combining adequate solvents; a purification process in a solution state in which only materials having a specified molecular weight or less are extracted and roved, such as ultrafiltration, centrifugation treatment and column chromatography; a reprecipitation process in which a polymer solution is added dropwise to a poor solvent to solidify a polymer in the poor solvent, and residual monomers and the like are removed; and a purification process in a solid state in which a polymer slurry separated by filtration is washed with a poor solvent.

For example, by bringing a solvent in which the foregoing polymer is sparingly soluble or insoluble (poor solvent) in a volume amount of 10 times or less, and preferably from 10 to 5 times that of the reaction solution into contact with a polymer-containing solution, the polymer is deposited as a solid. The solvent which is used at the precipitation or reprecipitation operation from the polymer solution (precipitation solvent or reprecipitation solvent) may be a poor solvent of the polymer. The solvent may be properly selected among hydrocarbons, halogenated hydrocarbons, nitro compounds, ethers, ketones, esters, carbonates, alcohols, carboxylic acids, water and mixed solvents containing of any of these solvents and used depending upon the type of the polymer. Of these, solvents containing at least an alcohol (particularly methanol, etc.) or water are preferable as the precipitation or reprecipitation solvent.

In order to prevent the polymerization from proceeding more than necessary, a polymerization inhibitor may be added to the polymer of a silsesquioxane and in a production step thereof. Examples of the polymerization inhibitor include 4-methoxyphenol, 2,6-bis(1,1-dimethylethyl)-4-methylphenol and catechol.

### [3] Photosensitive Composition:

The photosensitive composition of the invention contains a polymer obtained from the silsesquioxane constituted of one or two or more kinds the silsesquioxane compound represented by the foregoing prescribed average composition formula. However, as described previously, a polymerizable group derived from the foregoing cage-shaped silsesquioxane compound remains in the polymer.

Incidentally, the composition of the invention may be a solution having the polymer dissolved in a solvent (for example, an organic solvent) or may be a solid containing the polymer.

The composition of the invention can be used for various applications, and a content of the polymer or a type of an additive to be added is determined depending upon its purpose. Examples of the application of the composition of the invention include a film (for example, an insulating film), a low-refractive index film (for example, an antireflection film), a low-refractive index material, a gas adsorption material and a resist material. Above all, an insulating film or an antireflection film is preferable.

Though a content of the polymer in the composition is not particularly limited, when the polymer is used for the formation of a film as described later, the content of the polymer is preferably 50% by mass or more, more preferably 60% by mass or more, and most preferably 70% by mass or more, relative to the whole of solids. A maximum value of the content of the polymer is 99.9% by mass. When the content of the polymer in the solids is higher, a film having improved coating surface properties can be formed. Incidentally, the term “solids” as referred to herein means a solid component constituting a film as described later, and it does not include a solvent and the like.

The composition of the invention may contain a solvent. Namely, it is preferable for the polymer to be dissolved in an appropriate solvent and used upon being coated on a support.

The solvent is preferably a solvent capable of dissolving 5% by mass or more of the polymer therein at 25° C., and more preferably a solvent capable of dissolving 10% by mass or more of the polymer therein at 25° C. Specifically, solvents described in paragraph [0044] of JP-A-2008-214454 can be used.

Above all, preferred examples of the solvent which can be used include propylene glycol monomethyl ether acetate, propylene glycol monomethyl ether, 2-heptanone, cyclohexanone, γ-butyrolactone, ethylene glycol monomethyl ether, ethylene glycol monoethyl ether, ethylene glycol monoethyl ether acetate, propylene glycol monomethyl ether, propylene glycol monoethyl ether, ethylene carbonate, butyl acetate, methyl lactate, ethyl lactate, methyl methoxypropionate, ethyl ethoxypropionate, N-methylpyrrolidone, N,N-dimethylformamide, tetrahydrofuran, methyl isobutyl ketone, xylene, mesitylene and diisopropylbenzene.

In the case where the composition contains a solvent, a total solid concentration in the composition is preferably from 1 to 30% by mass relative to a total amount of the composition, and it is properly adjusted depending upon the use purpose. When the total solid concentration in the composition falls within the foregoing range, a thickness of the coating film falls within a suitable range, and the storage stability of the coating solution is more excellent.

It is preferable that a content of metals as impurities is sufficiently small in the composition. A metal concentration in the composition can be measured at a high sensitivity by means of an ICP-MS process or the like. In that case, the content of metals other than transition metals is preferably 300 ppm or less, and more preferably 100 ppm or less.

Each of the components of the photosensitive composition of the invention is hereunder described in detail.

[3-1] Polymerization initiator:

The composition of the invention contains (B) a photopolymerization initiator.

The photosensitive composition of the invention to which photosensitivity is imparted by incorporating the photopolymerization initiator (B) can be suitably used for a photoresist, a color resist, an optical coating material or the like. As the photopolymerization initiator, materials described below, which are known as a photopolymerization initiator, can be used.

The photopolymerization initiator is not particularly limited so far as it has ability to initiate polymerization of the residual polymerizable group of the polymer (A). The photopolymerization initiator can be properly selected among known photopolymerization initiators. For example, those having sensitivity to lights of from an ultraviolet light region to a visible light region are preferable. The photopolymerization initiator may be an activating agent capable of generating some kind of action with a light-excited sensitizer to emit an active radical, or may be an initiator capable of initiating cationic polymerization depending upon a type of monomer.

The photopolymerization initiator preferably contains at least one kind of a component having a molecular extinction coefficient of at least about 50 in the range of approximately from 200 to 800 nm (more preferably from 300 to 450 nm).

The photopolymerization initiator includes a radical photopolymerization initiator.

Examples of the radial photopolymerization initiator include halogenated hydrocarbon derivatives (for example, a halogenated hydrocarbon compound having a triazine skeleton and a halogenated hydrocarbon compound having an oxadiazole skeleton), hexaarylbiimidazole compounds, lophine dimers, benzoins, ketals, 2,3-dialkyldione compounds, organic peroxides, thio compounds, disulfide compounds, azo compounds, borate salts, inorganic complexes, coumarins, ketone compounds (benzophenones, thioxanthones, thiochromanones, anthraquinones), aromatic onium salts, fluoroamine compounds, ketoxime ethers, acetophenones (aminoacetophenone compound, hydroxyacetophenone compound), acylphosphine compounds such as acylphosphine oxide, and oxime compounds such as oxime derivative.

Examples of the halogenated hydrocarbon compound having a triazine skeleton include compounds described in Wakabayashi et al., Bull. Chem. Soc. Japan, 42, 2924 (1969), compounds described in Britain Patent 1388492, compounds described in JP-A-53-133428, compounds described in Germany Patent 3337024, compounds described in F. C. Schaefer et al., J. Org. Chem., 29, 1527 (1964), compounds described in JP-A-62-58241, compounds described in JP-A-5-281728, compounds described in JP-A-5-34920, and compounds described in U.S. Pat. No. 4,212,976.

The compounds described in U.S. Pat. No. 4,212,976 include, for example, a compound having an oxadiazole skeleton (e.g., 2-trichloromethyl-5-phenyl-1,3,4-oxadiazole,
2-trichloromethyl-5-(4-chlorophenyl)-1,3,4-oxadiazole,
2-trichloromethyl-5-(1-naphthyl)-1,3,4-oxadiazole,
2-trichloromethyl-5-(2-naphthyl)-1,3,4-oxadiazole,
2-tribromomethyl-5-phenyl-1,3,4-oxadiazole,
2-tribromomethyl-5-(2-naphthyl)-1,3,4-oxadiazole,
2-trichloromethyl-5-styryl-1,3,4-oxadiazole,
2-trichloromethyl-5-(4-chlorostyryl)-1,3,4-oxadiazole,
2-trichloromethyl-5-(4-methoxystyryl)-1,3,4-oxadiazole,
2-trichloromethyl-5-(1-naphthyl)-1,3,4-oxadiazole,
2-trichloromethyl-5-(4-n-buthoxystyryl)-1,3,4-oxadiazole,
2-tribromomethyl-5-styryl-1,3,4-oxadiazole).

Examples of the benzoins include benzoin, benzoin methyl ether, benzoin ethyl ether, benzoin isopropyl ether, benzyl dimethyl ketal, benzoin benzenesulfonic acid ester, benzoin toluenesulfonic acid ester, benzoin methyl ether, benzoin ethyl ether and benzoin isopropyl ether.

Examples of the borate salts include organoborate salt compounds described in Japanese Patent 2764769, JP-A-2002-116539 and Kunz, Martin, et al., Rad Tech' 98, Proceeding April, pp. 19-22 (1998, Chicago), and compounds described in paragraphs [0022] to [0027] of JP-A-2002-116539, supra. Specific examples of other organoboron compounds include organoboron transition metal coordination complexes described in JP-A-6-348011, JP-A-7-128785, JP-A-7-140589, JP-A-7-306527 and JP-A-7-292014. Specific examples thereof include ion complexes with a cationic dye.

Examples of the radical polymerization initiator other than those described above include acridine derivatives (e.g., 9-phenylacridine, 1,7-bis(9,9′-acridinyl)heptane), N-phenylglycine, polyhalogen compounds (e.g., carbon tetrabromide, phenyl tribromomethyl sulfone, phenyl trichloromethyl ketone), coumarins (e.g., 3-(2-benzofuroyl)-7-diethylaminocoumarin, 3-(2-benzofuroyl)-7-(1-pyrrolidinyl)coumarin, 3-benzoyl-7-diethylaminocoumarin, 3-(2-methoxybenzoyl)-7-diethylaminocoumarin, 3-(4-dimethylaminobenzoyl)-7-diethylaminocoumarin, 3,3′-carbonylbis(5,7-di-n-propoxycoumarin), 3,3′-carbonylbis(7-diethylaminocoumarin), 3-benzoyl-7-methoxycoumarin, 3-(2-furoyl)-7-diethylaminocoumarin, 3-(4-diethylaminocinnamoyl)-7-diethylaminocoumarin, 7-methoxy-3-(3-pyridylcarbonyl)coumarin, 3-benzoyl-5,7-dipropoxycoumarin, 7-benzotriazole-2-ylcoumarin, coumarin compounds described in JP-A-5-19475, JP-A-7-271028, JP-A-2002-363206, JP-A-2002-363207, JP-A-2002-363208 and JP-A-2002-363209), acylphosphine oxides (e.g., bis(2,4,6-trimethylbenzoyl)-phenylphosphine oxide, bis(2,6-dimethoxybenzoyl)-2,4,4-trimethyl-pentylphenylphosphine oxide, Lucirin TPO), metallocenes (e.g., bis(η5-2,4-chyclopentadien-1-yl)-bis(2,6-difluoro-3-(1H-pyrrol-1-yl)-phenyl)titanium, η5-cyclopentadienyl-η6-cumenyl-iron(1+)-hexafluorophosphate (1−)), and compounds described in JP-A-53-133428, JP-B-57-1819 (the term “JP-B” as used herein means an “examined Japanese patent publication”), JP-B-57-6096, and U.S. Pat. No. 3,615,455.

Examples of the ketone compounds include benzophenone, 2-methylbenzophenone, 3-methylbenzophenone, 4-methylbenzophenone, 4-methoxybenzophenone, 2-chlorobenzophenone, 4-chlorobenzophenone, 4-bromobenzophenone, 2-carboxybenzophenone, 2-ethoxycarbonylbenzophenone, benzophenone tetracarboxylic acids and tetramethyl esters thereof, 4,4′-bis(dialkylamino)benzophenones (e.g., 4,4′-bis(dimethylamino)benzophenone, 4,4′-bis(dicyclohexylamino)benzophenone, 4,4′-bis(diethylamino)benzophenone, 4,4′-bis(dihydroxyethylamino)benzophenone, 4-methoxy-4′-dimethylaminobenzophenone, 4,4′-dimethoxybenzophenone, 4-dimethylaminobenzophenone, 4-dimethylaminoacetophenone, benzyl, anthraquinone, 2-tert-butylanthraquinone, 2-methylanthraquinone, phenanthraquinone, xanthone, thioxanthone, 2-chloro-thioxanthone, 2,4-diethylthioxanthone, fluorenone, 2-benzyl-dimethylamino-1-(4-morpholinophenyl)-1-butanone, 2-methyl-1-[4-(methylthio)phenyl]-2-morpholino-1-propanone, 2-hydroxy-2-methyl-[4-(1-methylvinyl)phenyl]propanol oligomer, benzoin, benzoin ethers (e.g., benzoin methyl ether, benzoin ethyl ether, benzoin propyl ether, benzoin isopropyl ether, benzoin phenyl ether, benzyl dimethyl ketal), acridone, chloroacridone, N-methylacridone, N-butylacridone, and N-butyl-chloroacridone.

The radical polymerization initiator is more preferably a compound selected from the group consisting of an aminoacetophenone compound, a hydroxyacetophenone compound, an acylphosphine compound and an oxime compound. More specifically, for example, an aminoacetophenone-based initiator described in JP-A-10-291969, an acylphosphine oxide-based initiator described in Japanese Patent 4225898, and the oxime-based initiator as mentioned above may be used, and furthermore, compounds described in JP-A-2001-233842 may be also used as an oxime-based initiator.

As the aminoacetophenone-based initiator, commercial products IRGACURE-907, IRGACURE-369 and IRGACURE-379 (trade names, all produced by Ciba Japan) may be used. As the acylphosphine-based initiator, commercial products IRGACURE-819 and DAROCUR-TPO (trade names, both produced by Ciba Japan) may be used.

The hydroxyacetophenone compound is preferably a compound represented by the following formula (V):

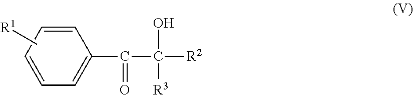

In formula (V), R¹ represents a hydrogen atom, an alkyl group (preferably an alkyl group having a carbon number of 1 to 10), an alkoxy group (preferably an alkoxy group having a carbon number of 1 to 10), or a divalent organic group. In the case where R¹ is a divalent organic group, the compound is a dimer where two photoactive hydroxyacetophenone structures (that is, a structure formed by removing the substituent R¹ from the compound represented by formula (V)) are connected through R¹. Each of R² and R³ independently represents a hydrogen atom or an alkyl group (preferably an alkyl group having a carbon number of 1 to 10). R² and R³ may combine to form a ring (preferably a ring having a carbon number of 4 to 8).

The alkyl group and alkoxy group as R¹, the alkyl group as R² and R³, and the ring formed by combining R² and R³ may further have a substituent.

Examples of the hydroxyacetophenone compound include 2-hydroxy-2-methyl-1-phenylpropan-1-one (DAROCURE 1173), 2-hydroxy-2-methyl-1-phenylbutan-1-one, 1-(4-methylphenyl)-2-hydroxy-2-methylpropan-1-one, 1-(4-isopropylphenyl)-2-methylpropan-1-one, 1-(4-butylphenyl)-2-hydroxy-2-methylpropan-1-one, 2-hydroxy-2-methyl-1-(4-octylphenyl)propan-1-one, 1-(4-dodecylphenyl)-2-methylpropan-1-one, 1-(4-methoxyphenyl)-2-methylpropan-1-one, 1-(4-methylthiophenyl)-2-methylpropan-1-one, 1-(4-chlorophenyl)-2-hydroxy-2-methylpropan-1-one, 1-(4-bromophenyl)-2-hydroxy-2-methylpropan-1-one, 2-hydroxy-1-(4-hydroxyphenyl)-2-methylpropan-1-one, 1-(4-dimethylaminophenyl)-2-hydroxy-2-methylpropan-1-one, 1-(4-carboethoxyphenyl)-2-hydroxy-2-methylpropan-1-one, 1-hydroxycyclohexylphenyl ketone (IRGACURE 184) and 1-[4-(2-hydroxyethoxy)-phenyl)]-2-hydroxy-2-methyl-1-propan-1-one (IRGACURE 2959).

Also, as the commercially available α-hydroxyacetophenone compound, polymerization initiators available from Ciba Specialty Chemicals under trade names of IRGACURE 184, DAROCURE 1173, IRGACURE 127, IRGACURE 2959, IRGACURE 1800, IRGACURE 1870 and DAROCURE 4265 may be used.

As the acylphosphine-based initiator, commercial products IRGACURE-819, IRGACURE-819DW and DAROCUR-TPO (trade names. all produced by Ciba Japan) may be used. Furthermore, a phosphine-based initiator described in JP-A-2009-134098 is also applicable.

From the viewpoints of sensitivity and curing speed, the photopolymerization initiator in the invention is most preferably an oxime compound such as oxime derivatives. The oxime compound is not particularly limited, and examples thereof include oxime based compounds described in JP-A-2000-80068 (paragraphs [0004] to [0296]), WO02/100903A1, JP-A-2001-233842, JP-A-2006-342166 (paragraphs [0004] to [0264]), etc.

Specific examples thereof include 2-(O-benzoyloxime)-1-[4-(phenylthio)phenyl]-1,2-butanedione, 2-(O-benzoyloxime)-1-[4-(phenylthio)phenyl]-1,2-pentanedione, 2-(O-benzoyloxime)-1-[4-(phenylthio)phenyl]-1,2-hexanedione, 2-(O-benzoyloxime)-1-[4-(phenylthio)phenyl]-1,2-heptanedione, 2-(O-benzoyloxime)-1-[4-(phenylthio)phenyl]-1,2-octanedione, 2-(O-benzoyloxime)-1-[4-(methylphenylthio)phenyl]-1,2-butanedione, 2-(O-benzoyloxime)-1-[4-(ethylphenylthio)phenyl]-1,2-butanedione, 2-(O-benzoyloxime)-1-[4-(butylphenylthio)phenyl]-1,2-butanedione, 1-(O-acetyloxime)-1-[9-ethyl-6-(2-methylbenzoyl)-9H-carbazol-3-yl]ethanone, 1-(O-acetyloxime)-1-[9-methyl-6-(2-methylbenzoyl)-9H-carbazol-3-yl]ethanone, 1-(O-acetyloxime)-1-[9-propyl-6-(2-methylbenzoyl)-9H-carbazol-3-yl]ethanone, 1-(O-acetyloxime)-1-[9-ethyl-6-(2-ethylbenzoyl)-9H-carbazol-3-yl]ethanone and 1-(O-acetyloxime)-1-[9-ethyl-6-(2-butylbenzoyl)-9H-carbazol-3-yl]ethanone. However, it should not be construed that the invention is limited thereto.

Of these, from the viewpoints of exposure amount, pattern shape, development residue, stability with time and coloration at the post-heating, oxime-O-acyl based compounds such as 2-(O-benzoyloxime)-1-[4-(phenylthio)phenyl]-1,2-octanedione and 1-(O-acetyloxime)-1-[9-ethyl-6-(2-methylbenzoyl)-9H-carbazol-3-yl]ethanone are especially preferable. Specifically, CGI-124 and CGI-242 (all of which are manufactured by Ciba Specialty Chemicals Inc.) and the like are preferable.

Furthermore, cyclic oxime compounds described in JP-A-2007-231000 and JP-A-2007-322744 may be also suitably used.

Most preferred oxime compounds include an oxime compound having a specific substituent described in JP-A-2007-269779 and an oxime compound having a thioaryl group described in JP-A-2009-191061.

Specifically, the oxime compound is preferably a compound represented by the following formula (I). Incidentally, the oxime compound may be an oxime compound where the N—O bond of the oxime bond is an (E) form, an oxime compound where the bond is a (Z) form, or a mixture of a (E) form and a (Z) form.

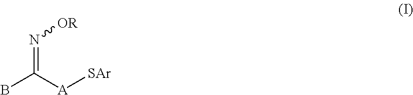

(In formula (I), each of R and B independently represents a monovalent substituent, A represents a divalent organic group, and Ar represents an aryl group.)

The monovalent substituent represented by R is preferably a monovalent nonmetallic atomic group.

Examples of the monovalent nonmetallic atomic group include an alkyl group, an aryl group, an acyl group, an alkoxycarbonyl group, an aryloxycarbonyl group, a heterocyclic group, an alkylthiocarbonyl group, and an arylthiocarbonyl group. These groups may have one or more substituents. The substituent may be further substituted with another substituent.

Examples of the substituent include a halogen atom, an aryloxy group, an alkoxycarbonyl group, an aryloxycarbonyl group, an acyloxy group, an acyl group, an alkyl group and an aryl group.

The alkyl group which may have a substituent is preferably an alkyl group having a carbon number of 1 to 30, and specific examples thereof include a methyl group, an ethyl group, a propyl group, a butyl group, a hexyl group, an octyl group, a decyl group, a dodecyl group, an octadecyl group, an isopropyl group, an isobutyl group, a sec-butyl group, a tert-butyl group, a 1-ethylpentyl group, a cyclopentyl group, a cyclohexyl group, a trifluoromethyl group, a 2-ethylhexyl group, a phenacyl group, a 1-naphthoylmethyl group, a 2-naphthoylmethyl group, a 4-methylsulfanylphenacyl group, a 4-phenylsulfanylphenacyl group, a 4-dimethylaminophenacyl group, a 4-cyanophenacyl group, a 4-methylphenacyl group, a 2-methylphenacyl group, a 3-fluorophenacyl group, a 3-trifluoromethylphenacyl group, and a 3-nitrophenacyl group.

The aryl group which may have a substituent is preferably an aryl group having a carbon number of 6 to 30, and specific examples thereof include a phenyl group, a biphenyl group, a 1-naphthyl group, a 2-naphthyl group, a 9-anthryl group, a 9-phenanthryl group, a 1-pyrenyl group, a 5-naphthacenyl group, a 1-indenyl group, a 2-azulenyl group, a 9-fluorenyl group, a terphenyl group, a quaterphenyl group, an o-, m- or p-tolyl group, a xylyl group, an o-, m- or p-cumenyl group, a mesityl group, a pentalenyl group, a binaphthalenyl group, a ternaphthalenyl group, a quaternaphthalenyl group, a heptalenyl group, a biphenylenyl group, an indacenyl group, a fluoranthenyl group, an acenaphthylenyl group, an aceanthrylenyl group, a phenalenyl group, a fluorenyl group, an anthryl group, a bianthracenyl group, a teranthracenyl group, a quateranthracenyl group, an anthraquinolyl group, a phenanthryl group, a triphenylenyl group, a pyrenyl group, a chrysenyl group, a naphthacenyl group, a pleiadenyl group, a picenyl group, a perylenyl group, a pentaphenyl group, a pentacenyl group, a tetraphenylenyl group, a hexaphenyl group, a hexacenyl group, a rubicenyl group, a coronenyl group, a trinaphthylenyl group, a heptaphenyl group, a heptacenyl group, a pyranthrenyl group, and an ovalenyl group.

The acyl group which may have a substituent is preferably an acyl group having a carbon number of 2 to 20, and specific examples thereof include an acetyl group, a propanoyl group, a butanoyl group, a trifluoroacetyl group, a pentanoyl group, a benzoyl group, a 1-naphthoyl group, a 2-naphthoyl group, a 4-methylsulfanylbenzoyl group, a 4-phenylsulfanylbenzoyl group, a 4-dimethylaminobenzoyl group, a 4-diethylaminobenzoyl group, a 2-chlorobenzoyl group, a 2-methylbenzoyl group, a 2-methoxybenzoyl group, a 2-butoxybenzoyl group, a 3-chlorobenzoyl group, a 3-trifluoromethylbenzoyl group, a 3-cyanobenzoyl group, a 3-nitrobenzoyl group, a 4-fluorobenzoyl group, a 4-cyanobenzoyl group, and a 4-methoxybenzoyl group.

The alkoxycarbonyl group which may have a substituent is preferably an alkoxycarbonyl group having a carbon number of 2 to 20, and specific examples thereof include a methoxycarbonyl group, an ethoxycarbonyl group, a propoxycarbonyl group, a butoxycarbonyl group, a hexyloxycarbonyl group, an octyloxycarbonyl group, a decyloxycarbonyl group, an octadecyloxycarbonyl group, and a trifluoromethyloxycarbonyl group.

Specific examples of the aryloxycarbonyl group which may have a substituent include a phenoxycarbonyl group, a 1-naphthyloxycarbonyl group, a 2-naphthyloxycarbonyl group, a 4-methylsulfanylphenyloxycarbonyl group, a 4-phenylsulfanylphenyloxycarbonyl group, a 4-dimethylaminophenyloxycarbonyl group, a 4-diethylaminophenyloxycarbonyl group, a 2-chlorophenyloxycarbonyl group, a 2-methylphenyloxycarbonyl group, a 2-methoxyphenyloxycarbonyl group, a 2-butoxyphenyloxycarbonyl group, a 3-chlorophenyloxycarbonyl group, a 3-trifluoromethylphenyloxycarbonyl group, a 3-cyanophenyloxycarbonyl group, a 3-nitrophenyloxycarbonyl group, a 4-fluorophenyloxycarbonyl group, a 4-cyanophenyloxycarbonyl group, and a 4-methoxyphenyloxycarbonyl group.

The heterocyclic group which may have a substituent is preferably an aromatic or aliphatic heterocyclic ring containing a nitrogen atom, an oxygen atom, a sulfur atom or a phosphorus atom.

Specific examples thereof include a thienyl group, a benzo[b]thienyl group, a naphtho[2,3-b]thienyl group, a thianthrenyl group, a furyl group, a pyranyl group, an isobenzofuranyl group, a chromenyl group, a xanthenyl group, a phenoxathiinyl group, a 2H-pyrrolyl group, a pyrrolyl group, an imidazolyl group, a pyrazolyl group, a pyridyl group, a pyrazinyl group, a pyrimidinyl group, a pyridazinyl group, an indolizinyl group, an isoindolyl group, a 3H-indolyl group, an indolyl group, a 1H-indazolyl group, a purinyl group, a 4H-quinolidinyl group, an isoquinolyl group, a quinolyl group, a phthalazinyl group, a naphthyridinyl group, a quinoxalinyl group, a quinazolinyl group, a cinnolinyl group, a pteridinyl group, a 4aH-carbazolyl group, a carbazolyl group, a β-carbolinyl group, a phenanthridinyl group, an acridinyl group, a perimidinyl group, a phenanthrolinyl group, a phenazinyl group, a phenarsazinyl group, an isothiazolyl group, a phenothiazinyl group, an isoxazolyl group, a furazanyl group, a phenoxazinyl group, an isochromanyl group, a chromanyl group, a pyrrolidinyl group, a pyrrolinyl group, an imidazolidinyl group, an imidazolinyl group, a pyrazolidinyl group, a pyrazolinyl group, a piperidyl group, a piperazinyl group, an indolinyl group, an isoindolinyl group, a quinuclidinyl group, a morpholinyl group, and a thioxanthryl group.

Specific examples of the alkylthiocarbonyl group which may have a substituent include a methylthiocarbonyl group, a propylthiocarbonyl group, a butylthiocarbonyl group, a hexylthiocarbonyl group, an octylthiocarbonyl group, a decylthiocarbonyl group, an octadecylthiocarbonyl group, and a trifluoromethylthiocarbonyl group.

Specific examples of the arylthiocarbonyl group which may have a substituent include a 1-naphthylthiocarbonyl group, a 2-naphthylthiocarbonyl group, a 4-methylsulfanylphenylthiocarbonyl group, a 4-phenylsulfanylphenylthiocarbonyl group, a 4-dimethylaminophenylthiocarbonyl group, a 4-diethylaminophenylthiocarbonyl group, a 2-chlorophenylthiocarbonyl group, a 2-methylphenylthiocarbonyl group, a 2-methoxyphenylthiocarbonyl group, a 2-butoxyphenylthiocarbonyl group, a 3-chlorophenylthiocarbonyl group, a 3-trifluoromethylphenylthiocarbonyl group, a 3-cyanophenylthiocarbonyl group, a 3-nitrophenylthiocarbonyl group, a 4-fluorophenylthiocarbonyl group, a 4-cyanophenylthiocarbonyl group, and a 4-methoxyphenylthiocarbonyl group.

The monovalent substituent represented by B is an aryl group, a heterocyclic group, an arylcarbonyl group, or a heterocyclic carbonyl group. These groups may have one or more substituents. Examples of the substituent include the substituents described above. Also, the above-described substituent may be further substituted with another substituent.

Above all, the structures shown below are preferred.

In the structures, Y, X and n have the same meanings as Y, X and n in Formula (II) described later, and preferred examples are also the same.

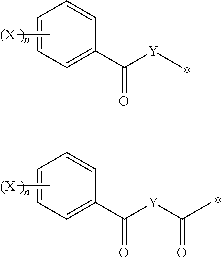

The divalent organic group represented by A include an alkylene group having a carbon number of 1 to 12, a cyclohexylene group having a carbon number of 6 to 12, and an alkynylene group having a carbon number of 2 to 12. These groups may have one or more substituents. Examples of the substituent include the substituents described above. Also, the above-described substituent may be further substituted with another substituent.

Above all, from the standpoint of increasing the sensitivity and suppressing the coloration by heating or with aging, A is preferably an unsubstituted alkylene group, an alkyl group (e.g. methyl group, ethyl group, tert-butyl group, dodecyl group)-substituted alkylene group, an alkenyl group (e.g. vinyl group, allyl group)-substituted alkylene group, or an aryl group (e.g. phenyl group, p-tolyl group, xylyl group, cumenyl group, naphthyl group, anthryl group, phenanthryl group, styryl group)-substituted alkylene group.

The aryl group represented by Ar is preferably an aryl group having a carbon number of 6 to 30 and may have a substituent. Examples of the substituent are the same as those of the substituent introduced into a substituted aryl group described as a specific example of the aryl group which may have a substituent.

Among these, from the viewpoint of increasing the sensitivity and suppressing the coloration by heating or aging, a substituted or unsubstituted phenyl group is preferred.

In formula (I), in view of sensitivity, the structure of “SAr” formed by Ar and S adjacent thereto is preferably a structure shown below. Me represents a methyl group, and Et represents an ethyl group.

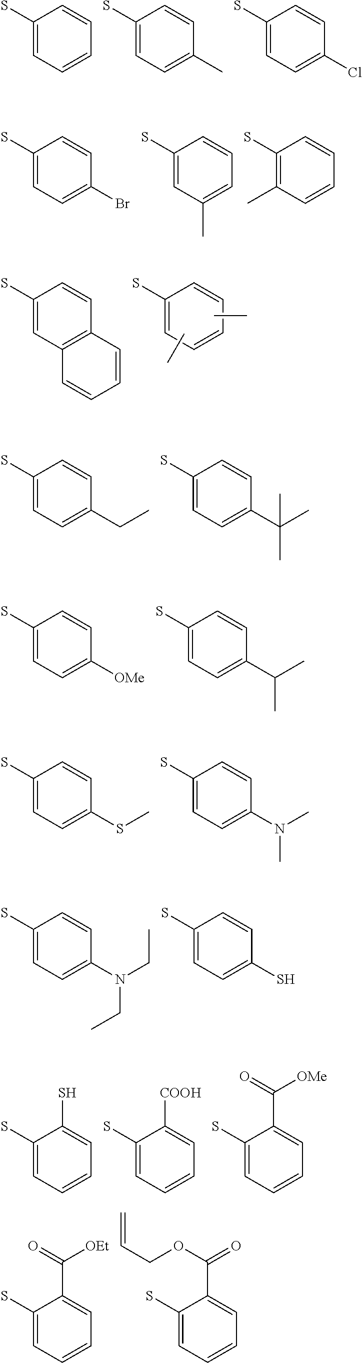

The oxime compound is preferably a compound represented by the following formula (II):

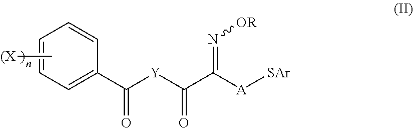

(In formula (II), each of R and X independently represents a monovalent substituent, each of A and Y independently represents a divalent organic group, Ar represents an aryl group, and n is an integer of 0 to 5.)

In formula (II), R, A and Ar have the same meanings as R, A and Ar in formula (I), and preferred examples are also the same.

The monovalent substituent represented by X includes an alkyl group, an aryl group, an alkoxy group, an aryloxy group, an acyloxy group, an acyl group, an alkoxycarbonyl group, an amino group, a heterocyclic group, and a halogen atom. These groups may have one or more substituents. Examples of the substituent include the substituents described above. The above-described substituents may be further substituted with another substituent.

Among these, X is preferably an alkyl group from the standpoint of enhancing solvent solubility and absorption efficiency in the long wavelength region.

In formula (II), n represents an integer of 0 to 5 and is preferably an integer of 0 to 2.

The divalent organic group represented by Y includes the structures shown below. In the groups shown below, “*” indicates the bonding position to the carbon atom adjacent to Yin formula (II).

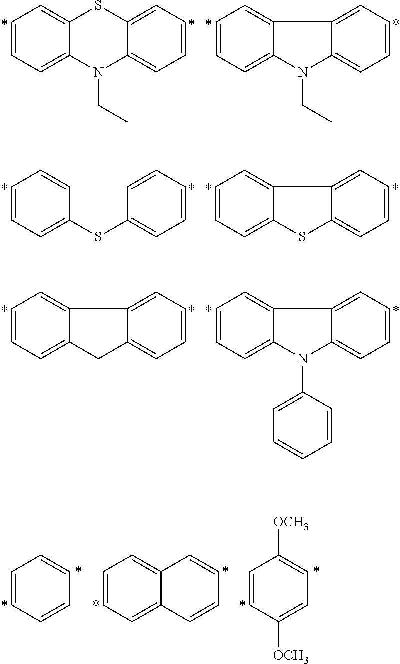

Among these, the structures shown below are preferred from the standpoint of increasing the sensitivity.

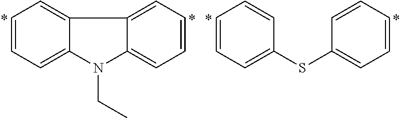

Furthermore, the oxime compound is preferably a compound represented by the following formula (III):

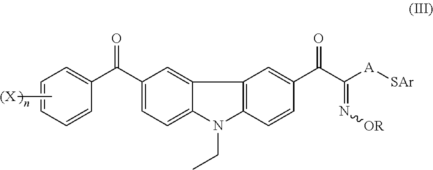

(In formula (III), each of R and X independently represents a monovalent substituent, A represents a divalent organic group, Ar represents an aryl group, and n is an integer of 0 to 5.)

In formula (III), R, X, A, Ar and n have the same meanings as R, X, A, Ar and n in formula (II), and preferred examples are also the same.

Specific examples (B-1) to (B-10) of the oxime compound which is suitably used are illustrated below, but the present invention is not limited thereto.

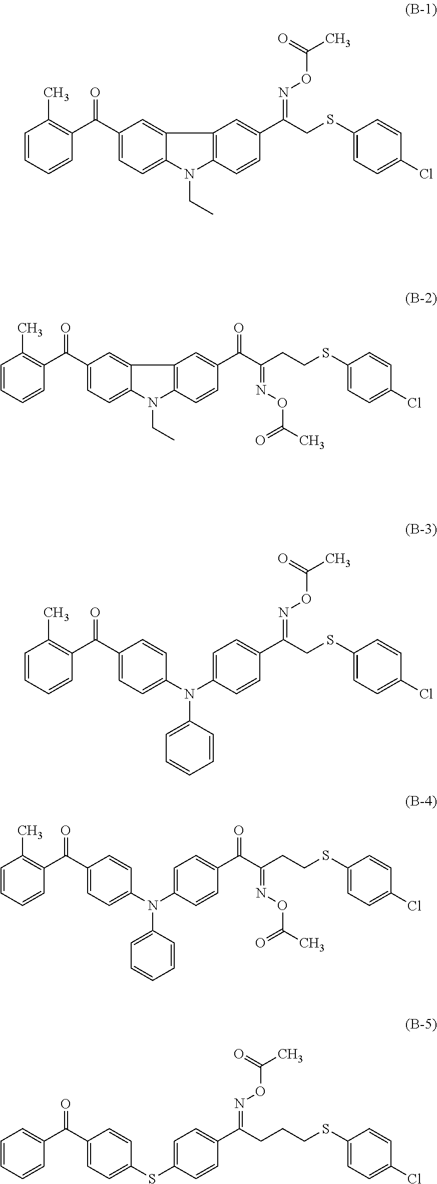

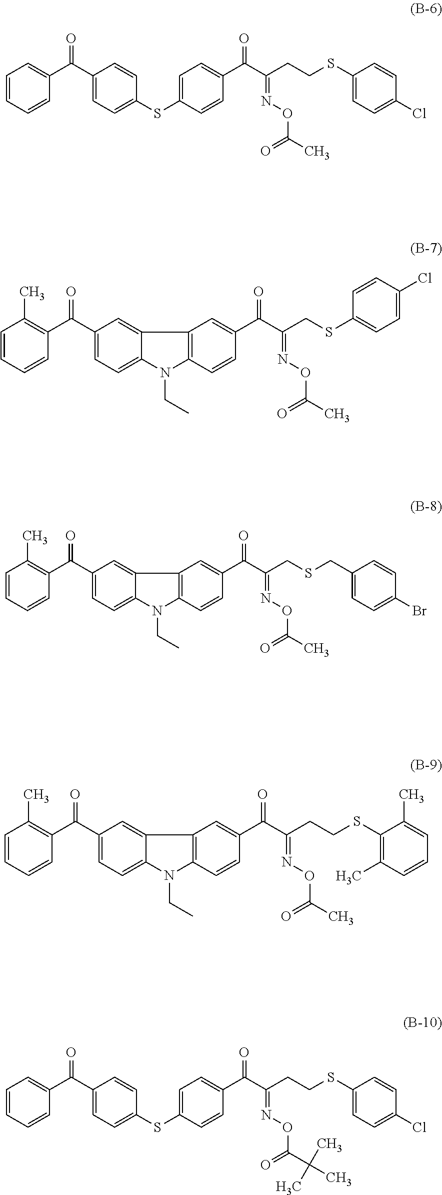

The oxime compound is a compound having a maximum absorption wavelength in the wavelength region of 350 to 500 nm, preferably a compound having an absorption wavelength in the wavelength region of 360 to 480 nm, more preferably a compound having high absorbance at 365 nm and 405 nm.

In view of sensitivity, the molar extinction coefficient at 365 nm or 405 nm of the oxime compound is preferably from 3,000 to 300,000, more preferably 5,000 to 300,000, still more preferably from 10,000 to 200,000.

The molar extinction coefficient of the compound may be measured by a known method but is preferably measured, for example, by using, specifically, an ultraviolet-visible spectrophotometer (Carry-5 spectrophotometer manufactured by Varian) with an ethyl acetate solvent at a concentration of 0.01 g/L.

A content of the photopolymerization initiator in the solids of the composition of the invention is in general from 1% by mass to 40% by mass, preferably from 2% by mass to 30% by mass, and more preferably from 2% by mass to 15% by weight.

[3-2] Polymerizable compound: The composition of the invention may further contain a polymerizable compound different from the polymer (A).

When the composition of the invention contains a polymerizable compound, solvent resistance, dimensional uniformity and hardness of the pattern film tend to be more enhanced.

The polymerizable compound is an addition polymerizable compound having at least one ethylenically unsaturated double bond and is selected among compounds having at least one, and preferably two or more terminal ethylenically unsaturated double bonds.

Such a compound is widely known in the industrial field in the art, and those compounds can be used in the invention without particular limitations.

These compounds have a chemical form, for example, a monomer, a prepolymer (namely a dimer, a trimer or an oligomer) and a mixture or copolymer thereof. Examples of the monomer and its copolymer include unsaturated carboxylic acids (for example, acrylic acid, methacrylic acid, itaconic acid, crotonic acid, isocrotonic acid, maleic acid, etc.) and esters or amides thereof. Of these, esters of an unsaturated carboxylic acid and an aliphatic polyhydric alcohol compound and amides of an unsaturated carboxylic acid and an aliphatic polyvalent amine compound are preferably used. Also, addition reaction products of an unsaturated carboxylic acid ester or an amide having a nucleophilic substituent (for example, a hydroxyl group, an amino group, a mercapto group, etc.) and a monofunctional or polyfunctional isocyanate or epoxy; dehydration condensation reaction products of an unsaturated carboxylic acid ester or amide having a nucleophilic substituent (for example, a hydroxyl group, an amino group, a mercapto group, etc.) and a monofunctional or polyfunctional carboxylic acid; and the like are favorably used. Also, addition reaction products of an unsaturated carboxylic acid ester or an amide having an electrophilic substituent (for example, an isocyanate group, an epoxy group, etc.) and a monofunctional or polyfunctional alcohol, amine or thiol are suitable. Furthermore, displacement reaction products of an unsaturated carboxylic acid ester or an amide having a leaving substituent (for example, a halogen group, a tosyloxy group, etc.) and a monofunctional or polyfunctional alcohol, amine or thiol are also suitable. As other examples, a group of compounds obtained by substituting the foregoing unsaturated carboxylic acids with an unsaturated phosphonic acid, styrene, vinyl ether, etc. can be used, too.

Specific examples of the monomer of an ester of an aliphatic polyhydric alcohol compound and an unsaturated carboxylic acid include an acrylic acid ester, a methacrylic acid ester and an itaconic acid ester.

Examples of the acrylic acid ester include ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri(acryloyloxyethyl)isocyanurate, polyester acrylate oligomers and isocyanuric acid EO-modified triacrylate.

Examples of the methacrylic acid ester include tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethylmethane and bis[p-(methacryloxyethoxy)phenyl] dimethylmethane.

Examples of the itaconic acid ester include ethylene glycol diitaconate, propylene glycol diitaconate, 1,3-butanediol diitaconate, 1,4-butanediol diitaconate, tetramethylene glycol diitaconate, pentaerythritol diitaconate and sorbitol tetraitaconate. Examples of crotonic acid esters include ethylene glycol dicrotonate, tetramethylene glycol dicrotonate, pentaerythritol dicrotonate and sorbitol tetradicrotonate. Examples of isocrotonic acid esters include ethylene glycol diisocrotonate, pentaerythritol diisocrotonate and sorbitol tetraisocrotonate. Examples of maleic acid esters include ethylene glycol dimaleate, triethylene glycol dimaleate, pentaerythritol dimaleate and sorbitol tetramaleate.

As examples of other esters, for example, aliphatic alcohol based esters described in JP-B-51-47334 and JP-A-57-196231; esters having an aromatic skeleton described in JP-A-59-5240, JP-A-59-5241 and JP-A-2-226149; and esters having an amino group described in JP-A-1-165613 are also suitably used. Furthermore, the foregoing ester monomers can also be used as a mixture.

Furthermore, an acid group-containing monomer can also be used. Examples thereof include (meth)acrylic acid, pentaerythritol triacrylate succinic acid monoester, dipentaerythritol pentaacrylate succinic acid monoester, pentaerythritol triacrylate maleic acid monoester, dipentaerythritol pentaacrylate maleic acid monoester, pentaerythritol triacrylate phthalic acid monoester, dipentaerythritol pentaacrylate phthalic acid monoester, pentaerythritol triacrylate tetrahydrophthalic acid monoester and dipentaerythritol pentaacrylate tetrahydrophthalic acid monoester. In particular, pentaerythritol triacrylate succinic acid monoester is preferable from the viewpoints of developability and sensitivity.

Also, specific examples of monomers of an amide of an aliphatic polyvalent amine compound and an unsaturated carboxylic acid include methylene bisacrylamide, methylene bismethacrylamide, 1,6-hexamethylene bisacrylamide, 1,6-hexamethylene bismethacrylamide, diethylene triamine trisacrylamide, xylylene bisacrylamide and xylylene bismethacrylamide. As examples of other preferred amide based monomers, those having a cyclohexylene structure described in JP-B-54-21726 can be exemplified.

Also, urethane based addition polymerizable compounds produced through an addition reaction of an isocyanate and a hydroxyl group are suitable, too. Specific examples thereof include vinyl urethane compounds containing two or more polymerizable vinyl groups in one molecule thereof, which are obtained by adding a hydroxyl group-containing vinyl monomer represented by the following general formula to a polyisocyanate compound having two or more isocyanate groups in one molecule thereof, as described in JP-B-48-41708.

CH₂═C(R¹⁰)COOCH₂CH(R¹¹)OH

In the foregoing general formula, each of R¹⁰ and R¹¹ represents H or CH₃.

Also, urethane acrylates described in JP-A-51-37193, JP-B-2-32293 and JP-B-2-16765; and urethane compounds having an ethylene oxide based skeleton described in JP-B-58-49860, JP-B-56-17654, JP-B-62-39417 and JP-B-62-39418 are suitable, too. Furthermore, by using an addition polymerizable compound having an amino structure or a sulfide structure in a molecule thereof as described in JP-A-63-277653, JP-A-63-260909 and JP-A-1-105238, a photopolymerizable composition which is very excellent in photosensitive speed can be obtained.

As other examples, polyester acrylates described in JP-A-48-64183, JP-B-49-43191 and JP-B-52-30490; and polyfunctional acrylates or methacrylates obtained by allowing an epoxy resin and (meth)acrylic acid to react with each other can be exemplified. Also, specified unsaturated compounds described in JP-B-46-43946, JP-B-1-40337 and JP-B-1-40336; and vinyl sulfonic acid based compounds described in JP-A-2-25493 can be exemplified, too. Also, in some cases, structures containing a perfluoroalkyl group described in JP-A-61-22048 are suitably used, too. Furthermore, compounds presented as photocurable monomers and oligomers in Journal of the Adhesion Society of Japan, Vol. 20, No. 7, pages 300 to 308 (1984) can be used.

With respect to such a polymerizable compound, details of a use method regarding its structure, single use or joint use and addition amount, etc. can be arbitrarily set in conformity with a performance design of the composition. For example, they are selected from the following viewpoints.

From the standpoint of sensitivity, a structure in which a content of an unsaturated group per molecule is high is preferable. In many cases, a bifunctional or more functional structure is preferable. Also, in order to increase the strength of an image area, namely a pattern film, a trifunctional or more functional structure is preferable. Furthermore, a method in which a compound having a different functionality or a different polymerizable group (for example, acrylic acid esters, methacrylic acid esters, styrene based compounds or vinyl ether based compounds) is used jointly, thereby adjusting both sensitivity and strength is efficient, too. From the viewpoint of curing sensitivity, it is preferable to use a compound containing two or more (meth)acrylic acid ester structures; it is more preferable to use a compound containing three or more (meth)acrylic acid ester structures; and it is the most preferable to use a compound containing four or more (meth)acrylic acid ester structures. Also, from the viewpoints of curing sensitivity and developability of an unexposed area, a compound containing a carboxylic acid group or an EO-modified product structure is preferable. Also, from the viewpoints of curing sensitivity and strength of an exposed area, it is preferable that a urethane bond is contained.

Also, the selection and use method of the polymerizable compound are an important factor relative to compatibility with other components (for example, a resin, a photopolymerization initiator or a pigment) in the composition and dispersibility. For example, there may be the case where the compatibility can be enhanced by use of a low-purity compound or joint use of two or more kinds. Also, a specified structure may be selected for the purpose of enhancing adhesion to a substrate or the like.

From the foregoing viewpoints, there are preferably exemplified bisphenol A diacrylate, a bisphenol A diacrylate EO-modified product, trimethylolpropane triacrylate, trimethylolpropane tri(acryloyloxypropyl)ether, trimethylolethane triacrylate, tetraethylene glycol diacrylate, pentaerythritol diacrylate, pentaerythritol triacrylate, pentaerythritol tetraacrylate, dipentaerythritol tetraacrylate, dipentaerythritol pentaacrylate, dipentaerythritol hexaacrylate, sorbitol triacrylate, sorbitol tetraacrylate, sorbitol pentaacrylate, sorbitol hexaacrylate, tri(acryloyloxyethyl) isocyanurate, a pentaerythritol tetraacrylate EO-modified product, a dipentaerythritol hexaacrylate EO-modified product and pentaerythritol triacrylate succinic acid monoester. Also, as commercially available products, urethane oligomers including UAS-10 and UAB-140 (all of which are manufactured by Sanyo-Kokusaku Pulp Co., Ltd.); DPHA-40H (manufactured by Nippon Kayaku Co., Ltd.); and UA-306H, UA-306T, UA-3061, AH-600, T-600 and AI-600 (all of which are manufactured by Kyoeisha Chemical Co., Ltd.); and UA-7200 (manufactured by Shin-Nakamura Chemical Co., Ltd.) are preferable.

Of these, a bisphenol A diacrylate EO-modified product, pentaerythritol triacrylate, pentaerythritol tetraacrylate, dipentaerythritol pentaacrylate, dipentaerythritol hexaacrylate, tri(acryloyloxyethyl)isocyanurate, a pentaerythritol tetraacrylate EO-modified product, a dipentaerythritol hexaacrylate EO-modified product and pentaerythritol triacrylate succinic acid monoester; and DPHA-40H (manufactured by Nippon Kayaku Co., Ltd.) and UA-306H, UA-306T, UA-3061, AH-600, T-600 and AI-600 (all of which are manufactured by Kyoeisha Chemical Co., Ltd.) as commercially available products are more preferable.

The polymerizable compound may be used alone or in combination of two or more kinds thereof.

The composition of the invention may or may not contain the polymerizable compound. When the composition of the invention contains the polymerizable compound, a content of the polymerizable compound in the solids of the composition is preferably from 1% by mass to 90% by mass, more preferably from 5% by mass to 80% by mass, and still more preferably from 10% by mass to 70% by mass.

[3-3] Alkali-soluble resin:

The composition of the invention may further contain an alkali-soluble resin. When the composition of the invention contains an alkali-soluble resin, developability is enhanced.

The alkali-soluble resin can be properly selected among alkali-soluble resins that are a linear organic polymer and which have at least one group capable of accelerating alkali solubility (for example, a carboxyl group, a phosphoric acid group, a sulfonic acid group, etc.) in a molecule (preferably a molecule composed of, as a main chain, an acrylic copolymer or a styrene based copolymer). Of these, those polymers which are soluble in an organic solvent and capable of being developed with a weakly alkaline aqueous solution are more preferable.

For the production of an alkali-soluble resin, for example, a method by a known radical polymerization process can be applied. At the production of an alkali-soluble resin by a radical polymerization process, polymerization conditions such as temperature, pressure, type and amount of a radical initiator and type of a solvent can be easily set by those skilled in the art, and the conditions can also be experimentally determined.

As the linear organic polymer which is used as the alkali-soluble resin, polymers having a carboxylic acid in a side chain thereof are preferable. Examples thereof include methacrylic acid copolymers, acrylic acid copolymers, itaconic acid copolymers, crotonic acid copolymers, maleic acid copolymers and partially esterified maleic acid copolymers; acidic cellulose derivatives having a carboxylic acid in a side chain thereof; and polymers having an acid anhydride added to a hydroxyl group-containing polymer. In particular, copolymers of (meth)acrylic acid and other monomer which is copolymerizable therewith are suitable as the alkali-soluble resin. Examples of other monomer which is copolymerizable with (meth)acrylic acid include alkyl (meth)acrylates, aryl (meth)acrylates and vinyl compounds. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate and cyclohexyl (meth)acrylate; and examples of the vinyl compound include styrene, α-methylstyrene, vinyltoluene, glycidyl methacrylate, acrylonitrile, vinyl acetate, N-vinylpyrrolidone, tetrahydrofurfuryl methacrylate, polystyrene macromonomer and polymethyl methacrylate macromonomer.

It is also preferable to use, as the alkali-soluble resin, a polymer (a) obtained by polymerizing monomer components including, as an essential component, a compound represented by the following general formula (ED) (hereinafter also referred to as “ether dimer”).

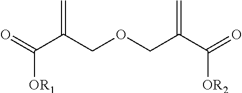

General Formula (ED)

In the general formula (ED), each of R₁ and R₂ independently represents a hydrogen atom or a hydrocarbon group. The hydrocarbon group represented by R₁ and R₂ is preferably a hydrocarbon group having from 1 to 15 carbon atoms, and it may further have a substituent.

When the composition of the invention contains the foregoing polymer (a), heat resistance and transparency of the cured coating film formed using the subject composition are more enhanced.

In the general formula (ED) representing the foregoing ether dimer, though the optionally substituted hydrocarbon group represented by R₁ and R₂ is not particularly limited, examples thereof include linear or branched alkyl groups such as a methyl group, an ethyl group, an n-propyl group, an isopropyl group, an n-butyl group, an isobutyl group, a t-butyl group, a t-amyl group, a stearyl group, a lauryl group and a 2-ethylhexyl group; aryl groups such as a phenyl group; alicyclic groups such as a cyclohexyl group, a t-butylcyclohexyl group, a dicyclopentadienyl group, a tricyclodecanyl group, an isobornyl group, an adamantyl group and a 2-methyl-2-adamantyl group; alkoxy group-substituted alkyl groups such as a 1-methoxyethyl group and a 1-ethoxyethyl group; and aryl group-substituted alkyl groups such as a benzyl group. Of these, primary or secondary carbon substituents which hardly leave by the action of an acid or heat, such as a methyl group, an ethyl group, a cyclohexyl group and a benzyl group, are especially preferable in view of heat resistance.

Specific examples of the ether dimer include dimethyl-2,2′-[oxybis(methylene)]bis-2-propenoate, diethyl-2,2′-[oxybis(methylene)]bis-2-propenoate, di(n-propyl)-2,2′-[oxybis(methylene)]bis-2-propenoate, di(isopropyl)-2,2′-[oxybis(methylene)]bis-2-propenoate, di(n-butyl)-2,2′-[oxybis(methylene)]bis-2-propenoate, di(isobutyl)-2,2′-[oxybis(methylene)]bis-2-propenoate, di(t-butyl)-2,2′-[oxybis(methylene)bis-2-propenoate, di(t-amyl)-2,2′-[oxybis(methylene)]bis-2-propenoate, di(stearyl)-2,2′-[oxybis(methylene)]bis-2-propenoate, di(lauryl)-2,2′-[oxybis(methylene)]bis-2-propenoate, di(2-ethylhexyl)-2,2′-[oxybis(methylene)]bis-2-propenoate, di(1-methoxyethyl)-2,2′-[oxybis(methylene)]bis-2-propenoate, di(1-ethoxyethyl)-2,2′-[oxybis(methylene)]bis-2-propenoate, dibenzyl-2,2′-[oxybis(methylene)]bis-2-propenoate, biphenyl-2,2′-[oxybis(methylene)]bis-2-propenoate, dicyclohexyl-2,2′-[oxybis(methylene)]bis-2-propenoate, di(t-butylcyclohexyl)-2,2′-[oxybis(methylene)]bis-2-propenoate, di(dicyclopentadienyl)-2,2′-[oxybis(methylene)]bis-2-propenoate, di(tricyclodecanyl)-2,2′-[oxybis(methylene)]bis-2-propenoate, di(isobornyl)-2,2′[oxybis(methyl ene)]bis-2-propenoate, diadamantyl-2,2′-[oxybis(methylene)]bis-2-propenoate and di(2-methyl-2-adamantyl)-2,2′-[oxybis(methylene)]bis-2-propenoate. Of these, dimethyl-2,2′-[oxybis(methylene)bis-2-propenoate, diethyl-2,2′-[oxybis(methylene)]bis-2-propenoate, dicyclohexyl-2,2′-[oxybis(methylene)]bis-2-propenoate and dibenzyl-2,2′-[oxybis(methylene)]bis-2-propenoate are especially preferable. Such an ether dimer may be used alone or in combination of two or more kinds thereof.

The structure derived from the compound represented by the foregoing general formula (ED) may be copolymerized with other monomer.

Of these, a benzyl (meth)acrylate/(meth)acrylic acid copolymer or a multi-component copolymer composed of benzyl (meth)acrylate/(meth)acrylic acid/other monomer is especially suitable. In addition to the above, there are exemplified a 2-hydroxypropyl (meth)acrylate/polystyrene macromonomer/benzyl methacrylate/methacrylic acid copolymer, a 2-hydroxy-3-phenoxypropyl acrylate/polymethyl methacrylate macromonomer/benzyl methacrylate/methacrylic acid copolymer, a 2-hydroxyethyl methacrylate/polystyrene macromonomer/methyl methacrylate/methacrylic acid copolymer and a 2-hydroxyethyl methacrylate/polystyrene macromonomer/benzyl methacrylate/methacrylic acid copolymer as described in JP-A-7-140654 as well as copolymerization products of 2-hydroxyethyl methacrylate.

Also, for the purpose of enhancing a crosslinking efficiency of the composition in the invention, an alkali-soluble resin having a polymerizable group may be used.

As the alkali-soluble resin having a polymerizable group, an alkali-soluble resin containing an allyl group, a (meth)acrylic group, an allyloxyalkyl group or the like in a side chain thereof is useful. Preferred examples of the alkali-soluble resin having a polymerizable group include a urethane-modified polymerizable double bond-containing acrylic resin obtained by allowing an isocyanate group and an OH group to react with each other in advance, with leaving one unreacted isocyanate group, and allowing a compound containing a (meth)acryloyl group and an acrylic resin containing a carboxyl group to react with each other; an unsaturated group-containing acrylic resin obtained by allowing an acrylic resin containing a carboxyl group and a compound having both an epoxy group and a polymerizable double bond in a molecule thereof to react with each other; a polymerizable double bond-containing acrylic resin obtained by allowing an acid pendant type epoxy acrylate resin, an acrylic resin containing an OH group and a dibasic acid anhydride having a polymerizable double bond to react with each other; a resin obtained by allowing an acrylic resin containing an OH group, an isocyanate and a compound having a polymerizable group to react with each other; and a resin obtained by subjecting a resin having an ester group having, at the α-position or β-position, a leaving group such as a halogen atom and a sulfonate group, in a side chain thereof to a treatment with a base, as described in JP-A-2002-229207 and JP-A-2003-335814.

An acid value of the alkali-soluble resin is preferably from 30 mg-KOH/g to 200 mg-KOH/g, more preferably from 50 mg-KOH/g to 150 mg-KOH/g, and most preferably from 70 mg-KOH/g to 120 mg-KOH/g.

Also, a weight average molecular weight (Mw) of the alkali-soluble resin is preferably from 2,000 to 50,000, more preferably from 5,000 to 30,000, and most preferably from 7,000 to 20,000.

The composition of the invention may or may not contain the alkali-soluble resin. When the composition of the invention contains the alkali-soluble resin, a content of the alkali-soluble resin in the composition is preferably from 1 to 15% by mass, more preferably from 2 to 12% by mass, and especially preferably from 3 to 10% by mass relative to the whole of solids of the composition. According to this, water repellency and development defect performance are enhanced.

### [3-4] Additives:

Furthermore, to the composition of the invention, additives such as a radical generator, colloidal silica, a surfactant, an adhesion accelerator, a pore-forming agent, an antioxidant, an ultraviolet absorber, an anticoagulant and a sensitizer may be added within the range where characteristics (for example, heat resistance, dielectric constant, mechanical strength, coatability, adhesion, etc.) of a film obtained using the composition are not impaired.

### <Colloidal Silica>

The composition may contain any colloidal silica within the range where the purpose of the invention is not impaired. For example, a dispersion liquid having high-purity silicic anhydride dispersed in a hydrophilic organic solvent or water and having an average particle size of usually from 5 to 30 nm, and preferably from 10 to 20 nm and a solid concentration of from about 5 to 40% by mass can be used.

### <Surfactant>

The composition may contain any surfactant within the range where the purpose of the invention is not impaired. Examples thereof include nonionic surfactants, anionic surfactants and cationic surfactants. Further examples thereof include silicone based surfactants, fluorine-containing surfactants, polyoxyalkylene oxide based surfactants and acrylic surfactants. The surfactant to be used may be used alone or in combination of two or more kinds thereof. As the surfactant, silicone based surfactants, nonionic surfactants, fluorine-containing surfactants or acrylic surfactants are preferable, with silicone based surfactants being especially preferable.

The composition of the invention may or may not contain the surfactant. When the composition of the invention contains the surfactant, a content of the surfactant is preferably 0.01% by mass or more and 1% by mass or less, and more preferably 0.01% by mass or more and 0.5% by mass or less, relative to a total amount of the composition.

Incidentally, the “silicone based surfactant” as referred to herein means a surfactant containing at least one Si atom. Any silicone based surfactant may be used as the silicone based surfactant. The silicone based surfactant is preferably of a structure containing an alkylene oxide and dimethylsiloxane, and more preferably of a structure containing the following chemical formula.

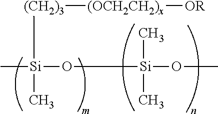

In the foregoing formula, R represents a hydrogen atom or an alkyl group having from 1 to 5 carbon atoms; x represents an integer of from 1 to 20; and each and m and n independently represents an integer of from 2 to 100. Each R may be the same as or different from every other R.

Examples of the silicone based surfactant include BYK 306 and BYK 307 (all of which are manufactured by BYK Chemie); SH7PA, SH21PA, SH28PA and SH30PA (all of which are manufactured by Dow Corning Toray Silicone Co., Ltd.); and Troysol 5366 (manufactured by Troy Chemical Corporation).

As the nonionic surfactant, any nonionic surfactant is usable. Examples thereof include polyoxyethylene alkyl ethers, polyoxyethylene aryl ethers, polyoxyethylene dialkyl esters, sorbitan fatty acid esters, fatty acid-modified polyoxyethylenes and a polyoxyethylene-polyoxypropylene block copolymer.

As the fluorine-containing surfactant, any fluorine-containing surfactant is usable. Examples thereof include perfluorooctyl polyethylene oxide, perfluorodecyl polyethylene oxide, perfluorododecyl polyethylene oxide, PF656 (manufactured by Omnova Solutions, Inc.), PF6320 (manufactured by Omnova Solutions, Inc.) and F-475 (manufactured by DIC Corporation).

As the acrylic surfactant, any acrylic surfactant is usable. Examples thereof include (meth)acrylic acid based copolymers.

### <Adherence Accelerator>

The composition may contain any adherence accelerator within the range not impairing the object of the present invention. Examples of the adherence accelerator include 3-glycidyloxypropyltrimethoxysilane, 1-methacryloxypropylmethyldimethoxysilane, 3-aminoglycidyloxypropyltriethoxysilane, 3-glycidyloxypropylmethyldimethoxysilane, and 3-aminopropyltrimethoxysilane. In addition, compounds described in paragraph [0048] of JP-A-2008-243945 may be used.

The photosensitive composition of the present invention may or may not contain an adherence accelerator but in the case of containing an adherence accelerator, the content thereof is preferably 10% by mass or less, more preferably from 0.03 to 5% by mass, based on the entire solid content in the composition.

### <Pore-Forming Agent>

In the invention, it is possible to contrive to realize a low refractive index by making the film porous by using a pore-forming factor within the range where the mechanical strength of the film is tolerable. Though the pre-forming agent serving as a pore-forming factor is not particularly limited, non-metal compounds are suitably used and required to simultaneously satisfy solubility in a solvent used in a coating solution and compatibility with a resin for insulating film or a precursor thereof.

As the pore-forming agent, a polymer can also be used. Examples of the polymer which can be used as the pore-forming agent include polyvinyl aromatic compounds (for example, polystyrene, polyvinylpyridine, halogenated polyvinyl aromatic compounds, etc.), polyacrylonitrile, polyalkylene oxides (for example, polyethylene oxide, polypropylene oxide, etc.), polyethylene, polylactic acid, polysiloxane, polycaprolactone, polycaprolactam, polyurethane, polymethacrylates (for example, polymethyl methacrylate, etc.), polymethacrylic acid, polyacrylates (for example, polymethyl acrylate, etc.), polyacrylic acid, polydienes (for example, polybutadiene, polyisoprene, etc.), polyvinyl chloride, polyacetal and amine-capped alkylene oxides. In addition to the above, polyphenylene oxide, poly(dimethylsiloxane), polytetrahydrofuran, polycyclohexylethylene, polyethyloxazoline, polyvinylpyridine and polycaprolactone are also usable.

Of these, in view of the fact that the resulting film has a lower refractive index, is uniform in film surface properties after curing and is transparent without causing turbidity, polystyrene, polyalkylene oxides, polylactic acid, polycaprolactone, polycaprolactam, polyurethane, polyacrylates, polyacrylic acid, polymethacrylates, polymethacrylic acid, polyacetal or polyperoxide is preferable, with polystyrene, polymethacrylates, polyalkylene oxides or polyacetal being especially preferable.

Examples of the polystyrene include anionic polymerized polystyrene, syndiotactic polystyrene, unsubstituted or substituted polystyrene (for example, poly(Cx-methylstyrene)), with unsubstituted polystyrene being preferable.

As the polymethacrylate, polymethacrylates having a tertiary ester are preferable. Specific examples of the polymethacrylate include those described below. But, it should not be construed that the invention is limited thereto.

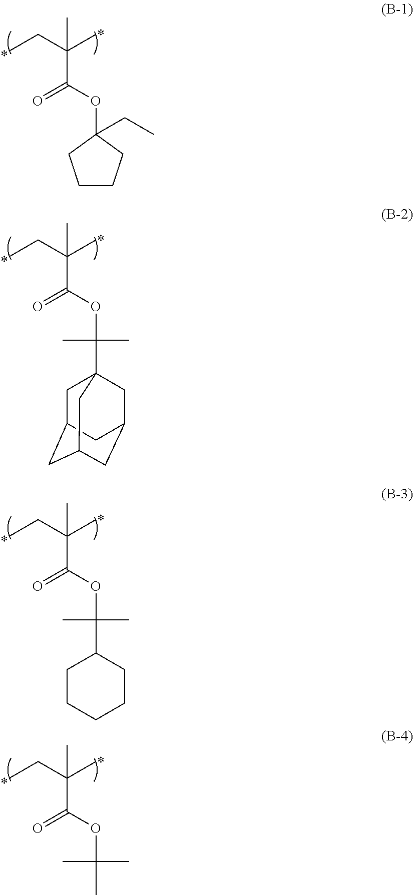

Examples of the polyalkylene oxide include polyethylene oxide, polyethylene oxide alkyl ethers, polyethylene oxide alkyl esters, polypropylene oxide, polypropylene oxide alkyl ethers, polypropylene oxide alkyl esters, a polyethylene oxide-polypropylene oxide copolymer, polyethylene oxide-polypropylene oxide alkyl ethers, polyethylene oxide-polypropylene oxide alkyl esters and polybutylene oxide.

The polyacetal may be any of a so-called polyacetal homopolymer obtained by homopolymerization of formaldehyde, a polyacetal copolymer obtained by polymerization of trioxane and a cyclic ether and/or a cyclic formal compound, or a polyacetal copolymer obtained by polymerization of divinyl ether and a diol. Specific examples of the polyacetal include those described below. But, it should not be construed that the invention is limited thereto.

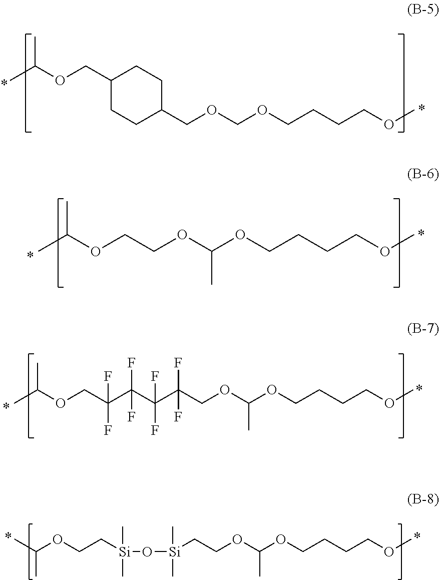

In view of the facts that the resulting film has a lower refractive index and that film contraction at the curing is suppressed, a boiling point or a decomposition temperature of the pore-forming agent is preferably from 180 to 350° C., and more preferably from 200 to 300° C. in terms of a 50% weight reduction temperature in the thermogravimetric analysis (at a programming rate of 20° C./min in a nitrogen gas stream).

Though an average molecular weight as reduced into polystyrene of the pore-forming agent is not particularly limited, in view of the fact that a transparent, irregularity-free film is obtainable while suppressing phase separation in the film, the average molecular weight as reduced into polystyrene of the pore-forming agent is preferably from 100 to 50,000, more preferably from 100 to 30,000, and especially preferably from 150 to 25,000.

The composition of the invention may or may not contain the pore-forming agent. When the composition of the invention contains the pore-forming agent, though an addition amount of the pore-forming agent is not particularly limited, it is preferably from 0.5 to 50% by mass, more preferably from 1.0 to 40% by mass, and especially preferably from 5.0 to 30% by mass relative to the whole of solids of the composition.

Also, for the purposes of accelerating alkali solubility in a non-exposed region and more enhancing developability of the composition, an organic carboxylic acid, and preferably a low-molecular weight organic carboxylic acid having a molecular weight of 1,000 or less may be added to the composition.

Specific examples thereof include aliphatic monocarboxylic acid such as formic acid, acetic acid, propionic acid, butyric acid, valeric acid, pivalic acid, caproic acid, diethylacetic acid, enanthic acid and caprylic acid; aliphatic dicarboxylic acids such as oxalic acid, malonic acid, succinic acid, glutaric acid, adipic acid, pimeric acid, suberic acid, azelaic acid, sebacic acid, brassylic acid, methylmalonic acid, ethylmalonic acid, dimethylmalonic acid, methylsuccinic acid, tetramethylsuccinic acid and citraconic acid; aliphatic tricarboxylic acids such as tricarbarylic acid, aconitic acid and camphoronic acid; aromatic monocarboxylic acids such as benzoic acid, toluic acid, cuminic acid, hemellitic acid and mesitylenic acid; aromatic polycarboxylic acids such as phthalic acid, isophthalic acid, terephthalic acid, trimellitic acid, trimesic acid, mellophanic acid and pyromellitic acid; and other carboxylic acids such as phenylacetic acid, hydroatropic acid, hydrocinnamic acid, mandelic acid, phenylsuccinic acid, atropic acid, cinnamic acid, methyl cinnamate, benzyl cinnamate, cinnamylideneacetic acid, coumaric acid and unbellic acid.

The composition of the invention may or may not contain the organic carboxylic acid. When the composition of the invention contains the organic carboxylic acid, though an addition amount of the organic carboxylic acid is not particularly limited, it is preferably from 5 to 40% by mass, more preferably from 5 to 30% by mass, and especially preferably from 10 to 30% by mass, relative to the whole of solids of the composition.

A production method of the composition is not particularly limited, and when the composition contains a solvent, the composition is obtained by adding a prescribed amount of the polymer to the solvent and stirring the mixture.

It is preferable that the foregoing composition is used for the film formation after removing insoluble materials, gel components and the like by means of filter filtration. A pore size of the filter to be used on that occasion is preferably from 0.05 to 2.0 more preferably from 0.05 to 1.0 μm, and most preferably from 0.05 to 0.5 μm. As to a material of the filter, polytetrafluoroethylene, polyethylene, polypropylene or nylon is preferable, with polytetrafluoroethylene, polyethylene or nylon being more preferable.

### [4] Pattern Forming Method

The pattern forming method of the present invention comprises a step of forming a photosensitive film, a step of exposing the photosensitive film, and a development step of developing the exposed photosensitive film to obtain a pattern film.

Here, the photosensitive film is formed from the photosensitive composition of the present invention.

The present invention also relates to a pattern film obtained by the pattern forming method above.

The formation method of the photosensitive film formed from the photosensitive composition of the present invention is not particularly limited, but the photosensitive composition is coated on a substrate such as a silicon wafer, an SiO₂ wafer, an SiN wafer, a glass, a plastic film and a microlens by an arbitrary method such as spin coating method, roller coating method, dip coating method, scanning method, spraying method and bar coating method, the solvent is removed by a heat treatment, if desired, to form a coating film (photosensitive film), and a prebaking treatment is applied thereto, whereby the photosensitive film can be formed.

The method for coating the composition on the substrate is preferably a spin coating, a scan coating, more preferably a spin coating method. With respect to the spin coating, a commercially available apparatus can be used. Examples of the apparatus which can be preferably used include CLEAN TRACK Series (manufactured by Tokyo Electron Ltd.), D-Spin Series manufactured by Dainippon Screen Mfg. Co., Ltd.), SS Series and CS Series (manufactured by Tokyo Ohka Kogyo Co., Ltd.).

As for the condition of spin coating, any rotation speed may be employed, but in view of in-plane uniformity of the film, the rotation speed is preferably about 1,300 rpm for a silicon substrate with a diameter of 300 mm. The method for discharging the composition solution may be either dynamic discharge of discharging the composition solution onto a rotating substrate or static discharge of discharging the composition solution onto a stationary substrate, but in view of in-plane uniformity of the film, dynamic discharge is preferred. From the standpoint of suppressing the amount of the composition consumed, a method of preliminarily discharging only the main solvent of the composition onto the substrate to form a liquid film and then discharging the composition thereover may be also employed. The spin coating time is not particularly limited but in view of throughput, is preferably within 180 seconds. Also, from the standpoint of conveyance of the substrate, it is also preferred to apply a treatment (edge rinse, back rinse) for allowing no remaining of the film on the substrate edge part.

The method for prebaking treatment is not particularly limited, but a generally employed method such as heating on a hot plate, heating using a furnace, and heating by irradiation of light from a xenon lamp in RTP (Rapid Thermal Processor) or the like, may be applied. Heating on a hot plate and heating using a furnace are preferred. As the hot plate, a commercially available apparatus can be preferably used and, for example, CLEAN TRACK Series (manufactured by Tokyo Electron Ltd.), D-Spin Series (manufactured by Dainippon Screen Mfg. Co., Ltd.) and SS Series or CS Series (manufactured by Tokyo Ohka Kogyo Co., Ltd.) may be preferably used. As the furnace, Cx Series (manufactured by Tokyo Electron Co., Ltd.) may be preferably used. The conditions of prebaking include conditions that a hot plate or an oven is used and heating is performed at 70 to 150° C. for 0.5 to 15 minutes.

The step of exposing the photosensitive film is performed through a mask, if desired.

Examples of the actinic ray or radiation which can be applied to the exposure include infrared light, g-line, h-line, i-line, KrF light, ArF light, X-ray and electron beam. In view of exposure dose, sensitivity and resolution, i-line, KrF light, ArF light and electron beam are preferred and furthermore, in view of general versatility, i-line and KrF light are most preferred. In the case of using i-line for the irradiation light, the light is preferably irradiated with an exposure dose of 100 to 10,000 mJ/cm². In the case of using KrF light, the light is preferably irradiated with an exposure dose of 30 to 300 mJ/cm².

Also, the exposed composition layer may be, if desired, heated at 70 to 180° C. for 0.5 to 15 minutes by using a hot plate or an oven before the subsequent development processing.

Subsequently, the composition layer after exposure is developed (development step) with a developer, whereby a negative or positive pattern (resist pattern) can be formed.

In conducting a positive development, it is preferable to use an alkali developer.

Examples of the alkali developer which can be used in conducting the positive development include an alkaline aqueous solution of inorganic alkalis such as sodium hydroxide, potassium hydroxide, sodium carbonate, sodium silicate, sodium metasilicate and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide and tetraethylammonium hydroxide, cyclic amines such as pyrrole and piperidine.

This alkaline aqueous solution may be used after adding thereto alcohols and a surfactant each in an appropriate amount.

The alkali concentration of the alkali developer is usually from 0.1 to 20% by mass.

The pH of the alkali developer is usually from 10.0 to 15.0.

In particular, an aqueous solution of 2.38% by mass tetramethylammonium hydroxide is preferred.

As for the rinsing solution in the rinsing treatment performed after the positive development, pure water is used, and the pure water may be used after adding thereto a surfactant in an appropriate amount.

In conducting a negative development, it is preferable to use an organic solvent-containing developer (organic developer).

As for the organic developer, a polar solvent such as ketone-based solvent, ester-based solvent, alcohol-based solvent, amide-based solvent and ether-based solvent, or a hydrocarbon-based solvent can be used.

Examples of the ketone-based solvent include 1-octanone, 2-octanone, 1-nonanone, 2-nonanone, acetone, 2-heptanone, 4-heptanone, 1-hexanone, 2-hexanone, diisobutyl ketone, cyclohexanone, methylcyclohexanone, phenylacetone, methyl ethyl ketone, methyl isobutyl ketone, acetyl acetone, acetonyl acetone, ionone, diacetonyl alcohol, acetyl carbinol, acetophenone, methyl naphthyl ketone, isophorone and propylene carbonate.

Examples of the ester-based solvent include methyl acetate, butyl acetate, ethyl acetate, isopropyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate and propyl lactate.

Examples of the alcohol-based solvent include an alcohol such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol and n-decanol; a glycol-based solvent such as ethylene glycol, diethylene glycol and triethylene glycol; and a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethyl butanol.

Examples of the ether-based solvent include, in addition to the glycol ether-based solvents above, dioxane and tetrahydrofuran.

Examples of the amide-based solvent which can be used include N-methyl-2-pyrrolidone, N,N-dimethylacetamide, N,N-dimethylformamide, hexamethylphosphoric triamide and 1,3-dimethyl-2-imidazolidinone.

Examples of the hydrocarbon-based solvent include an aromatic hydrocarbon-based solvent such as toluene and xylene, and an aliphatic hydrocarbon-based solvent such as pentane, hexane, octane and decane.

A plurality of these solvents may be mixed, or the solvent may be used by mixing it with a solvent other than those described above or with water. However, in order to sufficiently bring out the effects of the present invention, the water content ratio in the entire developer is preferably less than 10% by mass, and it is more preferred to contain substantially no water.

That is, the amount of the organic solvent used in the organic developer is preferably from 90 to 100% by mass, more preferably from 95 to 100% by mass, based on the entire amount of the developer.

In particular, the organic developer is preferably a developer containing at least one kind of a solvent selected from the group consisting of a ketone-based solvent, an ester-based solvent, an alcohol-based solvent, an amide-based solvent and an ether-based solvent.

The vapor pressure at 20° C. of the organic developer is preferably 5 kPa or less, more preferably 3 kPa or less, still more preferably 2 kPa or less. By setting the vapor pressure of the organic developer to 5 kPa or less, evaporation of the developer on a substrate or in a development cup is suppressed and the temperature uniformity in the wafer plane is enhanced, as a result, the dimensional uniformity in the wafer plane is improved.

Specific examples of the solvent having a vapor pressure of 5 kPa or less include a ketone-based solvent such as 1-octanone, 2-octanone, 1-nonanone, 2-nonanone, 4-heptanone, 2-hexanone, diisobutyl ketone, cyclohexanone, methylcyclohexanone, phenylacetone and methyl isobutyl ketone; an ester-based solvent such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, butyl formate, propyl formate, ethyl lactate, butyl lactate and propyl lactate; an alcohol-based solvent such as n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol and n-decanol; a glycol-based solvent such as ethylene glycol, diethylene glycol and triethylene glycol; a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethylbutanol; an ether-based solvent such as tetrahydrofuran; an amide-based solvent such as N-methyl-2-pyrrolidone, N,N-dimethylacetamide and N,N-dimethylformamide; an aromatic hydrocarbon-based solvent such as toluene and xylene; and an aliphatic hydrocarbon-based solvent such as octane and decane.

Specific examples of the solvent having a vapor pressure of 2 kPa or less that is a particularly preferred range include a ketone-based solvent such as 1-octanone, 2-octanone, 1-nonanone, 2-nonanone, 4-heptanone, 2-hexanone, diisobutyl ketone, cyclohexanone, methylcyclohexanone and phenylacetone; an ester-based solvent such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, ethyl lactate, butyl lactate and propyl lactate; an alcohol-based solvent such as n-butyl alcohol, sec-butyl alcohol, tert-butyl alcohol, isobutyl alcohol, n-hexyl alcohol, n-heptyl alcohol, n-octyl alcohol and n-decanol; a glycol-based solvent such as ethylene glycol, diethylene glycol and triethylene glycol; a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethylbutanol; an amide-based solvent such as N-methyl-2-pyrrolidone, N,N-dimethylacetamide and N,N-dimethylformamide; an aromatic hydrocarbon-based solvent such as xylene; and an aliphatic hydrocarbon-based solvent such as octane and decane.

In the organic developer, a surfactant can be added in an appropriate amount, if desired.

The surfactant is not particularly limited but, for example, an ionic or nonionic fluorine-containing and/or silicon-containing surfactant can be used. Examples of such a fluorine-containing and/or silicon-containing surfactant include surfactants described in JP-A-62-36663, JP-A-61-226746, JP-A-61-226745, JP-A-62-170950, JP-A-63-34540, JP-A-7-230165, JP-A-8-62834, JP-A-9-54432, JP-A-9-5988 and U.S. Pat. Nos. 5,405,720, 5,360,692, 5,529,881, 5,296,330, 5,436,098, 5,576,143, 5,294,511 and 5,824,451. A nonionic surfactant is preferred. The nonionic surfactant is not particularly limited, but use of a fluorine-containing surfactant or a silicon-containing surfactant is more preferred.

The amount of the surfactant used is usually from 0.001 to 5% by mass, preferably from 0.005 to 2% by mass, more preferably from 0.01 to 0.5% by mass, based on the entire amount of the developer.

In addition, in the present invention, a development with an alkali developer may be conducted before or after a development with the organic developer.

As regards the developing method, for example, a method of dipping the substrate in a bath filled with the developer for a fixed time (dipping method), a method of raising the developer on the substrate surface by the effect of a surface tension and keeping it still for a fixed time, thereby performing the development (puddle method), a method of spraying the developer on the substrate surface (spraying method), and a method of continuously ejecting the developer on the substrate spinning at a constant speed while scanning the developer ejecting nozzle at a constant rate (dynamic dispense method) may be applied.

In the case where the above-described various developing methods include a step of ejecting the developer toward the photosensitive film from a development nozzle of a developing apparatus, the ejection pressure of the developer ejected (the flow velocity per unit area of the developer ejected) is preferably 2 mL/sec/mm² or less, more preferably 1.5 mL/sec/mm² or less, still more preferably 1 mL/sec/mm² or less. The flow velocity has no particular lower limit but in view of throughput, is preferably 0.2 mL/sec/mm² or more.

By setting the ejection pressure of the ejected developer to the range above, pattern defects attributable to the resist scum after development can be greatly reduced.

Details of this mechanism are not clearly known, but it is considered that thanks to the ejection pressure in the above-described range, the pressure imposed on the photosensitive film by the developer becomes small and the photosensitive film or pattern film is kept from inadvertent chipping or collapse.

Here, the ejection pressure (mL/sec/mm²) of the developer is a value at the outlet of a development nozzle in a developing apparatus.

Examples of the method for adjusting the ejection pressure of the developer include a method of adjusting the ejection pressure by a pump or the like, and a method of supplying the developer from a pressurized tank and adjusting the pressure to change the ejection pressure.

After the step of developing the film, a step of stopping the development by replacing the solvent with another solvent may be practiced.

A step of rinsing the film with a rinsing solution is preferably provided after the development.

The rinsing solution used in the rinsing step after the development is not particularly limited as long as it does not dissolve the pattern film, and a solution containing a general organic solvent may be used. As for the rinsing solution, a rinsing solution containing at least one kind of an organic solvent selected from the group consisting of a hydrocarbon-based solvent, a ketone-based solvent, an ester-based solvent, an alcohol-based solvent, an amide-based solvent and an ether-based solvent is preferably used.

After the development, more preferably, a step of rinsing the film by using a rinsing solution containing at least one kind of an organic solvent selected from the group consisting of a ketone-based solvent, an ester-based solvent, an alcohol-based solvent and an amide-based solvent is preformed; still more preferably, after the development, a step of rinsing the film by using a rinsing solution containing an alcohol-based solvent or an ester-based solvent is performed; yet still more preferably, after the development, a step of rinsing the film by using a rinsing solution containing a monohydric alcohol is performed; and most preferably, after the development, a step of rinsing the film by using a rinsing solution containing a monohydric alcohol having a carbon number of 5 or more is performed.

The monohydric alcohol used in the rinsing step after the development includes a linear, branched or cyclic monohydric alcohol, and specific examples of the monohydric alcohol which can be used include 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol and 4-octanol. As for the particularly preferred monohydric alcohol having a carbon number of 5 or more, 1-hexanol, 2-hexanol, 4-methyl-2-pentanol, 1-pentanol, 3-methyl-1-butanol and the like can be used.

A plurality of these components may be mixed, or the solvent may be used by mixing it with an organic solvent other than those described above.

The water content ratio in the rinsing solution is preferably 10% by mass or less, more preferably 5% by mass or less, still more preferably 3% by mass or less. By setting the water content ratio to 10% by mass or less, good development characteristics can be obtained.

The vapor pressure at 20° C. of the rinsing solution used after the development is preferably from 0.05 to 5 kPa, more preferably from 0.1 to 5 kPa, and most preferably from 0.12 to 3 kPa. By setting the vapor pressure of the rinsing solution to the range from 0.05 to 5 kPa, the temperature uniformity in the wafer plane is enhanced and moreover, swelling due to permeation of the rinsing solution is suppressed, as a result, the dimensional uniformity in the wafer plane is improved.

The rinsing solution may be also used after adding thereto a surfactant in an appropriate amount.

In the rinsing step, the wafer after development is rinsed using the above-described organic solvent-containing rinsing solution. The method for rinsing treatment is not particularly limited, but examples of the method which can be applied include a method of continuously ejecting the rinsing solution on the substrate spinning at a constant speed (spin coating method), a method of dipping the substrate in a bath filled with the rinsing solution for a fixed time (dipping method), and a method of spraying the rinsing solution on the substrate surface (spraying method). Above all, it is preferred to perform the rinsing treatment by the spin coating method and after the rinsing, remove the rinsing solution from the substrate surface by spinning the substrate at a rotational speed of 2,000 to 4,000 rpm. It is also preferred to include a heating step (Post Bake) after the rinsing step. The developer and rinsing solution remaining between patterns and in the inside of the pattern are removed by the baking. The heating step after the rinsing step is performed at usually from 40 to 160° C., preferably from 70 to 95° C., for usually from 10 seconds to 3 minutes, preferably from 30 to 90 seconds.

After the development step, if desired, curing of the resulting pattern film may be more accelerated by subjecting the pattern film to post-heating and/or post-exposure (post-curing step by film curing treatment).

According to this, there may be the case where not only light resistance, weather resistance and film strength are enhanced, but low refractive index properties and low dielectric constant properties can be enhanced.

The film curing treatment as referred to herein means that the pattern film on the substrate is more cured, thereby more giving solvent resistance or the like to the film. As a film curing method, it is preferable to perform a heating treatment (baking). For example, a polymerization reaction at the post-heating of the residual polymerizable group in the polymer can be utilized. As to a condition of this post-heating treatment, a heating temperature is in the range of preferably from 100° C. to 600° C., more preferably from 200° C. to 500° C., and especially preferably from 200° C. to 450° C., and a heating time is in the range of preferably from one minutes to 3 hours, more preferably from one minute to 2 hours, and especially preferably from one minute to one hour. The post-heating treatment may be dividedly performed plural times.

Also, in the invention, the film curing may be performed upon irradiation with a high energy ray such as irradiation with light and irradiation with radiation, thereby causing a polymerization reaction between the still remaining polymerizable groups in the polymer, in place of the heating treatment. Examples of the high energy ray as referred to herein include an electron beam, an ultraviolet light and an X-ray. However, it should not be construed that the invention is limited to these methods.

As to the high energy ray, in the case of using an electron beam, the energy is preferably from 0.1 to 50 keV, more preferably from 0.2 to 30 keV, and especially preferably from 0.5 to 20 keV. A total dose amount of the electron beam is preferably from 0.01 to 5 μC/cm², more preferably from 0.01 to 2 μC/cm², and especially preferably from 0.01 to 1 μC/cm². A substrate temperature at the irradiation with an electron beam is preferably from 0 to 500° C., more preferably from 20 to 450° C., and especially preferably from 20 to 400° C. A pressure is preferably from 0 to 133 kPa, more preferably from 0 to 60 kPa, and especially preferably from 0 to 20 kPa.

From the viewpoint of preventing oxidation of the polymer from occurring, as to an atmosphere in the surroundings of the substrate, it is preferable to use an inert atmosphere such as Ar, He and nitrogen. Also, for the purpose of a reaction with plasma, electromagnetic wave or chemical species generated by an interaction with the electron beam, a gas such as oxygen, a hydrocarbon and ammonia may be added. The irradiation with an electron beam may be dividedly performed plural times. In that case, it is not necessary to make the irradiation condition with an electron beam identical every time, but the irradiation may be performed under a different condition every time.

An ultraviolet light may be used as the high energy ray. An irradiation wavelength region at the use of an ultraviolet light is preferably from 160 to 400 nm, and its output is preferably from 0.1 to 2,000 mWcm⁻² just above the substrate. A substrate temperature at the irradiation with an ultraviolet light is preferably from 250 to 450° C., more preferably from 250 to 400° C., and especially preferably from 250 to 350° C. From the viewpoint of preventing oxidation of the polymer of the invention from occurring, as to an atmosphere in the surroundings of the substrate, it is preferable to use an inert atmosphere such as Ar, He and nitrogen. Also, a pressure on that occasion is preferably from 0 to 133 kPa.

The film curing may be achieved by performing the heating treatment and the irradiation with a high energy ray such as irradiation with light and irradiation with radiation simultaneously or successively.

As to a film thickness, it is possible to form a coating film having a thickness of from about 0.05 to 1.5 μm by single coating and from about 0.1 to 3 μm by double coating, respectively in terms of a dry film thickness.

Since the cage-shaped silsesquioxane structure of the polymer is not decomposed at the baking, it is preferable that a group which nucleophilically attacks the Si atom during the production of a composition and a film (for example, a hydroxyl group, a silanol group, etc.) does not substantially exist.

As described previously, the composition of the invention can be utilized for various applications. For example, as to the applications, it is preferable to use the composition of the invention for fabricating an insulating film or an antireflection film.

Therefore, the invention also relates to an antireflection film that is a pattern film obtained by the foregoing pattern forming method of the invention.

Also, the invention relates to an insulating film that is a pattern film obtained by the foregoing pattern forming method of the invention.

Furthermore, the invention also relates to an optical device having the foregoing antireflection film. The invention also relates to an electronic device having the foregoing insulating film.

Such an insulating film and a low-refractive index film (for example, an antireflection film) are hereunder described in detail. However, though preferred ranges of various physical properties as described below in the insulating film or low-refractive index film are ranges which are preferable particularly for an application to an insulating film or a low-refractive index film, it should not be construed that the invention is limited to such an application.

### <Insulating Film>

Though a thickness of the insulating film obtained from the foregoing composition is not particularly limited, it is preferably from 0.005 to 10 μm, more preferably from 0.01 to 5.0 μm, and still more preferably from 0.01 to 1.0 μm.

Here, the thickness of the insulating film of the invention means a simple average value in the case of measuring arbitrary three or more places using an optical interference thickness meter.

Though a relative dielectric constant of the insulating film obtained by the foregoing method of the invention varies depending upon a material to be used, it is preferably 2.50 or less, and more preferably from 1.80 to 2.40 at a measurement temperature of 25° C.

Though a Young's modulus of the insulating film of the invention varies depending upon a material to be used, it is preferably from 2.0 to 15.0 GPa, and more preferably from 3.0 to 15.0 GPa at 25° C.

A film obtained from the foregoing film forming composition is preferably a porous film, and it is preferable that a pore diameter exhibiting a maximum peak in a pore distribution curve of pores in the porous film (hereinafter also referred to as a “maximum distribution diameter”) is 5 nm or less. When the maximum distribution diameter is 5 nm or less, it is possible to make more excellent mechanical strength and relative dielectric constant characteristics compatible with each other.

The maximum distribution diameter is more preferably 3 nm or less. Incidentally, though a lower limit of the maximum distribution diameter is not particularly limited, there is exemplified 0.5 nm as the lower limit which can be measured by a known measurement apparatus.

Incidentally, the maximum distribution diameter as referred to herein means a pore diameter exhibiting a maximum peak in a pore distribution curve obtained by the nitrogen gas adsorption method.

As to the insulating film obtained using the composition of the invention, when used as an interlayer insulating film for semiconductor, in its wiring structure, a barrier layer for preventing metal migration from occurring may be provided on the surface on the wiring side. Also, in addition to a cap layer for preventing peeling by CMP (chemical mechanical polishing) and an interlayer adhesion layer, an etching stopper layer or the like may be provided on the upper surface or bottom surface of the wiring or interlayer insulating film. Furthermore, a layer of the interlayer insulating film may be divided into plural layers using different materials, if desired.

The insulating film of the invention may be used by forming a laminated structure with other Si-containing insulating film or an organic film. It is preferable to use the insulating film of the invention upon being laminated with a hydrocarbon based film.

The insulating film obtained using the film forming composition of the invention can be subjected to etching processing for copper wiring or other purpose. Though any of wet etching or dry etching may be adopted as the etching processing, drying etching is preferable. For dry etching, any of ammonia based plasma or fluorocarbon based plasma can be properly used. For such plasma, not only Ar but a gas such as oxygen, nitrogen, hydrogen and helium can be used. Also, after the etching processing, ashing can also be performed for the purpose of removing a photoresist used for the processing or other purpose, and for the purpose of removing a residue at the ashing, rinsing can also be further performed.

After the copper wiring processing, the insulating film obtained using the film forming composition of the invention can be subjected to CMP for the purpose of flattening a copper plated part. As a CMP slurry (chemicals), commercially available slurries (for example, those manufactured by Fujimi Incorporated, Rodel Nitta Company, JSR Corporation, Hitachi Chemical Co., Ltd. and so on) can be used. Also, commercially available apparatuses (for example, those manufactured by Applied Materials Inc., Ebara Corporation and so on) can be properly used. Furthermore, for the purpose of removing a slurry residue after CMP, rinsing can also be performed.

### <Application>

The insulating film of the invention can be used for various purposes, and in particular, it is suitably used for electronic devices. The electronic device as referred to herein means a wide-ranging electronic appliance including semiconductor devices and magnetic recording heads. For example, the insulating film of the invention is suitable as an insulating film in a semiconductor device such as LSI, system LSI, DRAM, SDRAM, RDRAM and D-RDRAM, or in an electronic component such as a multi-chip module and multilayer wiring board, and is also usable as an interlayer insulating film, an etching stopper film, a surface protective film and a buffer coat film for a semiconductor, as a passivation film or α-ray intercepting film in LSI, as a cover ray film or overcoat film of a flexographic printing plate, as a cover coat of a flexible coppered plate, as a solder resist film, and as a liquid crystal orientation film. Also, the insulating film of the invention may be used as a surface protective film, an antireflective film or a retardation film for optical devices.

### <Low-Refractive Index Film>

The pattern film obtained using the foregoing composition exhibits excellent low refractive index properties. Specifically, a refractive index of the pattern film (wavelength: 633 nm, measurement temperature: 25° C.) is preferably 1.35 or less, more preferably from 1.27 to 1.35, and especially preferably from 1.27 to 1.33. When the pattern film has a refractive index falling within the foregoing range, it is useful as an antireflection film as described later.

Since the pattern film obtained using the composition has a large number of pores within the film, it exhibits excellent low refractive index properties. Specifically, a film density of the resulting film is from 0.7 to 1.25 g/cm³, preferably from 0.7 to 1.2 g/cm³, and more preferably from 0.8 to 1.2 g/cm³. When the film density is less than 0.7 g/cm³, there may be the case where the resulting film is inferior in mechanical strength. On the other hand, when the film density exceeds 1.25 g/cm³, there may be the case where the resulting film is inferior in heat resistance. Incidentally, the measurement of the film density can be carried out by a known measurement apparatus by means of X-ray reflectometry (XRR) or the like.

The pattern film obtained using the composition is small in a change of refractive index under a high-temperature condition and exhibits excellent heat resistance. Specifically, on the occasion of allowing the resulting film to stand for 2 hours under a high-temperature condition of 200° C. or higher, a change value of reactive index (wavelength: 633 nm) before and after standing ((refractive index after standing)−(refractive index before standing)) is preferably less than 0.006, more preferably less than 0.004, and especially preferably less than 0.002.

The pattern film obtained using the composition is small in a change of refractive index in a high-temperature and high-humidity environment and exhibits excellent heat resistance. Specifically, on the occasion of allowing the resulting film to stand at 110° C. and at a humidity of 95% for 12 hours, a change value of reactive index (wavelength: 633 nm) before and after standing ((refractive index after standing)−(refractive index before standing)) is preferably 0.01 or less.

Also, the pattern film obtained using the foregoing composition is excellent in adhesion to the substrate on which the pattern film is formed.

### <Antireflection Film>

As a preferred use embodiment of the pattern film obtained using the foregoing composition of the invention, there is exemplified an antireflection film. In particular, the pattern film is suitable as an antireflection film for optical devices (for example, microlenses for image sensors, plasma display panels, liquid crystal displays, organic electroluminescent devices, etc.).

In the case of using the pattern film as an antireflection film, it is preferable that its reflectance is low as far as possible. Specifically, a mirror average reflectance in a wavelength region of from 450 to 650 nm is preferably 3% or less, more preferably 2% or less, and most preferably 1% or less. Incidentally, it is preferable that a lower limit value thereof is low as far as possible, and the lower limit value is ultimately 0.

A haze of the antireflection film is preferably 3% or less, more preferably 1% or less, and most preferably 0.5% or less. Incidentally, it is preferable that a lower limit value thereof is low as far as possible, and the lower limit value is ultimately 0.

In the case of using the foregoing film as an antireflection film of a single-layered type, when a refractive index of a transparent substrate is defined as nG, it is preferable that a refractive index n of the antireflection film is √nG, namely a square root of the refractive index of the transparent substrate. For example, since a refractive index of optical glass is from 1.47 to 1.92 (wavelength: 633 nm, measurement temperature: 25° C.), n of the single-layered antireflection film formed on the optical glass is preferably from 1.21 to 1.38. Incidentally, on that occasion, a film thickness of the antireflection film is preferably from 10 nm to 10 μm.

In the case of using the foregoing film as an antireflection film of a multi-layered type, the film is used as a low-refractive index layer, and for example, it is possible to include a high-refractive index layer, a hard coat layer and a transparent substrate beneath the subject film. At that time, the high-refractive index layer maybe formed directly on the substrate without providing the hard coat layer. Also, a middle refractive index layer may be further provided between the high-refractive index layer and the low-refractive index layer, or between the high-refractive index layer and the hard coat layer.

Each of the layers in the case of a multi-layered type is hereunder described in detail.

### (1) Low-Refractive Index Layer:

The low-refractive index layer is constituted of the pattern film obtained using the foregoing composition of the invention. A refractive index and a thickness of the low-refractive index layer are described.

### (i) Refractive Index:

It is preferable to regulate a refractive index of the pattern film using the composition of the invention (wavelength: 633 nm, measurement temperature: 25° C.), namely a refractive index of a low-refractive index film (also referred to as a “low-refractive index layer”) to 1.35 or less. This is because by regulating the refractive index of the low-refractive index film to 1.35 or less, when combined with a high-refractive index film (also referred to as a “high-refractive index layer”), an antireflection effect can be surely revealed.

It is more preferable to regulate the refractive index of the low-refractive index film to 1.33 or less; and it is still more preferable to regulate the refractive index of the low-refractive index film to 1.32 or less. Incidentally, in the case of providing a plurality of the low-refractive index film, at least one of the layers may have a value of the refractive index falling within the foregoing range.

Also, in the case of providing the low-refractive index layer, in view of the fact that a more excellent antireflection effect is obtainable, it is preferable that a difference in refractive index from the high-refractive index layer is a value of 0.05 or more. When the difference in refractive index between the low-refractive index layer and the high-refractive index layer is 0.05 or more, a synergistic effect between these antireflection film layers is easily obtainable, and an antireflection effect is more surely obtainable. In consequence, the difference in refractive index between the low-refractive index layer and the high-refractive index layer is more preferably a value falling within the range of from 0.1 to 0.8, and still more preferably a value falling within the range of from 0.15 to 0.7.

### (ii) Thickness:

Though a thickness of the low-refractive index layer is not particularly limited, it is preferable that the thickness of the low-refractive index layer is, for example, from 20 to 300 nm. When the thickness of the low-refractive index layer is 20 nm or more, an adhesion to the high-refractive index film as a ground is surely obtainable; whereas when it is 300 nm or less, light interference is hardly generated, and an antireflection effect is more surely obtainable. In consequence, the thickness of the low-refractive index layer is more preferably from 20 to 250 nm, and still more preferably from 20 to 200 nm. Incidentally, in order to obtain higher antireflection properties, when a multi-layered structure is formed by providing a plurality of the low-refractive index layer, a total thickness thereof may be from 20 to 300 nm.

### (2) High-Refractive Index Layer:

A curing composition for forming a high-refractive index layer is not particularly limited. It is preferable that the curing composition contains, as a film-forming component, an epoxy based resin, a phenol based resin, a melamine based resin, an alkyd based resin, a cyanate based resin, an acrylic resin, a polyester based resin, a urethane based resin or a siloxane resin alone or in combination of two or more kinds thereof. So far as such a resin is concerned, it is possible to form a stiff thin film as the high-refractive index layer. As a result, it is possible to conspicuously enhance scratch resistance of the antireflection film.

However, in general, a refractive index of such a resin alone is from 1.45 to 1.62, and hence, there may be the case where in order to obtain a high antireflection performance, this refractive index is not sufficient. For that reason, it is preferable to blend an inorganic particle with a high refractive index, for example, a metal oxide particle, thereby regulating the refractive index to from 1.70 to 2.20. Also, as to a curing form, a curing composition capable of being subjected to heat curing, ultraviolet curing or electron radiation curing can be used. However, an ultraviolet curing composition with satisfactory productivity is more suitably used.

Though a thickness of the high-refractive index layer is not particularly limited, for example, it is preferably from 20 to 30,000 nm. When the thickness of the high-refractive index layer is 20 nm or more, in the case of being combined with the low-refractive index layer, an antireflection effect or an adhesion to the substrate is easy to be obtained more surely. On the other hand, when the thickness of the high-refractive index layer is 30,000 nm or less, light interference is hardly caused, and an antireflection effect is easy to be obtained more surely. In consequence, the thickness of the high-refractive index layer is more preferably from 20 to 1,000 nm, and still more preferably from 50 to 500 nm. Also, in order to obtain higher antireflection properties, when a multi-layered structure is formed by providing a plurality of the high-refractive index layer, a total thickness thereof may be from 20 to 30,000 nm. Incidentally, in the case of providing a hard coat layer between the high-refractive index layer and the substrate, the thickness of the high-refractive index layer can be set to from 20 to 300 nm.

### (3) Hard Coat Layer:

A constituent material of the hard coat layer which is used for the antireflection film of the invention is not particularly limited. Examples of such a material include siloxane resins, acrylic resins, melamine resins and epoxy resins. Such a resin may be used alone or in combination of two or more kinds thereof.

Also, though a thickness of the hard coat layer is not particularly limited, it is preferably from 1 to 50 μm, and more preferably from 5 to 10 μm. When the thickness of the hard coat layer is 1 μm or more, it is easy to enhance an adhesion to the substrate of the antireflection film more surely, whereas when the thickness of the hard coat layer is 50 μm or less, it is easy to uniformly form the hard coat layer.

### (4) Substrate:

Though a type of the substrate which is used for the antireflection film of the invention is not particularly limited, examples thereof include transparent substrates made of glass, a polycarbonate based resin, a polyester based resin, an acrylic resin, a triacetyl cellulose resin (TAC), etc., and a silicon wafer. By forming the antireflection film including such a substrate, it is possible to obtain an excellent antireflection effect in an application field of a wide-ranging antireflection film, such as a color filter in a lens part of camera, a screen display part of television receiver (CRT) or a liquid crystal display device, and an imaging device.

The pattern film obtained using the composition of the invention can also be used as a surface protective film or a retardation film for optical devices.

### EXAMPLES

The invention is hereunder described in more detail with reference to the following Examples, but it should not be construed that the invention is limited to these Examples.

For the following GPC measurement, Waters 2695 and Shodex's GPC column KF-805L (three columns connected directly) were used; 50 μL of a tetrahydrofuran solution having a sample concentration of 0.5% by mass was poured at a column temperature of 40° C.; tetrahydrofuran as an eluent solvent was allowed to flow at a flow rate of 1 mL/min; and a sample peak was detected by an RI detector (Waters 2414) and a UV detector (Waters 2996). Mw and Mn were calculated using a calibration curve prepared using standard polystyrene.

### <Synthesis of Compound I-12>

A mixed solution of 2,000 g of electronic grade concentrated hydrochloric acid, 12 L of n-butanol and 4,000 g of ion-exchanged water was cooled to 10° C., to which was then added dropwise a mixed solution of 840 g of vinyl triethoxysilane and 786 g of methyl triethoxysilane over 20 minutes. Thereafter, the mixture was further stirred at 25° C. for 18 hours. A deposited crystal was collected by means of filtration and washed with 300 mL of electronic grade methanol. After washing, the crystal was dissolved in 4,000 mL of tetrahydrofuran, to which were then successively added dropwise 4,000 mL of electronic grade methanol and 8,000 mL of ion-exchanged water while stirring. A deposited crystal was collected by means of filtration and dried to obtain 105 g of a desired product (Compound I-12) as a white solid. As a result of ¹H-NMR measurement (300 MHz, CDCl₃), there were observed multiplets at from 6.08 to 5.88 ppm and from 0.28 to 0.18 ppm, and from an integral ratio thereof, a vinyl/methyl ratio was calculated to be 3.9/4.1. In the foregoing formula (3), x was 3.9, and y was 4.1, with (x+y) being 8.0. Incidentally, the resulting silsesquioxane was a mixture of cage-shaped silsesquioxane compounds represented by the foregoing general formula (Q-6).

### <Synthesis of Compound I-13>

A mixed solution of 136 g of electronic grade concentrated hydrochloric acid, 1 L of n-butanol and 395 g of ion-exchanged water was cooled to 10° C., to which was then added dropwise a mixed solution of 78.3 g of vinyl triethoxysilane and 73.3 g of methyl triethoxysilane over 15 minutes. Thereafter, the mixture was further stirred at 25° C. for 18 hours. A deposited crystal was collected by means of filtration and washed with 100 mL of electronic grade methanol. After washing, the crystal was dissolved in 500 mL of tetrahydrofuran, to which were then successively added dropwise 200 mL of electronic grade methanol and 200 mL of ion-exchanged water while stirring. A deposited crystal was collected by means of filtration and dried to obtain 7.8 g of a desired product (Compound I-13) as a white solid. As a result of ¹H-NMR measurement (300 MHz, CDCl₃), there were observed multiplets at from 6.08 to 5.88 ppm and from 0.28 to 0.18 ppm, and from an integral ratio thereof, a vinyl/methyl ratio was calculated to be 4.0/4.0. In the foregoing formula (3), x was 4.0, and y was 4.0, with (x+y) being 8.0.

As a result of gas chromatography (analysis condition: SE-30 capillary column; pouring temperature=160° C.; after holding at 100° C. for 2 minutes, the temperature was elevated to 260° C. at a rate of 8° C./min; detector, FID), it was noted that the resulting silsesquioxane was a mixture composed mainly of cage-shaped silsesquioxane compounds represented by the general formula (6) having a vinyl/methyl ratio of 4/4 (x/y (mol %): 8/0 (1%), 7/1 (2%), 6/2 (11%), 5/3 (22%), 4/4 (28%), 3/5 (22%), 2/6 (11%) and 1/7 (3%)). Incidentally, the resulting silsesquioxane was a mixture of cage-shaped silsesquioxane compounds represented by the foregoing general formula (Q-6).

Also, a content of the cage-shaped silsesquioxane compound (A) was 72 mol % relative to the whole of the silsequioxanes.

### <Synthesis of Compound I-14>

A mixed solution of 2,000 g of electronic grade concentrated hydrochloric acid, 12 L of n-butanol and 4,000 g of ion-exchanged water was cooled to 10° C., to which was then added dropwise a mixed solution of 944 g of vinyl triethoxysilane and 688 g of methyl triethoxysilane over 20 minutes. Thereafter, the mixture was further stirred at 25° C. for 18 hours. A deposited crystal was collected by means of filtration and washed with 300 mL of electronic grade methanol. After washing, the crystal was dissolved in 1,500 mL of tetrahydrofuran, to which were then successively added dropwise 1,500 mL of electronic grade methanol and 1,500 mL of ion-exchanged water while stirring. A deposited crystal was collected by means of filtration and dried to obtain 108 g of a desired product (Compound I-14) as a white solid. As a result of ¹H-NMR measurement (300 MHz, CDCl₃), there were observed multiplets at from 6.08 to 5.88 ppm and from 0.28 to 0.18 ppm, and from an integral ratio thereof, a vinyl/methyl ratio was calculated to be 4.4/3.6. In the foregoing formula (3), x was 4.4, and y was 3.6, with (x+y) being 8.0. Incidentally, the resulting silsesquioxane was a mixture of cage-shaped silsesquioxane compounds represented by the foregoing general formula (Q-6).

### <Synthesis of Compound I-25>

A mixed solution of 271 g of electronic grade concentrated hydrochloric acid, 1,238 g of n-butanol and 541 g of ion-exchanged water was cooled to 10° C., to which was then added dropwise a mixed solution of 120 g of vinyl triethoxysilane and 120 g of propyl trimethoxysilane over 10 minutes. Thereafter, the mixture was further stirred at 25° C. for 18 hours. A deposited crystal was collected by means of filtration and washed with 100 mL of electronic grade methanol. After washing, the crystal was dissolved in 200 mL of tetrahydrofuran, to which were then successively added dropwise 217 mL of electronic grade methanol and 344 mL of ion-exchanged water while stirring. A deposited crystal was collected by means of filtration and dried to obtain 7 g of a desired product (Compound I-25) as a white solid. As a result of ¹H-NMR measurement (300 MHz, CDCl₃), there were observed multiplets at from 6.13 to 5.84 ppm, from 1.54 to 1.43 ppm, from 1.26 to 0.90 ppm and from 0.73 to 0.60 ppm, and from an integral ratio thereof, a vinyl/propyl ratio was calculated to be 4.0/4.0. In the foregoing formula (3), x was 4.0, and y was 4.0, with (x+y) being 8.0. Incidentally, the resulting silsesquioxane was a mixture of cage-shaped silsesquioxane compounds represented by the foregoing general formula (Q-6).

### <Synthesis of Compound I-27>

A mixed solution of 800 g of electronic grade concentrated hydrochloric acid, 3,700 g of n-butanol and 1,600 g of ion-exchanged water was cooled to 10° C., to which was then added dropwise a mixed solution of 360 g of vinyl triethoxysilane and 284 g of ethyl trimethoxysilane over 10 minutes. Thereafter, the mixture was further stirred at 25° C. for 18 hours. A deposited crystal was collected by means of filtration and washed with 100 mL of electronic grade methanol. After washing, the crystal was dissolved in 400 mL of tetrahydrofuran, to which were then successively added dropwise 400 mL of electronic grade methanol and 800 mL of ion-exchanged water while stirring. A deposited crystal was collected by means of filtration and dried to obtain 31 g of a desired product (Compound I-27) as a white solid. As a result of ¹H-NMR measurement (300 MHz, CDCl₃), there were observed multiplets at from 6.13 to 5.85 ppm, from 1.03 to 0.97 ppm and from 0.69 to 0.60 ppm, and from an integral ratio thereof, a vinyl/ethyl ratio was calculated to be 4.3/3.7. In the foregoing formula (3), x was 4.3, and y was 3.7, with (x+y) being 8.0. Incidentally, the resulting silsesquioxane was a mixture of cage-shaped silsesquioxane compounds represented by the foregoing general formula (Q-6).

Other Compounds I described in the foregoing Table 1 were synthesized by referring to the foregoing preparation examples.

Incidentally, the silsesquioxane of Compound I-4 was a mixture of cage-shaped silsesquioxane compounds represented by the foregoing general formula (Q-2); and the silsesquioxane of Compound I-31 was a mixture of cage-shaped silsesquioxane compounds represented by the foregoing general formula (Q-7).

Also, each of the silsesquioxanes of Compounds I-1 to I-3 was a mixture of cage-shaped silsesquioxane compounds represented by the foregoing general formula (Q-1); and the silsesquioxane of Compound I-5 was a mixture of cage-shaped silsesquioxane compounds represented by the foregoing general formula (Q-3).

Also, the silsesquioxane of Compound I-6 was a mixture of cage-shaped silsesquioxane compounds represented by the foregoing general formula (Q-4).

Also, the silsesquioxane of Compound I-7 was a mixture of cage-shaped silsesquioxane compounds represented by the foregoing general formula (Q-5).

Furthermore, each of the silsesquioxanes of Compounds I-8 to I-11 and Compounds I-15 to I-30 was a mixture of cage-shaped silsesquioxane compounds represented by the foregoing general formula (Q-6).

Synthesis methods of polymers (Resins A) using the above-synthesized silsesquioxanes (Compounds I) are hereunder described in detail.

### <Synthesis of Resin A-13>

5 g of the above-synthesized Compound I-13 was added to 132 g of chlorobenzene. While heat refluxing the resulting solution in a nitrogen gas stream at an internal temperature of 132° C., 31 mL of a solution obtained by dissolving 0.2 g of, as a polymerization initiator, V-601 (10-hour half-life temperature: 66° C.), manufactured by Wako Pure Chemical Industries, Ltd. in 80 g of chlorobenzene was added dropwise over 310 minutes. After completion of the dropwise addition, heat refluxing was continued for an additional one hour. After cooling the reaction solution to room temperature, 340 mL of electronic grade methanol and 34 mL of ion-exchanged water were added to the reaction solution, and a deposited solid was collected by means of filtration and washed with 10 mL of electronic grade methanol. After washing, the solid was dissolved in 40 g of tetrahydrofuran, to which was then added dropwise 8 g of ion-exchanged water while stirring. After stirring for one hour, a supernatant was removed by means of decantation, and 20 g of electronic grade methanol was added to the residue. A deposited solid was collected by means of filtration and dried to obtain 1.9 g of a desired product (Resin A-13) as a white solid.

The resulting resin was analyzed by GPC. As a result, Mw was found to be 23.2×10⁴, and Mn was found to be 10.9×10⁴. An amount of an unreacted compound (1-13) in the solid was 1% by mass or less, and a component having a molecular weight of 3,000,000 or more was not observed. A ¹H-NMR spectrum was measured with heavy chloroform as a measuring solvent. As a result, there were observed a proton peak derived from a methyl group (at from −0.5 to 0.5 ppm), a proton peak derived from an alkyl group formed upon polymerization of the vinyl group (at from 0.5 to 3.0 ppm) and a proton peak of the residual vinyl group (at from 4.9 to 6.8 ppm) in an integral ratio of 4.5/1.7/1.8. From this integral ratio, a content of the polymerizable group in the resin was found to be 22.5 mol % relative to the whole of organic groups bonded to the silicon atoms in the resin.

### <Synthesis of Resin A-12>

80 g of the above-synthesized Compound I-12 was added to 2,112 g of chlorobenzene. While heat refluxing the resulting solution in a nitrogen gas stream at an internal temperature of 120° C., 398 mL of a solution obtained by dissolving 500 mg of, as a polymerization initiator, V-601 (10-hour half-life temperature: 66° C.), manufactured by Wako Pure Chemical Industries, Ltd. in 200 g of chlorobenzene was added dropwise over 265.3 minutes. After completion of the dropwise addition, the reaction solution was cooled to room temperature; 5,200 g of electronic grade methanol and 520 mL of ion-exchanged water were added to the reaction solution; and a deposited solid was collected by means of filtration and washed with 100 mL of electronic grade methanol, followed by drying under reduced pressure for 12 hours. The solid was dissolved in 825 g of tetrahydrofuran, to which were then added dropwise 110 g of ion-exchanged water and 110 g of electronic grade methanol while stirring, and a deposited solid was collected by means of filtration and dried. The same operation was repeated three times to obtain 31 g of a desired product (Resin A-12) as a white solid.

The resulting resin was analyzed by GPC. As a result, Mw was found to be 19.3×10⁴, and Mn was found to be 7.85×10⁴. An amount of an unreacted compound (1-12) in the solid was 1% by mass or less, and a component having a molecular weight of 3,000,000 or more was not observed. A ¹H-NMR spectrum was measured with heavy chloroform as a measuring solvent. As a result, there were observed a proton peak derived from a methyl group (at from −0.5 to 0.5 ppm), a proton peak derived from an alkyl group formed upon polymerization of the vinyl group (at from 0.5 to 3.0 ppm) and a proton peak of the residual vinyl group (at from 4.9 to 6.8 ppm) in an integral ratio of 3.5/2.8/1.7. From this integral ratio, a content of the polymerizable group in the resin was found to be 21.3 mol % relative to the whole of organic groups bonded to the silicon atoms in the resin.

### <Synthesis of Resin A-25>

4 g of Compound I-25 was added to 106 g of chlorobenzene. While heat refluxing the resulting solution in a nitrogen gas stream at an internal temperature of 120° C., 15.95 mL of a solution obtained by dissolving 500 mg of, as a polymerization initiator, V-601 (10-hour half-life temperature: 66° C.), manufactured by Wako Pure Chemical Industries, Ltd. in 200 g of chlorobenzene was added dropwise over 200 minutes. After completion of the dropwise addition, the reaction solution was cooled to room temperature; 200 mL of electronic grade methanol and 20 mL of ion-exchanged water were added to the reaction solution; and a deposited solid was collected by means of filtration and washed with 50 mL of electronic grade methanol, followed by drying under reduced pressure for 12 hours. The solid was dissolved in 75 g of tetrahydrofuran, to which was then added dropwise 9 g of ion-exchanged water while stirring, and a deposited solid was collected by means of filtration and dried to obtain 1.0 g of a desired product (Resin A-25) as a white solid.

The resulting resin was analyzed by GPC. As a result, Mw was found to be 22.3×10⁴, and Mn was found to be 8.23×10⁴. An amount of an unreacted compound (1-25) in the solid was 1% by mass or less, and a component having a molecular weight of 3,000,000 or more was not observed. A ¹H-NMR spectrum was measured with heavy chloroform as a measuring solvent. As a result, there were observed a proton peak derived from a propyl group, a proton peak derived from an alkyl group formed upon polymerization of the vinyl group (at from 0.5 to 3.0 ppm) and a proton peak of the residual vinyl group (at from 4.9 to 6.8 ppm) in an integral ratio of 4.0/2.6/1.4. From this integral ratio, a content of the polymerizable group in the resin was found to be 17.5 mol % relative to the whole of organic groups bonded to the silicon atoms in the resin.

### <Synthesis of Resin A-32>

To 1,320 g of electronic grade butyl acetate, 50 g of 1,3,5,7,9,11,13,15-octaethenyl-pentacyclo[9.5.1.1^{3,9}.1^{5,15}.1^{7,13}]octasiloxane (cage structure: a compound represented by the general formula (Q-6), in which all of the eight substituents R's are a vinyl group, x=8, y=0) (Compound I-32) was added. The resulting solution was heated at 120° C. in a nitrogen gas stream, to which was then added dropwise 50.4 mL of a solution obtained by dissolving 0.47 g of, as a polymerization initiator, V-601 (10-hour half-life temperature: 66° C.), manufactured by Wako Pure Chemical Industries, Ltd. and 113 mg of 2,6-bis(1,1-dimethylethyl)-4-methylphenol in 235 mL of electronic grade butyl acetate over 80 minutes. After completion of the dropwise addition, the mixture was stirred at 120° C. for an additional one hour. After completion of stirring, 3 L of electronic grade methanol and 3 L of ion-exchanged water were added to the reaction solution, and a deposited solid was collected by means of filtration and washed with 100 mL of electronic grade methanol. After washing, the solid was dissolved in 724 g of tetrahydrofuran, to which was then successively added dropwise 50 g of electronic grade methanol and 150 g of water while stirring. After stirring for one hour, a supernatant was removed by means of decantation, and 200 g of electronic grade methanol was added to the residue. A deposited solid was collected by means of filtration and dried to obtain 17.7 g of a desired product (Resin A-32) as a white solid.

The resulting resin was analyzed by GPC. As a result, Mw was found to be 8.7×10⁴, and Mn was found to be 5.4×10⁴. An amount of an unreacted compound (1-32) in the solid was 2% by mass or less, and a component having a molecular weight of 3,000,000 or more was not observed. A ¹H-NMR spectrum was measured with heavy chloroform as a measuring solvent. As a result, there were observed a proton peak derived from an alkyl group formed upon polymerization of the vinyl group (at from 0.2 to 3.0 ppm) and a proton peak of the residual vinyl group (at from 4.9 to 6.8 ppm) in an integral ratio of 2.6/5.4. From this integral ratio, a content of the polymerizable group in the resin was found to be 67.5 mol % relative to the whole of organic groups bonded to the silicon atoms in the resin.

### <Synthesis of Resin A-33>

Resin A-33 (Mw=17.8×10⁴, Mn=9.99×10⁴) was synthesized from dodecavinyl-heptacyclo[13.9.1.1^{3,13}.1^{5,11}.1^{7,21}.1^{9,19}.1^{17,23}]dodecasiloxane (cage structure: a compound represented by the general formula (Q-1), in which all of the twelve substituents R's are a vinyl group, x=12, y=0) (Compound I-33) in the same manner as that in Resin A-32.

The resulting resin was analyzed by GPC. As a result, Mw was found to be 17.8×10⁴, and Mn was found to be 9.99×10⁴. An amount of an unreacted compound (1-33) in the solid was 2% by mass or less, and a component having a molecular weight of 3,000,000 or more was not observed. A ¹H-NMR spectrum was measured with heavy chloroform as a measuring solvent. As a result, there were observed a proton peak derived from an alkyl group formed upon polymerization of the vinyl group (at from 0.2 to 3.0 ppm) and a proton peak of the residual vinyl group (at from 4.9 to 6.8 ppm) in an integral ratio of 2.5/9.5. From this integral ratio, a content of the polymerizable group in the resin was found to be 79.2 mol % relative to the whole of organic groups bonded to the silicon atoms in the resin.

Other Resins A-1 to A-11, A-14 to A-24, A-26 to A-31 and A-34 to A-42 were synthesized by referring to the foregoing preparation examples. Incidentally, the type and composition of the silsesquioxane, a polymerization solvent and a polymerization temperature used for the synthesis of each of the resins, and a weight average molecular weight (Mw) and a number average molecular weight (Mn) of each of the resulting polymers are shown in Table 2.

Abbreviations in Table 2 are as follows.

BA: Butyl acetate

DPE: Diphenyl ether

PGMEA: Propylene glycol monomethyl ether acetate (another name: 1-methoxy-2-acetoxypropane)

TBB: t-Butylbenzene

CYHEX: Cyclohexanone

CB: Chlorobenzene

THF: Tetrahydrofuran

V-601: Dimethyl 2,2′-azobis(2-methylpropionate), manufactured by Wako Pure Chemical Industries, Ltd.

V-65: 2,2′-Azobis(2,4-dimethylvaleronitrile), manufactured by Wako Pure Chemical Industries, Ltd.

VR-110: 2,2′-Azobis(2,4,4-trimethylpentane), manufactured by Wako Pure Chemical Industries, Ltd.

V-40:1,1′-Azobis(cyclohexane-1-carbonitrile), manufactured by Wako Pure Chemical Industries, Ltd.

DCP: Dicumyl peroxide

TABLE 2

| | Re- | Com- | | Tem- | | | |
|---|---|---|---|---|---|---|---|
| | peat- | position | Polymer- | per- | | | |
| Resin | ing | ratio | ization | ature | Initi- | Mw | Mn |
| A | unit | (mass) | solvent | (° C.) | ator | (×10⁴) | (×10⁴) |
| A-1 | I-1 | 100 | CB | 132 | V-601 | 20.2 | 8.99 |
| A-2 | I-2 | 100 | CB | 120 | V-601 | 8.06 | 2.99 |
| A-3 | I-3 | 100 | CB | 120 | V-601 | 19.6 | 6.9 |
| A-4 | I-4 | 100 | CB | 120 | V-601 | 8.56 | 3.56 |
| A-5 | I-5 | 100 | CYHEX | 100 | V-65 | 9.88 | 4.56 |
| A-6 | I-6 | 100 | PGMEA | 100 | V-601 | 32.1 | 16.3 |
| A-7 | I-7 | 100 | THF | 50 | V-65 | 25.6 | 10.2 |
| A-8 | I-8 | 100 | CB | 120 | V-601 | 20.6 | 8.03 |
| A-9 | I-9 | 100 | CB | 120 | V-601 | 25.3 | 9.66 |
| A-10 | I-10 | 100 | CB | 120 | V-601 | 22.2 | 11.6 |
| A-11 | I-11 | 100 | CB | 120 | V-601 | 23.5 | 12.3 |
| A-12 | I-12 | 100 | CB | 120 | V-601 | 19.3 | 7.85 |
| A-13 | I-13 | 100 | CB | 132 | V-601 | 23.2 | 10.9 |
| A-14 | I-14 | 100 | CB | 120 | V-601 | 19.7 | 9.32 |
| A-15 | I-15 | 100 | CB | 120 | V-601 | 6.54 | 3.66 |
| A-16 | I-16 | 100 | CB | 120 | V-601 | 30.6 | 12.1 |
| A-17 | I-17 | 100 | CB | 120 | V-601 | 16.4 | 10.5 |
| A-18 | I-18 | 100 | CB | 120 | V-601 | 28.6 | 10.6 |
| A-19 | I-19 | 100 | TBB | 150 | VR-110 | 16.5 | 8.62 |
| A-20 | I-20 | 100 | DPE | 120 | V-601 | 26.9 | 10.6 |
| A-21 | I-21 | 100 | CYHEX | 120 | DCP | 16.4 | 8.56 |
| A-22 | I-22 | 100 | DPE | 120 | V-601 | 6.99 | 3.66 |
| A-23 | I-23 | 100 | CB | 80 | V-40 | 10.4 | 5.11 |
| A-24 | I-24 | 100 | CB | 132 | V-601 | 15.6 | 5.01 |
| A-25 | I-25 | 100 | CB | 120 | V-601 | 22.3 | 8.23 |
| A-26 | I-26 | 100 | CB | 100 | V-601 | 9.87 | 4.56 |
| A-27 | I-27 | 100 | CB | 80 | V-601 | 6.55 | 1.96 |
| A-28 | I-28 | 100 | DPE | 120 | V-601 | 23.1 | 8.15 |
| A-29 | I-29 | 100 | DPE | 100 | VR-110 | 48.7 | 15.6 |
| A-30 | I-30 | 100 | BA | 100 | V-601 | 35.1 | 13.3 |
| A-31 | I-31 | 100 | CB | 120 | V-601 | 31.1 | 12.4 |
| A-32 | I-32 | 100 | BA | 120 | V-601 | 8.7 | 5.4 |
| A-33 | I-33 | 100 | BA | 120 | V-601 | 17.8 | 9.99 |
| A-34 | I-32 | 100 | BA | 120 | V-601 | 9.99 | 4.82 |
| A-35 | I-32 | 100 | CB | 120 | V-601 | 20.5 | 8.25 |
| A-36 | I-32 | 100 | CB/BA | 120 | V-601 | 12.3 | 6.32 |
| | | | (mass ratio: | | | | |
| | | | 9/1) | | | | |
| A-37 | I-14 | 100 | CB | 120 | V-601 | 10.3 | 4.09 |
| A-38 | I-14 | 100 | BA | 120 | V-601 | 20.6 | 8.79 |
| A-39 | I-14 | 100 | BA | 120 | V-601 | 7.88 | 2.99 |
| A-40 | I-14/ | 50/50 | CB | 120 | V-65 | 18.9 | 7.56 |
| | I-32 | | | | | | |
| A-41 | I-14/ | 25/75 | CB | 120 | V-65 | 26.9 | 11.3 |
| | I-32 | | | | | | |
| A-42 | I-21/ | 50/50 | CYHEX | 120 | V-601 | 12.33 | 5.95 |
| | I-25 | | | | | | |

### <Comparative Resin (R-1)>

39.2 g of trichlorophenylsilane dissolved in 72 mL of acetone was added dropwise to 1.42 kg of ice water, and the mixture was stirred at 0° C. for 20 hours. A precipitate was collected by means of filtration, washed with water and then dried. Subsequently, the resultant was suspended in 200 mL of carbon disulfide, collected by means of filtration and then recrystallized from acetone/toluene to obtain 8 g of Comparative Resin (R-1).

### <Comparative Resin (R-2)>

A 50-mL three-necked flask was charged with 625 mg of tetraethoxysilane, 2.32 g of methyl triethoxysilane, 100 mg of oxalic acid, 12 mL of isopropyl alcohol, 4 mL of butanol and 3 mL of ion-exchanged water, and the mixture was heat refluxed for 7 hours to obtain Comparative Resin (R-2). After allowing it to stand for cooling, the resultant was filtered through a tetrafluoroethylene-made filter having a pore size of 0.1 μm.

### <Preparation of Photoconductive Composition>

Components shown in the following Tables 3 to 4 were dissolved in each of solvents shown in the following Tables 3 to 4, thereby regulating a total solid concentration to 8% by mass, and the resultant was filtered through a tetrafluoroethylene-made filter having a pore size of 0.1 μm. There were thus prepared photosensitive compositions of Examples 1 to 42 and Comparative Examples 1 to 3.

In Tables 3 to 4, the content of the surfactant is expressed by % by mass relative to the whole amount of the composition (coating solution). On the other hand, the content of each of the resin, the adhesion accelerator, the pore-forming agent, the polymerization initiator, the polymerizable compound and the alkali-soluble resin is expressed by % by mass relative to the whole amount of the composition (coating solution).

As the surfactant, BYK307 (manufactured by BYK Chemie), PF6320 (manufactured by Omnova Solutions, Inc.) and F-475 (manufactured by DIC Corporation) were used, respectively.

As the adhesion accelerator, GPTMS (3-glycidyloxypropyltrimethoxysilane) and MPMDMS (1-methacryloxypropylmethyldimethoxysilane) were used, respectively.

The contents of the pore-forming agent are described later.

As the polymerization initiator, commercially products were used. Details thereof are described previously.

As the polymerizable compound, PETA (pentaerythritol tetraacrylate) and DPHA (dipentaerythritol hexaacrylate) were used, respectively.

As the alkali-soluble resin, the following Resin P-1 was used.

P-1: A terpolymer of benzyl methacrylate, methacrylic acid and 2-hydroxyethyl methacrylate (mass ratio of repeating units: 70/13/17, Mw: 28,000, Mn: 11,000)

As to the solvent, the abbreviations used in Tables 3 to 4 are the same as those described above. Also, PGME means propylene glycol monomethyl ether (another name: 1-methoxy-2-propanol).

TABLE 3

| | | | | Adhesion | Pore-forming | Photopolymerization | Polymerizable | Alkali- |
|---|---|---|---|---|---|---|---|---|
| | Resin | Solvent | Surfactant | accelerator | agent | initiator | compound | soluble resin |
| | (% by mass) | (mass ratio) | (% by mass) | (% by mass) | (% by mass) | (% by mass) | (% by mass) | (% by mass) |
| Example 1 | A-1 | PGMEA | — | — | — | IRGACURE-907 | — | — |
| | (95) | (100) | | | | (5.0) | | |
| Example 2 | A-2 | PGMEA | — | — | — | IRGACURE-907 | — | — |
| | (95) | (100) | | | | (5.0) | | |
| Example 3 | A-3 | PGMEA | — | — | — | DAROCURE-1173 | — | — |
| | (95) | (100) | | | | (5.0) | | |
| Example 4 | A-4 | BA | — | — | — | IRGACURE-184 | — | — |
| | (95) | (100) | | | | (5.0) | | |
| Example 5 | A-5 | CYHEX | — | — | — | IRGACURE-127 | — | P-1 |
| | (85) | (100) | | | | (5.0) | | (10) |
| Example 6 | A-6 | PGMEA | — | — | — | CGI-124 | — | — |
| | (95) | (100) | | | | (50) | | |
| Example 7 | A-7 | CYHEX | — | MPMDMS | — | DAROCURE-1173 | — | — |
| | (95) | (100) | | (2.0) | | (5.0) | | |
| Example 8 | A-8 | PGMEA | — | — | — | CGI-124 | — | — |
| | (95) | (100) | | | | (5.0) | | |
| Example 9 | A-9 | PGMEA | — | — | — | IRGACURE-907 | — | — |
| | (95) | (100) | | | | (5.0) | | |
| Example 10 | A-10 | CYHEX | F-475 | — | — | CGI-124 | PETA | — |
| | (80) | (100) | (0.02) | | | (5.0) | (15) | |
| Example 11 | A-11 | PGMEA | — | MPMDMS | B-1 | IRGACURE-819 | — | — |
| | (82) | (100) | | (3.0) | (10) | (5.0) | | |
| Example 12 | A-12 | PGMEA | — | — | — | CGI-124 | DPHA | — |
| | (75) | (100) | | | | (5.0) | (20) | |
| Example 13 | A-13 | PGMEA | — | — | B-9 | IRGACURE-127 | — | — |
| | (80) | (100) | | | (15) | (5.0) | | |
| Example 14 | A-14 | PGMEA | — | — | — | CGI-124 | DPHA | — |
| | (85) | (100) | | | | (5.0) | (10) | |
| Example 15 | A-15 | PGMEA | BYK307 | — | — | CGI-124 | — | — |
| | (95) | (100) | (0.01) | | | (5.0) | | |
| Example 16 | A-16 | PGMEA | — | — | — | DAROCURE-1173 | — | — |
| | (95) | (100) | | | | (5.0) | | |
| Example 17 | A-17 | PGMEA | — | — | B-9 | IRGACURE-127 | — | — |
| | (85) | (100) | | | (10) | (5.0) | | |
| Example 18 | A-18 | CYHEX | — | — | — | DAROCURE-1173 | — | — |
| | (95) | (100) | | | | (5.0) | | |
| Example 19 | A-19 | PGMEA/PGME | — | — | — | IRGACURE-819 | — | P-1 |
| | (83) | (60/40) | | | | (7.0) | | (10) |
| Example 20 | A-20 | PGMEA | — | — | — | CGI-124 | — | — |
| | (95) | (100) | | | | (5.0) | | |
| Example 21 | A-21 | CYHEX | — | — | — | IRGACURE-819 | — | — |
| | (90) | (100) | | | | (10.0) | | |
| Example 22 | A-22 | PGMEA | — | — | — | IRGACURE-907 | — | — |
| | (91) | (100) | | | | (9.0) | | |
| Example 23 | A-23 | PGMEA | — | — | — | IRGACURE-819 | — | — |
| | (95) | (100) | | | | (7.0) | | |

TABLE 4

| | | | | Adhesion | Pore-forming | Photopolymerization | Polymerizable | Alkali- |
|---|---|---|---|---|---|---|---|---|
| | Resin | Solvent | Surfactant | accelerator | agent | initiator | compound | soluble resin |
| | (% by mass) | (mass ratio) | (% by mass) | (% by mass) | (% by mass) | (% by mass) | (% by mass) | (% by mass) |
| Example 24 | A-24 | PGMEA | — | — | — | IRGACURE-184 | PETA | — |
| | (70) | (100) | | | | (5.0) | (25) | |
| Example 25 | A-25/A-32 | PGMEA | — | GPTMS | — | CGI-124 | — | — |
| | (40/50) | (100) | | (5.0) | | (5.0) | | |
| Example 26 | A-26 | PGMEA | PF6320 | — | B-4 | CGI-124 | — | — |
| | (80) | (100) | (0.03) | | (15) | (5.0) | | |
| Example 27 | A-27 | CYHEX | — | — | B-5 | IRGACURE-184 | — | — |
| | (85) | (100) | | | (10) | (5.0) | | |
| Example 28 | A-28 | PGMEA | — | — | — | IRGACURE-127 | — | — |
| | (95) | (100) | | | | (5.0) | | |
| Example 29 | A-29 | PGMEA | — | — | B-6 | CGI-124 | — | — |
| | (85) | (100) | | | (5) | (10.0) | | |
| Example 30 | A-30 | PGMEA | — | — | — | DAROCURE-1173 | — | — |
| | (95) | (100) | | | | (5.0) | | |
| Example 31 | A-31 | BA | — | — | — | IRGACURE-127 | — | — |
| | (95) | (100) | | | | (5.0) | | |
| Example 32 | A-32 | PGMEA | — | — | — | IRGACURE-184 | — | — |
| | (95) | (100) | | | | (5.0) | | |
| Example 33 | A-33 | PGMEA | — | — | B-12 | CGI-124 | — | P-1 |
| | (80) | (100) | | | (10) | (5.0) | | (5) |
| Example 34 | A-34 | PGMEA | — | — | — | CGI-124 | — | — |
| | (95) | (100) | | | | (5.0) | | |
| Example 35 | A-35 | PGMEA | — | — | B-9 | CGI-124 | DPHA | — |
| | (80) | (100) | | | (5) | (5.0) | (10) | |
| Example 36 | A-36 | CYHEX | — | — | — | CGI-124 | — | — |
| | (95) | (100) | | | | (5.0) | | |
| Example 37 | A-37 | CYHEX | PF6320 | — | — | CGI-124 | — | — |
| | (95) | (100) | (0.01) | | | (5.0) | | |
| Example 38 | A-38 | BA | — | — | B-12 | DAROCURE-1173 | DPHA | — |
| | (75) | (100) | | | (10) | (5.0) | (10) | |
| Example 39 | A-16 | PGMEA | — | — | — | CGI-124 | — | — |
| | (95) | (100) | | | | (5.0) | | |
| Example 40 | A-16 | PGMEA | — | — | — | IRGACURE-127 | — | — |
| | (95) | (100) | | | | (5.0) | | |
| Example 41 | A-41 | PGMEA | — | — | B-9 | CGI-124 | — | — |
| | (85) | (100) | | | (10) | (5.0) | | |
| Example 42 | A-42 | BA | — | — | — | CGI-124 | — | — |
| | (95) | (100) | | | | (5.0) | | |
| Comparative | A-35 | PGMEA | — | — | — | Nil | — | — |
| Example 1 | (100) | (100) | | | | | | |
| Comparative | R-1 | PGMEA | — | — | — | IRGACURE-907 | — | — |
| Example 2 | (95) | (100) | | | | (5.0) | | |
| Comparative | R-2 | PGMEA | — | — | — | DAROCURE-1173 | — | — |
| Example 3 | (95) | (100) | | | | (5.0) | | |

Examples of the case of using a pore-forming agent are hereunder described in detail.

### <Synthesis of Resin B-1>

4 g of PGMEA was charged in a three-necked flask in a nitrogen gas stream and heated at 80° C. Subsequently, to this reaction solution, a solution obtained by dissolving 10 g of 1-ethyl-cyclopentyl methacrylate and 0.379 g of an initiator V-601 (manufactured by Wako Pure Chemical Industries, Ltd.) in 36 g of PGMEA was added dropwise over 2 hours. After completion of the dropwise addition, the mixture was further allowed to react at 80° C. for one hour. After allowing the reaction solution to stand for cooling, 500 mL of methanol was added dropwise thereto over 10 minutes, and a deposited powder was collected by means of filtration and dried to obtain 5.83 g of Resin B-1.

The resulting resin was analyzed by means of GPC. As a result, Mw was found to be 16,200, and Mn was found to be 9,800. As a result of thermogravimetric analysis (using SDT Q-600, manufacture by TA Instruments at a nitrogen flow rate of 100 mL/min and at a programming rate of 20° C./min), a 50% weight reduction temperature was found to be 228° C.

Resin B-4 was synthesized while referring to the foregoing preparation example. Resin B-4 is corresponding to a resin represented by the foregoing formula (B-4).

### <Synthesis of Resin B-5>

3.6 g of cyclohexanedimethanol and 3.6 g of butanediol divinyl ether were dissolved in 5 mL of tetrahydrofuran, to which was then added 100 mg of p-toluenesulfonic acid pyridine salt, and the mixture was stirred at room temperature for 4 hours. After completion of stirring, 0.5 mL of triethylamine was added, 100 mL of methanol was added to the reaction solution, and the mixture was stirred for 30 minutes. After completion of stirring, an upper layer of separated two layers was removed, and a lower layer was dried under reduced pressure, thereby obtaining 2.8 g of Resin B-5 as a transparent viscous liquid. The resulting resin was analyzed by means of GPC. As a result, Mw was found to be 14,000, and Mn was found to be 3,500. As a result of thermogravimetric analysis (using SDT Q-600, manufacture by TA Instruments at a nitrogen flow rate of 100 mL/min and at a programming rate of 20° C./min), a 50% weight reduction temperature was found to be 241° C.

Polyacetal B-6 was synthesized while referring to the foregoing preparation example. Resins B-5 and B-6 are corresponding to resins represented by the foregoing formulae (B-5) and (B-6), respectively.

A number average molecular weight as reduced into polystyrene and a 50% weight reduction temperature of each of the above-synthesized Resins B-1, B-4, B-5 and B-6 and Aldrich's polyalkylene glycols (B-9) and (B-12) are shown in Table 5.

TABLE 5

| | | | 50% weight |
|---|---|---|---|
| Pore-forming | Weight average | Number average | reduction |
| agent | molecular weight | molecular weight | temperature (° C.) |
| B-1 | 16200 | 9800 | 228 |
| B-4 | 19200 | 10200 | 262 |
| B-5 | 14000 | 3500 | 241 |
| B-6 | 10500 | 1900 | 191 |
| B-9: Polyeth- | — | 200 | 271 |
| ylene glycol | | | |
| B-12: Polypro- | — | 200 | 275 |
| pylene glycol | | | |

Pattern films formed by the following method were evaluated by the following methods. The results are shown in Table 6.

### <Formation of Photosensitive Film and Exposure>

(1) i-Ray exposure:

A solution of each of the thus prepared photosensitive compositions was coated on a 6-inch silicon wafer, and the substrate was preliminarily dried on a hot plate at 100° C. for 1.5 minutes, thereby forming a photosensitive film having a thickness of 300 nm. Subsequently, pattern exposure was performed at a wavelength of 365 nm using an exposure mask in which pixels of 0.5 μm in square were provided on a substrate and using an i-ray stepper exposure apparatus FPA-3000i5+ (manufactured by Canon Inc.).

### (2) KrF Exposure:

A solution of each of the thus prepared photosensitive compositions was uniformly coated on a silicon wafer utilizing a spin coater Mark 8, manufactured by Tokyo Electron Ltd. and dried by heating at 100° C. for 1.5 minutes, thereby forming a photosensitive film having a thickness of 300 nm. This pattern film was subjected to pattern exposure using an exposure mask (line/space=1/1) and using a KrF excimer laser scanner (PAS5500/850C, manufactured by ASML, NA=0.68, σ=0.60).

### (3) ArF Exposure:

A solution of each of the thus prepared photosensitive compositions was uniformly coated on a silicon wafer utilizing a spin coater Mark 8, manufactured by Tokyo Electron Ltd. and baked at 115° C. for 60 seconds, thereby forming a photosensitive film having a thickness of 200 nm. The resulting wafer was subjected to pattern exposure using an exposure mask (line/space=1/1) and using an ArF excimer laser scanner (PAS5500/1100, manufactured by ASML, NA=0.75, dipole, σo/σi=0.89/0.65).

(4) EB exposure:

A solution of each of the thus prepared photosensitive compositions was coated on a silicon wafer which had been subjected to a treatment with hexamethyldisilasane, by utilizing a spin coater Mark 8, manufactured by Tokyo Electron Ltd. and baked at 120° C. for 60 seconds, thereby forming a photosensitive film having a thickness of 300 nm. This photosensitive film was irradiated with an electron beam using an electron beam drawing apparatus (HL750, manufactured by Hitachi, Ltd., accelerating voltage: 50 keV).

### <Formation of Pattern Film (Development on Photosensitive Film)>

The resulting exposed film was developed with a developer shown in Table 6 by any one of the following methods.

(A) The exposed substrate was dipped in a tank filled with the developer and dried while allowing nitrogen to flow.
(B) The exposed substrate was developed while puddling for 30 seconds and subsequently rinsed with a rinse solution while puddling for 30 seconds, and the wafer was then rotated at a rotation rate of 2,000 rpm for 30 seconds.
(C) The exposed substrate was developed while puddling for 180 seconds and subsequently rinsed with a rinse solution while puddling for 60 seconds, and the wafer was then rotated at a rotation rate of 2,000 rpm for 30 seconds.

### <Curing of Pattern Film>

The resulting pattern film was cured by any one of the following methods.

### (Antireflection Film)

### (1) Heating A:

The pattern film was heated on a hot plate at 220° C. for 5 minutes in the atmosphere.

### (2) UV Irradiation A:

The pattern film was irradiated with an ultraviolet ray of 10,000 [mJ/cm²] using a high-pressure mercury lamp (UMA-802-HC552FFAL, manufactured by Ushio Inc.). Incidentally, a proportion of light having a wavelength of 275 nm or less contained in the light irradiated from the high-pressure mercury lamp is 10%.

### <Insulating Film>

### (1) Heating B:

By using a clean oven CLH-21CD(III), manufactured by Koyo Thermo Systems Co., Ltd., the insulating film was heated in the clean oven at 400° C. for 60 minutes.

### (2) EB Irradiation:

By using Mini-EB, manufactured by Ushio Inc., the insulating film was irradiated with an electron beam at a dose of 1 μCcm⁻² and at an electron accelerating voltage of 20 keV for 5 minutes in an Ar atmosphere under a condition at a pressure of 100 kPa and at a substrate temperature of 350° C.

### (3) UV Irradiation B:

By using a dielectric barrier discharge mode excimer lamp UER20-172, manufactured by Ushio Inc., the insulating film was irradiated with 100 mJ/cm² of light having a wavelength of 172 nm on a hot plate at 350° C. in a nitrogen gas stream.

Each of the resulting cured films was evaluated by the following methods. The results are shown in Table 6.

### <Resolution>

The resulting pattern film was observed by a length measuring SEM (S-8840, manufactured by Hitachi, Ltd.). The case where resolution of the following exposure pattern was recognized is expressed as “A”, whereas the case where resolution of the pattern could not be confirmed is expressed as “B”.

i-Ray exposure: Pixel of 0.5 μm in square

KrF exposure: 0.2 μm line (line/space=1/1)

ArF exposure: 0.13 μm line (line/space=1/1)

EB exposure: 0.10 μm line (line/space=1/1)<

### <Sensitivity>

A minimum exposure amount at which the exposure pattern was resolved (mJ/cm² in the case of i-ray exposure, KrF exposure and ArF exposure; and μC/cm² in the case of EB exposure) was defined as sensitivity. It is meant that the smaller the value, the more satisfactory the performance is.

### <Coating Surface Properties>

As a result of visual inspection, the case where the generation of surface roughness such as a striation and a burr was confirmed is expressed as “B”, whereas the case where the generation of surface roughness was not confirmed is expressed as “A”.

### <Refractive Index>

A value in a pattern film portion on the silicon wafer as measured using a Woolam's spectral ellipsometer (VASE) at a wavelength of 633 nm and at 25° C. was used.

### <Heat Resistance>

The cured film was heated on a hot plate at 220° C. for 2 hours in the atmosphere. As to a change in refractive index before and after the test, the case where it was less than 0.002 is expressed as “A”; the case where it was 0.002 or more and less than 0.004 is expressed as “B”; the case where it was 0.004 or more and less than 0.006 is expressed as “C”; and the case where it was 0.006 or more is expressed as “D”. Incidentally, from the viewpoint of practical use, it is necessary that “D” is not included.

### <Relative Dielectric Constant>

By using a mercury probe, manufactured by Four Dimensions, Inc. and an HP4285ALCR meter, manufactured by Yokogawa Hewlett-Packard, the relative dielectric constant was calculated from a capacity value (in a cured film portion, measurement temperature: 25° C.) at 1 MHz

### <Young's Modulus>

The Young's modulus was measured at 25° C. using an MTS's nanoindenter SA2. The case where a measured value was 5.0 GPa or more is expressed as “A”; the case where it was 3.0 GPa or more and less than 5.0 GPa is expressed as “B”; the case where it was 1.5 GPa or more and less than 3.0 GPa is expressed as “C”; and the case where it was less than 1.5 GPa is expressed as “D”. Incidentally, from the viewpoint of practical use, it is necessary that “D” is not included.

Abbreviations regarding the developers and rinse solutions in Table 6 are as follows.

BA: Butyl acetate

PGMEA: Propylene glycol monomethyl ether acetate (another name: 1-methoxy-2-acetoxypropane)

CYHEX: Cyclohexanone

IPA: Isopropanol

MIBK: 4-Methyl-2-pentanone

MEK: Methyl ethyl ketone

TABLE 6

| | | | | | | | | Coating | | | | |
|---|---|---|---|---|---|---|---|---|---|---|---|---|
| | Expo- | Devel- | | | | | Sensi- | surface | Refrac- | Heat | Relative | Young's |
| | sure | opment | Devel- | Rinse | Curing | Reso- | tivity | prop- | tive | resis- | dielectric | modulus |
| | mode | mode | oper | solution | method | lution | (mJ/cm²) | erties | index | tance | constant | (GPa) |
| Example 1 | i-Ray | A | PGMEA | PGMEA | Heating A | A | 950 | A | 1.33 | B | 2.32 | B |
| Example 2 | i-Ray | C | PGMEA | PGMEA | UV irradiation A | A | 850 | A | 1.32 | B | 2.35 | C |
| Example 3 | i-Ray | B | PGMEA | 1-Hexanol | Heating A | A | 1050 | A | 1.32 | B | 2.32 | B |
| Example 4 | i-Ray | A | CYHEX | CYHEX | UV irradiation A | A | 700 | A | 1.32 | B | 2.29 | B |
| Example 5 | i-Ray | A | PGMEA | PGMEA | UV irradiation A | A | 900 | A | 1.32 | B | 2.31 | B |
| Example 6 | i-Ray | B | IPA | IPA | UV irradiation A | A | 450 | A | 1.32 | C | 2.22 | B |
| Example 7 | i-Ray | A | PGMEA | PGMEA | UV irradiation A | A | 1000 | A | 1.31 | B | 2.35 | A |
| Example 8 | i-Ray | A | Toluene | PGMEA | Heating A | A | 400 | A | 1.33 | B | 2.34 | B |
| Example 9 | i-Ray | A | PGMEA | PGMEA | Heating A | A | 800 | A | 1.31 | B | 2.35 | B |
| Example 10 | i-Ray | A | PGMEA | PGMEA | UV irradiation A | A | 250 | A | 1.31 | C | 2.31 | A |
| Example 11 | i-Ray | B | BA | BA | Heating A | A | 750 | A | 1.31 | B | 2.19 | A |
| Example 12 | i-Ray | A | PGMEA | PGMEA | Heating A | A | 200 | A | 1.32 | B | 2.36 | A |
| Example 13 | i-Ray | A | BA | BA | Heating B | A | 850 | A | 1.32 | A | 2.20 | B |
| Example 14 | i-Ray | B | PGMEA | PGMEA | Heating A | A | 150 | A | 1.31 | A | 2.25 | B |
| Example 15 | i-Ray | A | PGMEA | PGMEA | UV irradiation A | A | 550 | A | 1.31 | B | 2.30 | B |
| Example 16 | i-Ray | A | PGMEA | PGMEA | UV irradiation B | A | 950 | A | 1.29 | A | 2.18 | B |
| Example 17 | i-Ray | A | PGMEA | PGMEA | UV irradiation B | A | 800 | A | 1.29 | A | 2.18 | C |
| Example 18 | i-Ray | B | MIBK | MIBK | Heating B | A | 950 | A | 1.30 | A | 2.21 | B |
| Example 19 | i-Ray | A | PGMEA | PGMEA | Heating B | A | 850 | A | 1.32 | A | 2.22 | C |
| Example 20 | i-Ray | A | MEK | MEK | Heating B | A | 400 | A | 1.31 | A | 2.24 | B |
| Example 21 | i-Ray | B | CYHEX | CYHEX | UV irradiation B | A | 800 | A | 1.29 | A | 2.21 | B |
| Example 22 | i-Ray | A | BA | BA | Heating B | A | 750 | A | 1.30 | A | 2.31 | B |
| Example 23 | i-Ray | A | PGMEA | 1-Hexanol | UV irradiation B | A | 800 | A | 1.29 | A | 2.22 | B |
| Example 24 | i-Ray | A | PGMEA | PGMEA | Heating B | A | 400 | A | 1.33 | A | 2.23 | A |
| Example 25 | i-Ray | B | PGMEA | PGMEA | Heating B | A | 250 | A | 1.33 | A | 2.23 | A |
| Example 26 | KrF | A | PGMEA | PGMEA | UV irradiation B | A | 75 | A | 1.32 | A | 2.19 | B |
| Example 27 | KrF | A | PGMEA | PGMEA | UV irradiation B | A | 160 | A | 1.30 | A | 2.20 | B |
| Example 28 | KrF | C | PGMEA | 1-Hexanol | Heating B | A | 120 | A | 1.31 | A | 2.20 | B |
| Example 29 | KrF | A | CYHEX | CYHEX | EB irradiation | A | 60 | A | 1.30 | A | 2.20 | B |
| Example 30 | KrF | A | PGMEA | PGMEA | UV irradiation B | A | 110 | A | 1.32 | A | 2.15 | B |
| Example 31 | KrF | B | BA | BA | Heating B | A | 150 | A | 1.33 | A | 2.19 | B |
| Example 32 | KrF | A | PGMEA | PGMEA | Heating B | A | 130 | A | 1.32 | A | 2.26 | B |
| Example 33 | KrF | A | CYHEX | CYHEX | UV irradiation B | A | 70 | A | 1.31 | A | 2.19 | B |
| Example 34 | KrF | A | PGMEA | PGMEA | EB irradiation | A | 65 | A | 1.32 | A | 2.22 | B |
| Example 35 | KrF | B | PGMEA | PGMEA | Heating B | A | 45 | A | 1.29 | A | 2.26 | B |
| Example 36 | KrF | B | PGMEA | PGMEA | Heating A | A | 60 | A | 1.30 | B | 2.19 | A |
| Example 37 | KrF | C | Toluene | CYHEX | Heating B | A | 65 | A | 1.32 | B | 2.24 | B |
| Example 38 | KrF | A | PGMEA | PGMEA | UV irradiation A | A | 85 | A | 1.31 | C | 2.19 | A |
| Example 39 | KrF | A | PGMEA | PGMEA | Heating B | A | 55 | A | 1.33 | B | 2.23 | B |
| Example 40 | KrF | A | BA | BA | EB irradiation | A | 120 | A | 1.32 | A | 2.19 | B |
| Example 41 | EB | C | PGMEA | PGMEA | Heating B | A | 120 | A | 1.31 | A | 2.31 | B |
| | | | | | | | (μC/cm²) | | | | | |
| Example 42 | EB | A | PGMEA | 1-Hexanol | UV irradiation B | A | 100 | A | 1.31 | A | 2.26 | B |
| | | | | | | | (μC/cm²) | | | | | |
| Comparative | i-Ray | A | PGMEA | PGMEA | Heating B | B | >2500 | B | 1.30 | D | 2.28 | B |
| Example 1 | | | | | | | | | | | | |
| Comparative | i-Ray | A | PGMEA | PGMEA | Heating A | B | >2500 | B | 1.36 | D | 2.51 | D |
| Example 2 | | | | | | | | | | | | |
| Comparative | KrF | A | PGMEA | PGMEA | UV irradiation A | B | >250 | B | 1.35 | D | 2.60 | D |
| Example 3 | | | | | | | | | | | | |

It was noted from the results shown in Table 6 that in the case of using the photosensitive composition of the invention, a pattern film which is satisfactory in coating surface properties, low in refractive index, small in a change of refractive index even under a high-temperature condition, low in dielectric constant and high in Young's modulus can be formed at a high resolution.

On the other hand, in the case of using a polymer of a silsesquioxane which does not satisfy the formula (1), the foregoing effects of the invention could not be satisfied at the same time.

The following items were also evaluated.

### <Heat Resistance>

The evaluation of heat resistance was also performed by heating the resulting film in air at 400° C. for 60 seconds and measuring a change rate in film thickness. It may be said that a coating film having a value close to 0 is good in heat resistance. The values of Examples 35 and 37 were 4.5% and 4.9%, respectively, whereas those of Comparative Examples 2 and 3 were 10.1% and 8.9%, respectively.

### <Pore Size and Density>

The pore size and density were measured on the basis of the following methods.

The pore size of the resulting pattern film was measured by means of small angle X-ray scattering (SAXS). The analysis was performed using a spherical model on the assumption that the pore size distribution follows a gamma distribution function, and a maximum frequency diameter of the resulting pore distribution was defined as a maximum distribution diameter. The pore sizes of Examples 14, 35, 37 and 39 were 3.2 nm, 4.3 nm, 2.6 nm and 2.9 nm, respectively, whereas those of Comparative Examples 2 and 3 were 9.6 nm and 8.9 nm, respectively.

The film density of the resulting pattern film was measure by means of X-ray reflectometry (XRR). The densities of Examples 14, 35, 37 and 39 were 0.95 g/cm³, 0.99 g/cm³, 0.94 g/cm³ and 0.89 g/cm³, respectively, whereas those of Comparative Examples 2 and 3 were 1.26 g/cm³ and 1.19 g/cm³, respectively.

Examples in which a film obtained from the photosensitive composition according to the invention was applied to an antireflection film are hereunder described in detail.

### <Reflectance>

As to the reflectance, a mirror average reflectance (%) of light having a wavelength of from 450 to 650 nm at an incident angle of 5° was measured using a spectrophotometer (manufactured by JASCO Corporation).

### [Production 1 of Antireflection Film]

A reflectance of the exposed film portion of a photosensitive film obtained from each of the photosensitive compositions of Examples 14, 35 and 37 and Comparative Example 2 was measured. As a result, the reflectances (%) were 0.6%, 0.7%, 0.5% and 4.1%, respectively.

### [Production 2 of Antireflection Film]

RASA TI, manufactured by Rasa Industries, Ltd. was spin coated on a silicon wafer and baked at 350° C. to form a film having a thickness of 60 nm and a refractive index of 2.0. The photosensitive composition of Example 37 whose concentration had been adjusted was coated thereonto such that the film thickness after prebaking was 20 nm, exposed and developed. Thereafter, the resultant was heated on a hot plate at 100° C. for 2 minutes, and subsequently, the substrate was heated at 350° C. for 5 minutes to form an antireflection film of a multi-layered type.

As a comparative example, the composition of Comparative Example 3 was used in place of the composition of Example 37, and the same operations were followed, thereby forming an antireflection film of a multi-layered type.

A reflectance was measured. As a result, in the case of using the composition of Example 37, the reflectance was 0.8%, whereas in the case of using the composition of Comparative Example 3, the reflectance was 4.7%.

The entire disclosure of each and every foreign patent application from which the benefit of foreign priority has been claimed in the present application is incorporated herein by reference, as if fully set forth.

What is claimed is:

1. A photosensitive composition comprising:
(A) a polymer obtained from a silsesquioxane constituted of one or two or more kinds of a cage-shaped silsesquioxane compound represented by the following formula (1):
(RSiO_{1.5})ₐ (1)
wherein
each R independently represents an organic group, and at least two of R's represent a polymerizable group; a represents an integer of from 8 to 16; and each R may be the same as or different from every other R, and
(B) a photopolymerization initiator,
provided that a polymerizable group derived from the cage-shaped silsesquioxane compound remains in the polymer.

2. The photosensitive composition according to claim 1, wherein the cage-shaped silsesquioxane compound is one or two or more members selected from the group consisting of cage-shaped silsesquioxane compounds represented by the following general formulae (Q-1) to (Q-7): 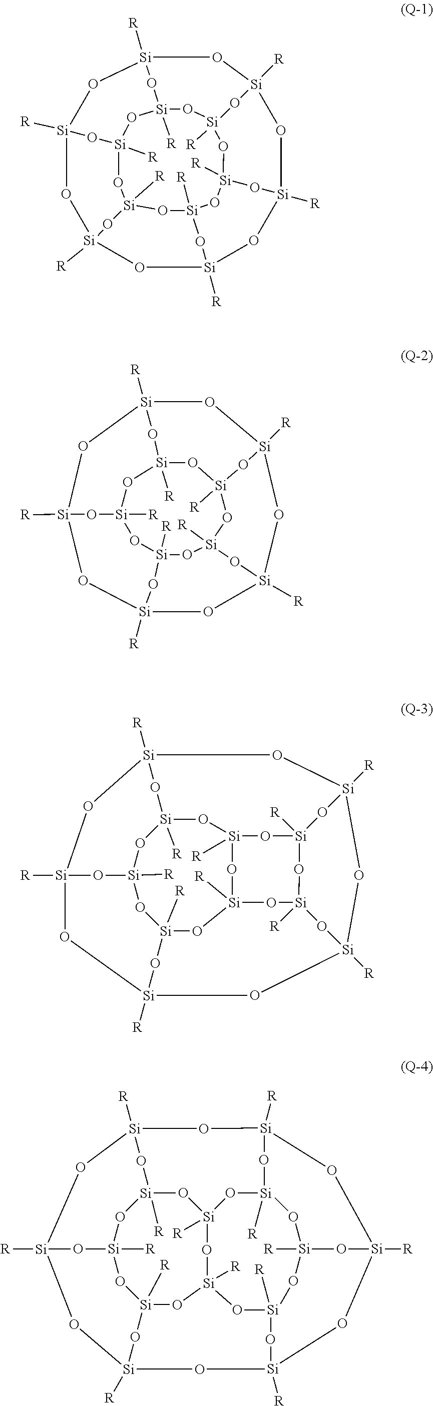 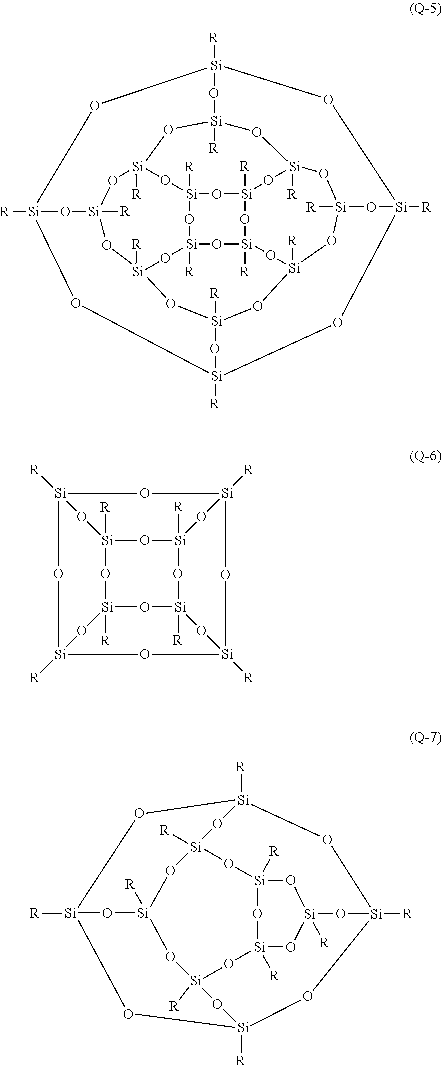
wherein
each R independently represents an organic group, and in each of the general formulae (Q-1) to (Q-7), at least two of R's represent a polymerizable group.

3. The photosensitive composition according to claim 1, wherein a content of the polymerizable group in the polymer is from 10 to 90 mol % in the whole of organic groups bonded to the silicon atoms.

4. The photosensitive composition according to claim 1, wherein a weight average molecular weight of the polymer is from 10,000 to 500,000.

5. The photosensitive composition according to claim 1, which is a negative working composition.

6. The photosensitive composition according to claim 1, wherein the photopolymerization initiator is an oxime compound.

7. A pattern forming material, which is the photosensitive composition according to claim 1.

8. A photosensitive film, which is formed from the photosensitive composition according to claim 1.

9. A pattern forming method comprising:
a step of forming the photosensitive film according to claim 8;
a step of exposing the photosensitive film; and
a development step of developing the exposed photosensitive film to obtain a pattern film.

10. The pattern forming method according to claim 9, wherein the development step is a step of performing development with a developer containing an organic solvent.

11. The pattern forming method according to claim 10, wherein the developer containing an organic solvent is a developer containing at least one solvent selected from the group consisting of a ketone based solvent, an ester based solvent, an alcohol based solvent, an amide based solvent and an ether based solvent.

12. A pattern film obtained by the pattern forming method according to claim 9.

13. The pattern film according to claim 12, having a refractive index of 1.35 or less.

14. The pattern film according to claim 12, having a relative dielectric constant at 25° C. of 2.50 or less.

15. The pattern film according to claim 12, having a film density of from 0.7 to 1.25 g/cm³.

16. An antireflection film, which is the pattern film according to claim 12.

17. An insulating film, which is the pattern film according to claim 12.

18. An optical device having the antireflection film according to claim 16.

19. An electronic device having the insulating film according to claim 17.
